(19) United States
(12) Patent Application Publication
(10) Pub. No.: US 2007/0117271 A1
(43) Pub. Date: May 24, 2007

(54) Methods and compositions for the formation of recessed electrical features on a substrate

(75) Inventors: Toivo T. Kodas, Albuquerque, NM (US); Mark J. Hampden-Smith, Albuquerque, NM (US); Karel Vanheusden, Placitas, NM (US); Hugh Denham, Albuquerque, NM (US); Aaron D. Stump, Albuquerque, NM (US); Allen B. Schult, Albuquerque, NM (US); Paolina Atanassova, Albuquerque, NM (US); Klaus Kunze, Albuquerque, NM (US)

Correspondence Address: Jaimes Sher, Esq.;Cabot Corporation, 5401 Venice Avenue NE, Albuquerque, NM, 87113, US

(73) Assignee: Cabot Corporation, Boston, MA (US)

(21) Appl. No.: 11/642,687

(22) Filed: Dec. 21, 2006

Related U.S. Application Data
(63) Continuation of application No. 10/265,295, filed on Oct. 4, 2002.
(60) Provisional application No. 60/338,797, filed on Nov. 2, 2001.
(60) Provisional application No. 60/327,621, filed on Oct. 5, 2001.

(51) Int. Cl. H01L 21/00

(52) U.S. Cl. 438/122

(57) ABSTRACT

Precursor compositions having a low conversion temperature and methods for the fabrication of recessed electrical features from the precursor compositions. The electrical features can be conductors, resistors and dielectric features. The precursor compositions are deposited into recessed features, such as trenches, formed in a substrate and are reacted at a low temperature to form electrical features having good electrical and mechanical properties. The substrate can be a low temperature substrate, such as an organic substrate.

### CROSS-REFERENCE TO RELATED APPLICATIONS

This application is a continuation application of co-pending U.S. patent application Ser. No. 10/265,295, filed Oct. 4, 2002, which claims the benefit of U.S. Provisional Patent Application No. 60/338,797 filed Nov. 22, 2001 and U.S. Provisional Patent Application No. 60/327,621 filed Oct. 5, 2001. Each of the foregoing referenced patent applications is incorporated by reference herein as if set forth below in its entirety.

### BACKGROUND OF THE INVENTION

1. Field of the Invention

The present invention relates to precursor compositions that are useful for the fabrication of electronic features such as conductors, resistors, inductors and capacitors. The precursor compositions can have a low conversion temperature to enable low-temperature treatment of the precursors to form electronic features on a variety of substrates. The precursor compositions can advantageously be deposited in a recessed feature formed in the substrate and subsequently converted to the electronic feature.

2. Description of Related Art

A variety of materials are used to create electronic circuitry on a substrate. Examples include metals and other conductive materials for electrical conductors, dielectric materials for insulation and capacitive elements, resistive materials for resistors, ferroelectric materials for capacitive elements and magnetic materials for inductors.

Dielectric materials have a wide variety of applications in electronic circuits. They are used to provide electrical insulation as well as to facilitate the temporary storage of electrical charge. The dielectric constant, dielectric loss factor, and dielectric strength determine the suitability for a specific application. Variations in dielectric properties with frequency, temperature, and a range of environmental conditions such as humidity also play a role in determining the usefulness of any particular material composition.

Most resistors for integrated electronic applications are required to be ohmic, to display small deviations from their predetermined value (tolerance), and to have small temperature coefficients of resistance (TCR). TCR is an expression of change in resistance due to change in temperature and it is expressed in parts per million per degree Celsius (ppm/° C.). The TCR of conductive and semiconductive materials can be either positive (increasing resistance with increase in temperature) or negative (decreasing resistance with increasing temperature).

The major demand for resistors in electronic applications lies in the resistance range from 10³ to 10⁸Ω. This is a serious challenge, as pure materials with suitable and reliable electrical behavior typically have resistivities below about 10⁻⁶ Ω-m. Unfortunately there are no pure, single-phase materials that provide optimum properties for ohmic resistors. The key to producing a resistor with a specific resistivity and low TCR lies in tailoring composition and microstructure of the final product.

Commercial ferrite applications usually require a high permeability and/or saturation magnetization. Short magnetic switching times are also highly desirable. Ceramic magnetic materials are currently being used in the fast growing area of high-frequency solid-state devices. The higher resistivity of these ferromagnetic oxides gives them a decisive advantage over magnetic metals. Lowering the high frequency loss is a challenge and many of the properties are sensitive to the effects of heat treatment and composition. For instance, a surplus or deficiency of Fe ions of a few percent can change the resistivity of a magnetic ceramic by several orders of magnitude. Eddy-current losses can be controlled by improving the resistivity of the ferrite. In a more general sense, phase purity, proper oxidation state, large grain size and low porosity all contribute strongly to lowering the loss in ferrites.

The electronics industry relies on printing of patterns of various materials onto substrates to form circuits. The primary methods for printing of these patterns are screen-printing for features larger than 100 μm and thin film approaches for features less than 100 μm. Other subtractive processes are available for feature sizes less than 100 μm. These include photo-patternable pastes, laser trimming, and others.

U.S. Pat. No. 5,801,108 by Huang et al. discloses dielectric pastes formulated from starting materials including a dielectric powder composition, a glass composition such as a borosilicate glass that will melt at about 500° C. to 600° C. and react with the dielectric powder upon firing and partially form a crystallized phase, and a binding material such as an organic binder. The resulting dielectric precursor is a multiphase, dielectric precursor wherein at least one phase is an alkaline earth, transition metal silicate. It is also disclosed that when the dielectric powder to crystallizable glass ratio is approximately 60 to 40 wt. %, then the resulting mixture will densify at approximately 850° C.

Precursor derived printable electronic compositions are described by R. W. Vest (Metallo-organic materials for improved thick film reliability, Nov. 1, 1980, Final Report, Contract #N00163-79-C-0352, National Avionic Center). These compositions were not designed for processing at low temperatures and the processing temperatures were high, such as greater than 250° C. Further, Vest described only compositions that contained precursors and a solvent; the use of pastes including particles or particles and precursors is not disclosed.

U.S. Pat. Nos. 6,036,889 and 5,882,722 by Kydd disclose conductor precursor compositions that contain particles, a metal organic decomposition (MOD) precursor and a vehicle and provide pure conductors at low temperatures on organic substrates. However, materials to form dielectrics, resistors, and ferrite materials are not disclosed. Also, formulations for fine mesh screen printing are not disclosed.

U.S. Pat. No. 6,197,366 by Takamatsu discloses methods using inorganometallic compounds to obtain formulations that convert to dense solid metals at low temperatures.

Polymer thick film materials containing particles in a polymerizable organic vehicle have also been disclosed in the prior art. These compositions are processable at low temperatures, such as less than 200° C., allowing deposition onto organic substrates. However, these compositions are not designed for fine feature sizes such as those have a resolution of less than 200 μm. Polymer thick film also has limited performance and suffers from poor stability in changing environments. Attempts have been made to produce metal-containing compositions at low temperatures by using a composition including a polymer and a precursor to a metal. See, for example, U.S. Pat. No. 6,019,926, by Southward et al. However, the deposits were chosen for optical properties and were either not conductive or poorly conductive.

U.S. Pat. Nos. 5,846,615 and 5,894,038, both by Sharma et al., disclose precursors to Au and Pd that have low reaction temperatures thereby conceptually enabling processing at low temperatures to form metals. The printing of these compositions, however, is not disclosed in detail.

U.S. Pat. No. 5,332,646 by Wright et al. discloses a method of making colloidal palladium and/or platinum metal dispersions by reducing a palladium and/or platinum metal of a metallo-organic palladium and/or platinum metal salt which lacks halide functionality. However, formulations for depositing electronic materials for resistors are not disclosed.

Attempts have been made to form conductive electronic features in a substrate by applying a paste or other precursor composition to a groove or trench formed in the substrate.

U.S. Pat. No. 4,270,823 discloses a method for forming conductive lines in grooves. The method requires a leveling step to insure that the spacing from the top of the groove to the conductor within is constant. This step requires that the grooves are in parallel relation and doesn't allow for patterning. The conductive lines are created from a mixture of metal powders and glass frit, and are densified by melting the glass phase.

U.S. Pat. No. 4,336,320 discloses a method for forming conductive features by putting grooves into a layer and filling those grooves with a conductive paste. The method involves photopatterning of a deposited commercial dielectric paste layer, creating channels with photopatterning and then filling with a commercial paste. The process is for high temperature processing and there is no description of the method for filling of the grooves.

U.S. Pat. No. 4,508,753 discloses a method for producing fine line conductive or resistive patterns on an insulative coating. The method involves application of an insulating coating to a substrate (insulating or non-insulating), then stamping, machining or laser engraving a pattern of grooves into the coating, filling the grooves with a conductive or resistive paste, wiping off the excess paste and then firing. Lapping or abrading the surface prior to firing may also be used to eliminate excess paste from the surface of the insulating layer.

U.S. Pat. No. 4,508,754 discloses a method similar to U.S. Pat. No. 4,508,753 without the step requiring the initial coating of the substrate. Grooves are cut into a dielectric substrate and then filled with a conductive or resistive paste. The surface is then cleaned and the device is fired.

U.S. Pat. No. 4,756,929 discloses a method for effectively increasing the density of printed wiring patterns by moving away from a planar approach. This patent describes the benefit of creating high aspect ratio grooves and coating them to produce effectively wider conductor traces than the footprint they have on the substrate. The invention relies on photopatterning and electroless plating to accomplish this goal.

U.S. Pat. No. 4,931,323 discloses copper lines patterned with a laser.

U.S. Pat. No. 5,153,023 discloses catalysis of electroless metal plating on plastic. A laser is used to pattern a precursor on a low temperature polymer substrate.

U.S. Pat. No. 5,366,760 discloses filled intaglio picked up on roller and then printed onto desired substrate.

U.S. Pat. No. 5,384,953 discloses milling grooves to act as catch basins for repairing electrical lines without shorting into other lines.

U.S. Pat. No. 6,251,471 discloses a method for the creation of electrical feedthroughs by milling a groove into a substrate and filling that groove with a conductive film. The patent requires that the groove be at least 0.005″ deep, and the final structure requires a mechanical grinding to level the surface of the substrate and conducting line.

U.S. Pat. No. 4,897,676 discloses a high density circuit comprising a plurality of conductors formed by filling a pattern of grooves in a substrate. The conductive feature size is below 0.005″ along with depth of ⅓ to ⅔ the width and a spacing between conductors of 0.005″. Patterning multiple layers to form a circuit is also disclosed.

U.S. Pat. No. 5,716,663 discloses a method for forming a multilayer printed circuit board by forming grooves in a substrate, filling the grooves with ink, heating to form conductive traces, forming vias in a similar manner, overcoating with a dielectric, forming grooves in the dielectric and repeating the process used for the first conductor features. A processing temperature of from about 100° C. to 350° C. is disclosed. The conductive lines are created from a mixture of metal powders and polymer.

U.S. Pat. No. 5,747,222 discloses a method for forming a multilayer printed circuit board by forming grooves in a substrate using a photopatterned layer, filling the grooves at least partially with ink, overcoating and repeating the process and then combining this with a top thin film layer. The conductive lines not made by thin film approaches in this patent are created from a mixture of metal powders and polymer.

U.S. Pat. No. 4,912,844 discloses a method for forming a printed circuit board comprising the steps of forming grooves in a substrate and filling the grooves with a conductive material. The conductive lines were made using a solder type composition, an approach that does not provide the high conductivity afforded by metals such as silver.

U.S. Pat. No. 6,200,405 discloses a method for forming a multilayer ceramic electronic component by forming a conductor pattern in a groove on the ceramic green sheet. This application requires high firing temperatures, close to 800° C. Thus, an approach combining fabrication of fine features, high conductivity, low processing temperature, and high reliability was not disclosed.

There exists a need for precursor compositions to electronic materials for use in electronics, displays, and other applications. Further, there is a need for precursor compositions that provide low processing temperatures to allow deposition onto organic substrates while still providing a feature with high conductivity. Furthermore, there exists a need for a precursor compositions and deposition methods that offer enhanced resolution control.

### DESCRIPTION OF THE INVENTION

The present invention is directed to precursor compositions that can be deposited onto a substrate and converted to an electronic material. The precursor compositions preferably have a low conversion temperature, thereby enabling the formation of electronic features on a variety of substrates, including organic substrates. In a preferred embodiment, the precursor compositions are deposited into one or more recessed features in the substrate.

The precursor compositions according to the present invention can be formulated to have a wide range of properties and a wide range of relative cost. For example, in high volume applications that do not require well-controlled properties, inexpensive precursor compositions can be deposited on cellulose-based materials, such as paper, to form simple disposable circuits. On the other hand, the precursor compositions of the present invention can be utilized to form complex and high precision circuitry having good electrical properties.

The method for forming the electronic features according to the present invention can also make use of relatively low processing temperatures. Depending upon the materials included in the precursor composition, the conversion temperature can be not greater than 900° C., such as not greater than about 600° C. In one embodiment, the conversion temperature is not greater than about 400° C., such as not greater than about 350° C. and preferably not greater than about 250° C. The heating time can also be very short, such as not greater than about 5 minutes, more preferably not greater than about 1 minute and even more preferably not greater than about 10 seconds.

### Definitions

As used herein, the term precursor composition refers to a flowable composition that can be treated, such as by heating, to form an electronic feature. According to the present invention, the precursor composition is deposited into a recessed feature in a substrate and the viscosity of the composition is typically not critical. The viscosity will, however, affect the type of tool that can be used to deposit the precursor composition. In this regard, the precursor compositions can be formulated to have a high viscosity of at least about 1000 centipoise, such as at least 5000 centipoise. According to one embodiment, the precursor composition has a viscosity of greater than about 10,000 centipoise. Such compositions are commonly referred to as pastes. Alternatively, the precursor compositions can be formulated to have a low viscosity, such as not greater than about 1000 centipoise, to enable the deposition of the composition by methods such as ink-jet deposition. Such low viscosity compositions can have a viscosity of not greater than 500 centipoise, preferably not greater than 100 centipoise and even more preferably not greater than 50 centipoise. As used herein, the viscosity is measured under the relevant deposition conditions. For example, some precursor compositions may be heated prior to and/or during deposition to reduce the viscosity.

As used herein, the term molecular precursor refers to a molecular compound that includes a metal atom. Examples include organometallics (molecules with carbon-metal bonds), metal organics (molecules containing organic ligands with metal bonds to other types of elements such as oxygen, nitrogen or sulfur) and inorganic compounds such as metal nitrates, metal halides and other metal salts.

As used herein, the term precursor solution refers to a precursor or a mixture of precursors dissolved in a solvent. A solvent is a flowable chemical that is capable of dissolving at least a portion of the molecular precursor. The precursor solution can also include other additives such as crystallization inhibitors, reducing agents, and agents that reduce the conversion (e.g., decomposition) temperature of the molecular precursors.

In addition to the precursor solution, the precursor composition can include particulates of one or several materials. The particulates can fall in two size ranges referred to herein as nanoparticles and micron-size particles. Nanoparticles have an average size of not greater than about 100 nanometers, and typically have an average size ranging from about 10 to 80 nanometers. Micron-size particles have an average particle size of greater than about 0.1 μm, typically greater than about 0.3 μm such as from about 0.3 μm to 3 μm. Nanoparticles and micron-size particles are collectively referred to herein as particles or powders.

The precursor compositions can also include a vehicle. As used herein, a vehicle is a flowable medium that facilitates deposition of the precursor composition, such as by imparting sufficient flow properties to the composition. As will be appreciated from the following discussion, the same chemical can have multiple functions, such as one that is both a solvent and a vehicle.

Other materials, referred to simply as additives, can also be included in the precursor compositions of the present invention. As is discussed below, such additives can include, but are not limited to, crystallization inhibitors, polymers, polymer precursors (monomers), reducing agents, binders, dispersants, surfactants, thickening agents and the like.

The precursor compositions according to the present invention can be deposited into a recessed feature on a substrate and converted to the electronic material. As used herein, recessed feature includes features that are formed below the top surface of the substrate and do not go all the way through the substrate (e.g., a trench) as well as features that go all the way through the substrate (e.g., a via).

### Precursor Compositions

As is discussed above, the precursor compositions according to the present invention can optionally include particulates in the form of nanoparticles and/or micron-size particles.

Nanoparticles have an average size of not greater than about 100 nanometers, such as from about 10 to 80 nanometers. Particularly preferred for the precursor compositions of the present invention are nanoparticles having an average size of at least about 75 nanometers, such as in the range of from about 25 to 75 nanometers.

Nanoparticles that are particularly preferred for use in the present invention are not substantially agglomerated. Preferred nanoparticle compositions include Al₂O₃, CuOₓ, SiO₂ and TiO₂, conductive metal oxides such as In₂O₃, indium-tin oxide (ITO) and antimony-tin oxide (ATO), silver, palladium, copper, gold, platinum and nickel. Other useful nanoparticles of metal oxides include pyrogenous silica such as HS-5 or M5 or others (Cabot Corp., Boston, Mass.) and AEROSIL 200 or others (Degussa AG, Dusseldorf, Germany) or surface modified silica such as TS530 or TS720 (Cabot Corp., Boston, Mass.) and AEROSIL 380 (Degussa AG, Dusseldorf, Germany). In one embodiment of the present invention, the nanoparticles are composed of the same metal that is contained in the metal precursor compound, discussed below. Nanoparticles can be fabricated using a number of methods and one preferred method, referred to as the Polyol process, is disclosed in U.S. Pat. No. 4,539,041 by Figlarz et al., which is incorporated herein by reference in its entirety.

Preferred compositions of micron-size particles are similar to the compositions described above with respect to nanoparticles. Generally, the volume median particle size of the micron-size particles is at least about 0.1 μm, such as at least about 0.3 μm. Further, the median particle size is preferably not greater than about 20 μm. For most applications, the volume median particle size is more preferably not greater than about 10 μm and even more preferably not greater than about 5 μm. A particularly preferred median particle size is from about 0.3 μm to about 3 μm. According to one embodiment of the present invention, it is preferred that the volume median particle size of the micron-size particles is at least 10 times smaller than the orifice diameter of a tool depositing the precursor, such as not greater than about 5 μm for syringe-dispense device having a 50 μm orifice. As used herein, the term “average” particle size refers to the volume median particle size.

The shape of the particles can be varied from completely spherical such as those produced by spray pyrolysis to flakes that are leaf-like in shape with very large aspect ratios. Particles can also be any oblong shape in between spheres and flakes. When substantially spherical particles are described, the particle size refers to the particle diameter, when flakes are described, the particle size refers to the largest dimension measure across such a particle. The presence of flakes can have an adverse effect on rheology and can result in clogging of a deposition tool orifice, such as a syringe dispense tool. Hence, flake content, flake particle size, flake agglomeration, and surface morphology are all well controlled in the present invention. In one embodiment, precursor compositions according to the present invention do not include any flakes.

According to a preferred embodiment of the present invention, the particles (nanoparticles and micron-size particles) also have a narrow particle size distribution, such that the majority of particles are about the same size. For micron-size particles, this will reduce clogging in the mesh opening for a screen-printing tool or the channel in a syringe dispense tool. Preferably, at least about 70 volume percent and more preferably at least about 80 volume percent of the particles are not larger than twice the average particle size. For example, when the average particle size of micron-size particles is about 2 μm, it is preferred that at least about 70 volume percent of the micron-size particles are not larger than 4 μm and it is more preferred that at least about 80 volume percent of the micron-size particles are not larger than 4 μm. Further, it is preferred that at least about 70 volume percent and more preferably at least about 80 volume percent of the particles are not larger than about 1.5 times the average particle size. Thus, when the average particle size of the micron-size particles is about 2 μm, it is preferred that at least about 70 volume percent of the micron-size particles are not larger than 3 μm and it is more preferred that at least about 80 volume percent of the micron-size particles are not larger than 3 μm.

It is known that micron-size particles and nanoparticles often form soft agglomerates as a result of their relatively high surface energy, as compared to larger particles. It is also known that such soft agglomerates may be dispersed easily by treatments such as exposure to ultrasound in a liquid medium, sieving, high shear mixing and 3-roll milling. The average particle size and particle size distributions described herein are measured by mixing samples of the powders in a liquid medium, such as water and a surfactant, and exposing the suspension to ultrasound through either an ultrasonic bath or horn. The ultrasonic treatment supplies sufficient energy to disperse the soft agglomerates into primary particles. The primary particle size and size distribution are then measured by light scattering in a MICROTRAC instrument. Thus, the references to particle size herein refer to the primary particle size, such as after lightly dispersing soft agglomerates of the particles.

It is also possible according to the present invention to provide micron-size particles, nanoparticles, or combinations of these, having a bimodal particle size distribution. That is, the particles can have two distinct and different average particle sizes. Preferably, each of the distinct particle size distributions will meet the foregoing size distribution limitations. A bimodal particle size distribution can advantageously enhance the packing efficiency of the particles when deposited according to the present invention. The two modes can include particles having different compositions. In one embodiment, the two modes have average particle sizes at about 1 μm and 5 μm, and in another embodiment the average particle size of the modes are at about 0.5 μm and 2.5 μm. The bimodal particle size distribution can also be achieved using nanoparticles and in another embodiment, the larger mode has an average particle size of 1 μm to 10 μm and the smaller mode has an average particle size of from about 10 to 100 nanometers.

The particles that are useful in the precursor compositions according to the present invention also have a high degree of purity and it is preferred that the particles include not greater than about 1.0 atomic percent impurities and more preferably not greater than about 0.1 atomic percent impurities and even more preferably not greater than about 0.01 atomic percent impurities. Impurities are those materials that are not intended in the final product and that negatively affect the properties of the final product. For many electronic materials, the most critical impurities to avoid are Na, K, Cl, S and F. It will be appreciated that the particles can include composite particles having one or more second phases. Such second phases are not considered impurities.

The particles for use in the precursor compositions according to the present invention can also be coated particles wherein the particle includes a surface coating surrounding the particle core. Coatings can be generated on the particle surface by a number of different mechanisms. One preferred mechanism is spray pyrolysis. One or more coating precursors can vaporize and fuse to the hot particle surface and thermally react resulting in the formation of a thin film coating by chemical vapor deposition (CVD). Preferred coatings deposited by CVD include metal oxides and elemental metals. Further, the coating can be formed by physical vapor deposition (PVD) wherein a coating material physically deposits on the surface of the particles. Preferred coatings deposited by PVD include organic materials and elemental metals. Alternatively, a gaseous precursor can react in the gas phase forming small particles, for example, less than about 5 nanometers in size, which then diffuse to the larger particle surface and sinter onto the surface, thus forming a coating. This method is referred to as gas-to-particle conversion (GPC). Whether such coating reactions occur by CVD, PVD or GPC is dependent on the reactor conditions, such as temperature, precursor partial pressure, water partial pressure and the concentration of particles in the gas stream. Another possible surface coating method is surface conversion of the particles by reaction with a vapor phase reactant to convert the surface of the particles to a different material than that originally contained in the particles.

In addition, a volatile coating material such as lead oxide, molybdenum oxide or vanadium oxide can be introduced into a reactor containing the particles such that the coating deposits on the particles by condensation. Further, the particles can be coated using other techniques. For example, soluble precursors to both the particle and the coating can be used in the precursor solution of a spray pyrolysis process. In another embodiment, a colloidal precursor and a soluble precursor can be used to form a particulate colloidal coating on the composite particle. It will be appreciated that multiple coatings can be deposited on the surface of the particles if such multiple coatings are desirable.

The coatings are preferably as thin as possible while maintaining conformity about the particles such that the core of the particle is not substantially exposed. For example, the coatings on a micron-size particle can have an average thickness of not greater than about 200 nanometers, preferably not greater than about 100 nanometers and more preferably not more than about 50 nanometers. For most applications, the coating has an average thickness of at least about 5 nanometers.

For example, copper particles can be coated with another metal such as silver to stabilize the surface against oxidation during heat treatment of the precursor. Alternatively, silver particles can be coated with one or more metals such as copper, silver/palladium or silver/platinum to increase the solder leach resistance while maintaining high conductivity. Another preferred example of a coated particle is Ag coated with a silica coating. This will prevent particle agglomeration during production and formulation into a precursor. The coating can act as a sintering delay barrier in certain specific applications. When formulated into a silver precursor, the silica coating can have a positive impact on precursor composition flowability and the minimum feature size of the features formed using the precursor.

In addition to the foregoing, the particles can be coated after deposition of the precursor onto the substrate by a molecular precursor, such as a metallo-organic precursor, contained in the precursor composition. In this case, the coating will form during heat treatment of the precursor.

Nanoparticles can also be coated with the coating methods described above. In addition, it may be advantageous to coat nanoparticles with materials such as a polymer to prevent agglomeration of the nanoparticles due to high surface energy. This is described by P. Y. Silvert et al. (Preparation of colloidal silver dispersions by the polyol process, Journal of Material Chemistry, 1997, volume 7 (2), pp. 293-299). In another embodiment of the present invention, the particles can be coated with an intrinsically conductive polymer, preventing agglomeration in the precursor and providing a conductive patch after solidification of the precursor. In yet another embodiment, the polymer can decompose during heating enabling the nanoparticles to sinter together. In one embodiment, the nanoparticles are generated in-situ and are coated with a polymer. Preferred coatings for nanoparticles according to the present invention include polystyrene, polystyrene/methacrylate, polyvinyl pyrolidone, sodium bis(2-ethylhexyl) sulfosuccinate, tetra-n-octyl-ammonium bromide and alkane thiolates.

The particles that are useful with the present invention can also be “capped” with other compounds. The term capped refers to having compounds bonded to the outer surface of the particles without necessarily creating a coating over the outer surface. The particles used with the present invention can be capped with any functional group including organic compounds such as polymers, organometallic compounds, and metal organic compounds. These capping agents can serve a variety of functions including the prevention of agglomeration of the particles, prevention of oxidation, enhancement of bonding of the particles to a surface, and enhancement of the flowability of the particles in a precursor composition. Preferred capping agents that are useful with the particles of the present invention include amine compounds, organometallic compounds, and metal organic compounds.

The particulates in accordance with the present invention can also be composite particles wherein the particles include a first phase and a second phase associated with the first phase. Preferred composite particulates include carbon-metal, carbon-polymer, carbon-ceramic, carbon1-carbon2, ceramic-ceramic, ceramic-metal, metal1-metal2, metal-polymer, ceramic-polymer, and polymer1-polymer2. Also preferred are certain 3-phase combinations such as metal-carbon-polymer. In one embodiment, the second phase is uniformly dispersed throughout the first phase. The second phase can be conductive compound or it can be a non-conductive compound. For example, sintering inhibitors such as metal oxides can be included as a second phase in a first phase of a metallic material, such as silver metal to inhibit sintering of the metal without substantially affecting the conductivity.

The particulates according to a preferred embodiment of the present invention are also substantially spherical in shape. That is, the particulates are not jagged or irregular in shape. Spherical particles are particularly advantageous because they are able to disperse more readily in a precursor composition and impart advantageous flow characteristics to the precursor composition. For a given level of solids-loading, a precursor composition having spherical particles will have a lower viscosity than a composition having non-spherical particles. Spherical particles are also less abrasive than jagged particles.

Micron-size particles in accordance with the foregoing can be produced, for example, by spray pyrolysis. Spray pyrolysis for production of micron-size particles is described in U.S. Pat. No. 6,103,393 by Kodas, et al., which is incorporated herein by reference in its entirety.

The application of passive electronic components on flexible and/or low temperature substrates such as polyimide requires new approaches and concepts for the development of suitable precursor chemistries and formulations. Low temperature substrate materials require low precursor conversion temperatures.

One method according to the present invention for formulating compositions for fabrication of conductive, resistive and dielectric circuit components utilizes suitable molecular precursors that can be converted to functional components. In the past, significant progress has been made in the development of metal organic precursors for printing conductors, dielectrics and resistors. See, for example, “Chemical aspects of solution routes to perovskite-phase mixed-metal oxides from metal-organic precursors”, C. D. Chandler, C Roger, and M. J. Hampden-Smith, Chem. Rev 93, 1205-1241 (1993). The chemical precursor to the functional phase should convert to the final material at a low temperature. The formulations should be easy to synthesize, environmentally benign, provide clean elimination of inorganic or organic ligands and be compatible with other precursor constituents. Other factors are solubility in various solvents, stability during the delivery process, homogeneous film formation, good adhesion to the substrate, high ceramic yield, and shelf life. If a laser is used for precursor conversion, the precursor material should be highly absorptive at the laser wavelength being used to promote efficient laser energy coupling allowing for decomposition at low laser power. This will prevent substrate damage during laser processing.

The metal-ligand bond is a key factor in designing the metal organic precursors. For conductive phases in low-ohm resistors, this bond should be reactive enough to permit complete elimination of the ligand during formation of metallic features for conductors like silver, gold, nickel, copper, palladium or alloys of these elements. Typical precursor families include metal carboxylates, alkoxides, and diketonates including at least one metal oxygen bond. Depending on the metal, thiolates and amines can be specifically tailored to the required characteristics.

Deposition of electro-ceramic materials for dielectric, ferrite, and resistor applications requires precursors that are able to undergo clean and low temperature transformation to single oxides or mixed oxides. This is required to mimic the high-fire compositions currently being used in the electronic industry. Typical reaction mechanisms involved for these metal oxide based formulations are condensation, polymerization, or elimination reactions of alkoxides typically used in sol gel processes. Other reaction routes involve ether, carboxylic anhydride, or ester elimination.

The present invention is also directed to the specific combinations of precursors, additives and solvents for the successful conversion to the final material at low temperatures. Even if a conversion at low temperature with complete elimination of byproducts can be achieved, metal oxide materials may still need some higher temperature treatment for proper crystallization and consolidation. In contrast, important metals like silver, gold, palladium and copper can be deposited using carefully designed metal precursors at temperatures well below 200° C., in some cases even below 150° C. with good adhesion to polymeric substrates such as polyimide substrates. The lower deposition temperatures required for complex mixed metal oxides would result in structures with materials that have controlled stoichiometries and in some cases would afford kinetic routes to new meta-stable crystal structures.

Particularly preferred precursor compositions for conductive, dielectric and resistive features are described more fully below.

The precursor compositions according to the present invention can also include molecular metal precursors, either alone or in combination with particulates. Preferred examples include precursors to silver (Ag), nickel (Ni), platinum (Pt), gold (Au), palladium (Pd), copper (Cu), indium (In) and tin (Sn). Other molecular metal precursors can include precursors to aluminum (Al), zinc (Zn), iron (Fe), tungsten (W), molybdenum (Mo), ruthenium (Ru), lead (Pb), bismuth (Bi) and similar metals. The molecular metal precursors can be either soluble or insoluble in the precursor composition.

In general, molecular metal precursor compounds that eliminate ligands by a radical mechanism upon conversion to metal are preferred, especially if the species formed are stable radicals and therefore lower the decomposition temperature of that precursor.

Furthermore, molecular metal precursors containing ligands that upon precursor conversion eliminate cleanly and escape completely from the substrate (or the formed functional structure) are preferred because they are not susceptible to carbon contamination or contamination by anionic species such as nitrates. Therefore, preferred precursors for metals used for conductors are carboxylates, alkoxides or combinations thereof that would convert to metals, metal oxides or mixed metal oxides by eliminating small molecules such as carboxylic acid anhydrides, ethers or esters. Metal carboxylates, particularly halogenocarboxylates such as fluorocarboxylates, are particularly preferred metal precursors due to their high solubility.

Silver Precursors

Examples of silver metal precursors that can be used in the conductor precursor compositions according to the present invention are illustrated in Table 1.

TABLE 1
Silver Precursor Molecular Compounds and Salts

| General Class | Examples | Chemical Formula |
|---|---|---|
| Nitrates | Silver nitrate | AgNO₃ |
| Nitrites | Silver Nitrite | AgNO₂ |
| Oxides | Silver oxide | Ag₂O, AgO |
| Carbonates | Silver carbonate | Ag₂CO₃ |
| Oxalates | Silver oxalate | Ag₂C₂O₄ |
| (Pyrazolyl)borates | Silver trispyrazolylborate | Ag[(N₂C₃H₃)₃]BH |
| | Silver | Ag[((CH₃)₂N₂C₃H₃)₃]BH |
| | tris(dimethylpyrazolyl)borate | |
| Azides | Silver azide | AgN₃ |
| Fluoroborates | Silver tetrafluoroborate | AgBF₄ |
| Carboxylates | Silver acetate | AgO₂CCH₃ |
| | Silver propionate | AgO₂CC₂H₅ |
| | Silver butanoate | AgO₂CC₃H₇ |
| | Silver ethylbutyrate | AgO₂CCH(C₂H₅)C₂H₅ |
| | Silver pivalate | AgO₂CC(CH₃)₃ |
| | Silver cyclohexanebutyrate | AgO₂C(CH₂)₃C₆H₁₁ |
| | Silver ethylhexanoate | AgO₂CCH(C₂H₅)C₄H₉ |
| | Silver neodecanoate | AgO₂CC₉H₁₉ |
| Halogenocarboxylates | Silver trifluoroacetate | AgO₂CCF₃ |
| | Silver pentafluoropropionate | AgO₂CC₂F₅ |
| | Silver heptafluorobutyrate | AgO₂CC₃F₇ |
| | Silver trichloroacetate | AgO₂CCCl₃ |
| | Silver 6,6,7,7,8,8,8-heptafluoro- | AgFOD |
| | 2,2-dimethyl-3,5-octanedionate | |
| Hydroxycarboxylates | Silver lactate | AgO₂CH(OH)CH₃ |
| | Silver citrate | Ag₃C₆H₅O₇ |
| | Silver glycolate | AgOOCCH(OH)CH₃ |
| Aromatic and nitro | Silver benzoate | AgO₂CCH₂C₆H₅ |
| and/or fluoro substituted | Silver phenylacetate | AgOOCCH₂C₆H₅ |
| aromatic Carboxylates | Silver nitrophenylacetates | AgOOCCH₂C₆H₄NO₂ |
| | Silver dinitrophenylacetate | AgOOCCH₂C₆H₃(NO₂)₂ |
| | Silver difluorophenylacetate | AgOOCCH₂C₆H₃F₂ |
| | Silver 2-fluoro-5-nitrobenzoate | AgOOCC₆H₃(NO₂)F |
| Beta diketonates | Silver acetylacetonate | Ag[CH₃COCH═C(O—)CH₃] |
| | Silver hexafluoroacetylacetonate | Ag[CF₃COCH═C(O—)CF₃] |
| | Silver trifluoroacetylacetonate | Ag[CH₃COCH═C(O—)CF₃] |
| Silver sulfonates | Silver tosylate | AgO₃SC₆H₄CH₃ |
| | Silver triflate | AgO₃SCF₃ |

In addition to the foregoing, complex silver salts containing neutral inorganic or organic ligands can also be used as precursors. These salts are usually in the form of nitrates, halides, perchlorates, hydroxides or tetrafluoroborates. Examples are listed in Table 2.

TABLE 2
Complex Silver Salt Precursors

| Class | Examples (Cation) |
|---|---|
| Amines | [Ag(RNH₂)₂]⁺, Ag(R₂NH)₂]⁺, [Ag(R₃N)₂]⁺, |
| | R = aliphatic or aromatic |
| N-Heterocycles | [Ag(L)ₓ]⁺, (L = aziridine, pyrrol, indol, piperidine, |
| | pyridine, aliphatic substituted and amino substituted |
| | pyridines, imidazole, pyrimidine, piperazine, triazoles, |
| | etc.) |
| Amino alcohols | [Ag(L)ₓ]⁺, L = Ethanolamine |
| Amino acids | [Ag(L)ₓ]⁺, L = Glycine |
| Acid amides | [Ag(L)ₓ]⁺, L = Formamides, acetamides |
| Nitriles | [Ag(L)ₓ]⁺, L = Acetonitriles |

The molecular metal precursors can be utilized in an aqueous-based solvent or an organic solvent. Organic solvents are typically used for ink-jet deposition. Preferred molecular metal precursors for silver in an organic solvent include Ag-nitrate, Ag-neodecanoate, Ag-trifluoroacetate, Ag-acetate, Ag-lactate, Ag-cyclohexanebutyrate, Ag-carbonate, Ag-oxide, Ag-ethylhexanoate, Ag-acetylacetonate, Ag-ethylbutyrate, Ag-pentafluoropropionate, Ag-benzoate, Ag-citrate, Ag-heptafluorobutyrate, Ag-salicylate, Ag-decanoate and Ag-glycolate. Among the foregoing, particularly preferred molecular metal precursors for silver include Ag-acetate, Ag-nitrate, Ag-trifluoroacetate and Ag-neodecanoate. Most preferred among the foregoing silver precursors are Ag-trifluoroacetate and Ag-acetate. The preferred precursors generally have a high solubility and high metal yield. For example, Ag-trifluoroacetate has a solubility in dimethylacetamide of about 78 wt. % and Ag-trifluoroacetate is a particularly preferred silver precursor according to the present invention.

Preferred molecular silver precursors for aqueous-based solvents include Ag-nitrates, Ag-fluorides such as silver fluoride or silver hydrogen fluoride (AgHF₂), Ag-thiosulfate, Ag-trifluoroacetate and soluble diamine complexes of silver salts.

Silver precursors in solid form that decompose at a low temperature, such as not greater than about 200° C., can also be used. Examples include Ag-oxide, Ag-nitrite, Ag-carbonate, Ag-lactate, Ag-sulfite and Ag-citrate.

When a more volatile molecular silver precursor is desired, such as for spray deposition of the precursor composition, the precursor can be selected from alkene silver betadiketonates, R₂(CH)₂Ag([R′COCH═C(O—)CR″] where R=methyl or ethyl and R′, R″=CF₃, C₂F₅, C₃F₇, CH₃, CₘH₂ₘ₊₁ (m=2 to 4), or trialkylphosphine and triarylphosphine derivatives of silver carboxylates, silver beta diketonates or silver cyclopentadienides.

Molecular metal precursors for nickel that are preferred according to the present invention are illustrated in Table 3. A particularly preferred nickel-precursor for use with an aqueous-based solvent is Ni-acetylacetonate.

TABLE 3
Molecular Precursors for Nickel Metal

| General Class | Example | Chemical Formula |
|---|---|---|
| Inorganic Salts | Ni-nitrate | Ni(NO₃)₂ |
| | Ni-sulfate | NiSO₄ |
| | Nickel ammine complexes | [Ni(NH₃)₆]ⁿ⁺ (n = 2, 3) |
| | Ni-tetrafluoroborate | Ni(BF₄)₂ |
| Metal Organics | Ni-oxalate | NiC₂O₄ |
| (Alkoxides, Beta- | Ni-isopropoxide | Ni(OC₃H₇)₂ |
| diketonates, | Ni-methoxyethoxide | Ni(OCH₂CH₂OCH₃)₂ |
| Carboxylates, | Ni-acetylacetonate | [Ni(acac)₂]₃ or |
| Fluorocarboxylates | | Ni(acac)₂(H₂O)₂ |
| | Ni-hexafluoroacetylacetonate | Ni[CF₃COCH═C(O—)CF₃]₂ |
| | Ni-formate | Ni(O₂CH)₂ |
| | Ni-acetate | Ni(O₂CCH₃)₂ |
| | Ni-octanoate | Ni(O₂CC₇H₁₅)₂ |
| | Ni-ethylhexanoate | Ni(O₂CCH(C₂H₅)C₄H₉)₂ |
| | Ni-trifluoroacetate | Ni(OOCCF₃)₂ |

Various molecular precursors can be used for platinum metal. Preferred molecular precursors include ammonium salts of platinum such as ammonium hexachloro platinate (NH₄)₂PtCl₆, and ammonium tetrachloro platinate (NH₄)₂PtCl₄; sodium and potassium salts of halogeno, pseudohalogeno or nitrito platinates such as potassium hexachloro platinate K₂PtCl₆, sodium tetrachloro platinate Na₂PtCl₄, potassium hexabromo platinate K₂PtBr₆, potassium tetranitrito platinate K₂Pt(NO₂)₄; dihydrogen salts of hydroxo or halogeno platinates such as hexachloro platinic acid H₂PtCl₆, hexabromo platinic acid H₂PtBr₆, dihydrogen hexahydroxo platinate H₂Pt(OH)₆; diamine and tetramine platinum compounds such as diamine platinum chloride Pt(NH₃)₂Cl₂, tetramine platinum chloride [Pt(NH₃)₄]Cl₂, tetramine platinum hydroxide [Pt(NH₃)₄](OH)₂, tetramine platinum nitrite [Pt(NH₃)₄](NO₂)₂, tetramine platinum nitrate Pt(NH₃)₄(NO₃)₂, tetramine platinum bicarbonate [Pt(NH₃)₄](HCO₃)₂, tetramine platinum tetrachloroplatinate [Pt(NH₃)₄]PtCl₄; platinum diketonates such as platinum (II) 2,4-pentanedionate Pt(C₅H₇O₂)₂; platinum nitrates such as dihydrogen hexahydroxo platinate H₂Pt(OH)₆ acidified with nitric acid; other platinum salts such as Pt-sulfite and Pt-oxalate; and platinum salts comprising other N-donor ligands such as [Pt(CN)₆]⁴⁺.

Platinum precursors useful in organic-based precursor compositions include Pt-carboxylates or mixed carboxylates. Examples of carboxylates include Pt-formate, Pt-acetate, Pt-propionate, Pt-benzoate, Pt-stearate, Pt-neodecanoate. Other precursors useful in organic vehicles include aminoorgano platinum compounds including Pt(diaminopropane)(ethylhexanoate).

Preferred combinations of platinum precursors and solvents include : PtCl₄ in H₂O; Pt-nitrate solution from H₂Pt(OH)₆; H₂Pt(OH)₆ in H₂O; H₂PtCl₆ in H₂O; and [Pt(NH₃)₄](NO₃)₂ in H₂O.

Gold precursors that are particularly useful for aqueous based precursor compositions include Au-chloride (AuCl₃) and tetrachloric auric acid (HAuCl₄).

Gold precursors useful for organic based formulations include: Au-thiolates, Au-carboxylates such as Au-acetate Au(O₂CCH₃)₃; aminoorgano gold carboxylates such as imidazole gold ethylhexanoate; mixed gold carboxylates such as gold hydroxide acetate isobutyrate; Au-thiocarboxylates and Au-dithiocarboxylates.

In general, preferred gold molecular metal precursors for low temperature conversion are compounds comprising a set of different ligands such as mixed carboxylates or mixed alkoxo metal carboxylates. As one example, gold acetate isobutyrate hydroxide decomposes at 155° C., a lower temperature than gold acetate. As another example, gold acetate neodecanoate hydroxide decomposes to gold metal at even lower temperature, 125° C. Still other examples can be selected from gold acetate trifluoroacetate hydroxide, gold bis(trifluoroacetate) hydroxide and gold acetate pivalate hydroxide.

Other useful gold precursors include Au-azide and Au-isocyanide. When a more volatile molecular gold precursor is desired, such as for spray deposition, the precursor can be selected from:
dialkyl and monoalkyl gold carboxylates, R₃₋ₙAu(O₂CR′)ₙ (n=1,2) R=methyl, ethyl; R′=CF₃, C₂F₅, C₃F₇, CH₃, CₘH₂ₘ₊₁ (m=2-9)
dialkyl and monoalkyl gold beta diketonates, R₃₋ₙAu [R′COCH═C(O—)CR″]ₙ (n=1,2), R=methyl, ethyl; R′, R″=CF₃, C₂F₅, C₃F₇, CH₃, CₘH₂ₘ₊₁ (m=2-4)
dialkyl and monoalkyl gold alkoxides, R₃₋ₙAu(OR′)ₙ (n=1,2) R=methyl, ethyl; R′=CF₃, C₂F₅, C₃F₇, CH₃, CₘH₂₊₁ (m=2-4), SiR₃″ (R″=methyl, ethyl, propyl, isopropyl, n-butyl, isobutyl, tert. Butyl)
phosphine gold complexes:
   RAu(PR′₃) R, R′=methyl, ethyl, propyl, isopropyl, n-butyl, isobutyl, tert. Butyl,
R₃Au(PR′₃) R, R′=methyl, ethyl, propyl, isopropyl, n-butyl, isobutyl, tert. butyl.

Particularly useful precursors to palladium for organic based precursor compositions according to the present invention include Pd-carboxylates, including Pd-fluorocarboxylates such as Pd-acetate, Pd-propionate, PD-ethylhexanoate, Pd-neodecanoate and Pd-trifluoroacetate as well as mixed carboxylates such as Pd(OOCH)(OAc), Pd(OAc)(ethylhexanoate), Pd(ethylhexanoate)₂, Pd(OOCH)_{1.5} (ethylhexanoate)_{0.5}, Pd(OOCH)(ethylhexanoate), Pd(OOCCH(OH)CH(OH)COOH)ₘ (ethylhexanoate), Pd(OPr)₂, Pd(OAc)(OPr), Pd-oxalate, Pd(OOCCHO)ₘ(OOCCH₂OH)ₙ=(Glyoxilic palladium glycolate) and Pd-alkoxides. A particularly preferred palladium precursor is Pd-trifluoroacetate.

Palladium precursors useful for aqueous based precursor compositions include: tetramine palladium hydroxide [Pd(NH₃)₄](OH)₂; Pd-nitrate Pd(NO₃)₂; Pd-oxalate Pd(O₂CCO₂)₂; Pd-chloride PdCl₂; Di- and tetramine palladium chlorides, hydroxides or nitrates such as tetramine palladium chloride [Pd(NH₃)₄]Cl₂, tetramine palladium hydroxide [Pd(NH₃)₄](OH)₂, tetramine palladium nitrate [Pd(NH₃)₄](NO₃)₂, diamine palladium nitrate [Pd(NH₃)₂](NO₃)₂ and tetramine palladium tetrachloropalladate [Pd(NH₃)₄][PdCl₄].

When selecting a molecular copper precursor compound, it is desired that the compound react during processing to metallic copper without the formation of copper oxide or other species that are detrimental to the conductivity of the conductive copper feature. Some copper molecular precursors form copper by thermal decomposition at elevated temperatures. Other molecular copper precursors require a reducing agent to convert to copper metal. The introduction of the reducing agent can occur in the form of a chemical agent (e.g., formic acid) that is soluble in the precursor composition to afford a reduction to copper either during transport to the substrate or on the substrate. In some cases, the ligand of the molecular copper precursor has reducing characteristics, such as in Cu-formate or Cu-hypophosphite, leading to reduction to copper metal. However, formation of metallic copper or other undesired side reactions that occur prematurely in the ink or precursor composition should be avoided.

Accordingly, the ligand can be an important factor in the selection of suitable copper molecular precursors. During thermal decomposition or reduction of the precursor, the ligand needs to leave the system cleanly, preferably without the formation of carbon or other residues it could be incorporated into the copper feature. Copper precursors containing inorganic ligands are preferred in cases where carbon contamination is detrimental. Other desired characteristics for molecular copper precursors are low decomposition temperature or processing temperature for reduction to copper metal, high solubility in the selected solvent/vehicle to increase metallic yield and achieve dense features and the compound should be environmentally benign.

Preferred copper metal precursors according to the present invention include Cu-formate and Cu-neodecanoate. Molecular copper precursors that are useful for aqueous-based precursor compositions include: Cu-nitrate and amine complexes thereof; Cu-carboxylates including Cu-formate and Cu-acetate; and Cu beta-diketonates such as Cu-hexafluoroacetylacetonate and copper salts such as Cu-chloride.

Molecular copper precursors generally useful for organic based formulations include: Cu-carboxylates and Cu-fluorocarboxylates such as: Cu-formate; Cu-ethylhexanoate; Cu-neodecanoate; Cu-methacrylate; Cu-trifluoroacetate; Cu-hexanoate; and copper beta-diketonates such as cyclooctadiene Cu hexafluoroacetylacetonate.

Among the foregoing, Cu-formate is particularly preferred as it is highly soluble in water and results in the in-situ formation of formic acid, which is an effective reducing agent.

As is discussed above, two or more molecular metal precursors can be combined to form metal alloys and/or metal compounds. Preferred combinations of metal precursors to form alloys based on silver include: Ag-nitrate and Pd-nitrate; Ag-acetate and [Pd(NH₃)₄](OH)₂; Ag-trifluoroacetate and [Pd(NH₃)₄](OH)₂; and Ag-neodecanoate and Pd-neodecanoate. One particularly preferred combination of molecular metal precursors is Ag-trifluoroacetate and Pd-trifluoroacetate. Another preferred alloy is Ag/Cu.

To form alloys, the two (or more) molecular metal precursors should have similar decomposition temperatures to avoid the formation of one of the metal species before the other species. Preferably, the decomposition temperatures of the different molecular metal precursors are within 50° C., more preferably within 25° C.

The conductor precursor compositions according to the present invention can also include a solvent capable of solubilizing the molecular metal precursor discussed above. The solvent can be water thereby forming an aqueous-based precursor composition. Water is more environmentally acceptable as compared to organic solvents. However, water cannot typically be used for deposition of the precursor composition onto hydrophobic substrates, such as tetrafluoroethylene fluorocarbon substrates (e.g., TEFLON, E.I. duPont deNemours Wilmington, Del.), without modification of the substrate or the aqueous composition.

The solvent can also include an organic solvent, by itself or in addition to water. The selected solvent should be capable of solubilizing the selected molecular metal precursor to a high level. A low solubility of the molecular metal precursor in the solvent leads to low yields of the conductor, thin deposits and low conductivity. The precursor compositions of the present invention exploit combinations of solvents and precursors that advantageously provide high solubility of the molecular precursor while still allowing low temperature conversion of the precursor to the conductor.

According to one embodiment of the present invention, the solubility of the molecular metal precursor in the solvent is preferably at least about 20 weight percent metal precursor, more preferably at least 40 weight percent metal precursor, even more preferably at least about 50 weight percent metal precursor and most preferably at least about 60 weight percent metal precursor. Such high levels of metal precursor lead to increased metal yield and the ability to deposit features having adequate thickness.

In some cases, the solvent can be a high melting point solvent, such as one having a melting point of at least about 30° C. and not greater than about 100° C. In this embodiment, a heated ink-jet head can be used to deposit the precursor composition while in a flowable state whereby the solvent solidifies upon contacting the substrate. Subsequent processing can then remove the solvent by other means and then convert the material to the final product, thereby retaining resolution. Preferred solvents according to this embodiment are waxes, high molecular weight fatty acids, alcohols, acetone, N-methyl-2-pyrrolidone, toluene, tetrahydrofuran (THF) and the like. Alternatively, the precursor composition may be a liquid at room temperature, wherein the substrate is kept at a lower temperature below the freezing point of the composition.

The solvent can also be a low melting point solvent. A low melting point is required when the precursor composition must remain as a liquid on the substrate until dried. A preferred low melting point solvent according to this embodiment is DMAc, which has a melting point of about −20° C.

In addition, the solvent can be a low vapor pressure solvent. A lower vapor pressure advantageously prolongs the work life of the composition in cases where evaporation in the ink-jet head, syringe or other tool leads to problems such as clogging. A preferred solvent according to this embodiment is terpineol. Other low vapor pressure solvents include diethylene glycol, ethylene glycol, hexylene glycol, N-methyl-2-pyrrolidone, and tri(ethylene glycol) dimethyl ether.

The solvent can also be a high vapor pressure solvent, such as one having a vapor pressure of at least about 1 kPa. A high vapor pressure allows rapid removal of the solvent by drying. Other high vapor pressure solvents include acetone, tetrahydrofuran, toluene, xylene, ethanol, methanol, 2-butanone, and water.

The solvents can be polar or non-polar. Solvents that are useful according to the present invention include amines, amides, alcohols, water, ketones, unsaturated hydrocarbons, saturated hydrocarbons, mineral acids organic acids and bases, Preferred solvents include alcohols, amines, amides, water, ketone, ether, aldehydes and alkenes. Particularly preferred organic solvents according to the present invention for use with metal carboxylate compounds include N,N,-dimethylacetamide (DMAc), diethyleneglycol butylether (DEGBE), ethanolamine and N-methylpyrrolidone.

As is discussed above, a vehicle is a flowable medium that facilitates the deposition of the precursor composition. In cases where the liquid serves only to carry particles and not to dissolve molecular species, the terminology of vehicle is often used for the liquid. However, in many precursor compositions, the solvent can also be considered the vehicle. The metal, such as silver, can be bound to the vehicle, for example, by synthesizing a silver derivative of terpineol that simultaneously acts as both a precursor to silver and as a vehicle. This improves the metallic yield and reduces the porosity of the conductive feature.

Examples of preferred vehicles are listed in Table 4. Particularly preferred vehicles according to the present invention can include alpha terpineol, toluene and ethylene glycol.

TABLE 4
Organic Vehicles Useful in Precursor Compositions

| Formula/Class | Name |
|---|---|
| Alcohols | 2-Octanol |
| | Benzyl alcohol |
| | 4-hydroxy-3methoxy benzaldehyde |
| | Isodeconol |
| | Butylcarbitol |
| Terpene alcohol | Alpha-terpineol |
| | Beta-terpineol |
| | Cineol |
| Esters | 2,2,4 trimethylpentanediol-1,3 |
| | monoisobutyrate |
| | Butyl carbitol acetate |
| | Butyl oxalate |
| | Dibutyl phthalate |
| | Dibutyl benzoate |
| | Butyl cellosolve acetate |
| | Ethylene glycol diacetate |
| | Ethylene glycol diacetate |
| | N-methyl-2-pyrrolidone |
| Amides | N,N-dimethyl formamide |
| | N,N-dimethyl acetamide |
| Aromatics | Xylenes |
| | Aromasol |
| Substituted aromatics | Nitrobenzene |
| | o-nitrotoluene |
| Terpenes | Alpha-pinene, beta-pinene, dipentene, |
| | dipentene oxide |
| Essential Oils | Rosemary, lavender, fennel, sassafras, |
| | wintergreen, anise oils, camphor, turpentine |

The precursor compositions in accordance with the present invention can also include one or more polymers, co-polymers or polymer blends. The polymers can be thermoplastic polymers or thermoset polymers. Thermoplastic polymers are characterized by being fully polymerized. They do not take part in any reactions to further polymerize or cross-link to form a final product. Typically, such thermoplastic polymers are melt-cast, injection molded or dissolved in a solvent. Examples include polyimide films, ABS plastics, vinyl, acrylic, styrene polymers of medium or high molecular weight and the like.

The polymers can also be thermoset polymers, which are characterized by not being fully polymerized or cured. The components that make up thermoset polymers must undergo further reactions to form fully polymerized, cross-linked or dense final products. Thermoset polymers tend to be resistant to solvents, heat, moisture and light.

A typical thermoset polymer mixture initially includes a monomer, resin or low molecular weight polymer. These components require heat, hardeners, light or a combination of the three to fully polymerize. Hardeners are used to speed the polymerization reactions. Some thermoset polymer systems are two part epoxies that are mixed at consumption or are mixed, stored and used as needed.

Specific examples of thermoset polymers include amine or amide-based epoxies such as diethylenetriamine, polyglycoldianine and triethylenetetramine. Other examples include imidazole, aromatic epoxies, brominated epoxies, thermoset PET, phenolic resins such as bisphenol-A, polymide, acrylics, urethanes, and silicones. Hardeners can include isophoronediamine and meta-phenylenediamene.

The polymer can also be an ultraviolet or other light-curable polymer. The polymers in this category are typically UV and light-curable materials that require photoinitiators to initiate the cure. Light energy is absorbed by the photoinitiators in the formulation causing them to fragment into reactive species, which can polymerize or cross-link with other components in the formulation. In acrylate-based adhesives, the reactive species formed in the initiation step are known as free radicals. Another type of photoinitiator, a cationic salt, is used to polymerize epoxy functional resins generating an acid, which reacts to create the cure. Examples of these polymers-include cyanoacrylates such as z-cyanoacrylic acid methyl ester with an initiator as well as typical epoxy resin with a cationic salt.

The polymers can also be conductive polymers such as intrinsically conductive polymers. Conductive polymers are disclosed, for example, in U.S. Pat. No. 4,959,430 by Jonas et al., which is incorporated herein by reference in its entirety. Other examples of intrinsically conductive polymers are listed in Table 5 below.

TABLE 5
Intrinsically Conductive Polymers

| | | |
|---|---|---|
| Examples | Class/Monomers | Catalyst/Dopant |

Polyacetylene

| | | |
|---|---|---|
| Poly[bis(benzylthio) | Phenyl vinyl sulfoxide | Ti alkylidene |
| acetylene] | 1,3,5,7-Cyclooctatetraene | |
| Poly[bis(ethylthio)acetylene] | | |
| Poly[bis(methylthio)acetylene] | | |

Polyaniline

| | |
|---|---|
| Fully reduced | organic sulfonic acids such as: |
| Half oxidized | Dinonylnaphthalenedisulfonc |
| | acid |
| | Dinonylnaphthaleneusulfonic |
| | acid |
| | Dodecylbenzenesulfonic acid |

Poly(anilinesulfonic acid)

Self-doped state

Polypyrrole

Organic sulfonic acid

Polythiophene

| | |
|---|---|
| Poly(thiophine-2.5-diyl) | 2,5-Dibromo-3- |
| Poly(3-alkylthiophene-2.5- | alkyl/arylthiophene |
| diyl) | alkyl = butyl, hexyl, octyl, |
| alkyl = butyl, hexyl, octyl, | decyl, dodecyl |
| decyl, dodecyl | aryl = phenyl |
| Poly(styrenesulfonate)/poly- | Dibromodithiophene |
| (2,3-dihydrothieno-[3,4-b]- | Terthiophene |
| 1,4-dioxin) | Other substituted thiophenes |

Poly(1,4-phenylenevinylene)
(PPV)

p-Xylylenebis
(tetrahydrothiopheniumchloride))

Poly(1,4-phenylene sulfide)
Poly(fluroenyleneethynylene)

Other additives can be included in the conductor precursor compositions in accordance with the present invention. Among these are reducing agents to prevent the undesirable oxidation of metal species. Reducing agents are materials that are oxidized, thereby causing the reduction of another substance. The reducing agent loses one or more electrons and is referred to as having been oxidized. For example, copper and nickel metal have a strong tendency to oxidize. Precursor compositions adapted to form base metals, including nickel or copper, according to the present invention can include reducing agents as additives to provide reaction conditions for the formation of the metal at the desired temperature, rather than the metal oxide. Reducing agents are particularly applicable when using molecular metal precursor compounds where the ligand is not reducing by itself. Examples of reducing agents include amino alcohols and formic acid. Alternatively, the precursor conversion process can take place under reducing atmosphere, such as nitrogen, hydrogen or forming gas.

In some cases, the addition of reducing agents results in the formation of the metal even under ambient conditions. The reducing agent can be part of the precursor itself, for example in the case of certain ligands. An example is Cu-formate where the precursor forms copper metal even in ambient air at low temperatures. In addition, the Cu-formate precursor is highly soluble in water, results in a relatively high metallic yield and forms only gaseous byproducts, which are reducing in nature and protect the in-situ formed copper from oxidation. Cu-formate is therefore a preferred precursor for aqueous based precursor compositions. Other examples of molecular metal precursors containing a ligand that is a reducing agent are Ni-acetylacetonate and Ni-formate.

The compositions can also include crystallization inhibitors and a preferred crystallization inhibitor is lactic acid. Such inhibitors reduce the formation of large crystallites directly from the molecular metal precursor, which can be detrimental to conductivity. Other crystallization inhibitors include ethylcellulose and polymers such as styrene allyl alcohol (SAA) and polyvinyl pyrolydone (PVP). Other compounds useful for inhibiting crystallization are other polyalcohols such as malto dextrin, sodium carboxymethylcellulose and polyoxyethylenephenylether such as TRITON or IGEPAL. In general, solvents with a higher melting point and lower vapor pressure inhibit crystallization of a compound more than a lower melting point solvent with a higher vapor pressure. Preferably, not greater than about 10 wt. % crystallization inhibitor (as a percentage of the total composition) is added, more preferably not greater than 5 wt. % and even more preferably not greater than 2 wt. %.

The precursor compositions can also include an adhesion promoter adapted to improve the adhesion of the conductive feature to the underlying substrate. For example, polyamic acid can improve the adhesion of the composition to a polymer substrate. In addition, the precursor compositions can include rheology modifiers. As an example, styrene allyl alcohol (SAA) can be added to the precursor composition to reduce spreading on the substrate.

The precursor compositions can also include complexing agents. Complexing agents are a molecule or species that binds to a metal atom and isolates the metal atom from solution. Complexing agents are adapted to increase the solubility of the molecular precursors in the solvent, resulting in a higher yield of metal. One preferred complexing agent, particularly for use with Cu-formate and Ni-formate, is 3-amino-1-propanal. For example, a preferred precursor composition for the formation of copper includes Cu-formate dissolved in water and 3-amino-1-propanol.

The precursor compositions according to the present invention can also include a binder to maintain the shape of the deposited feature. The binder can be, for example, a polymer or in some cases can be a precursor compound. When the precursor composition is deposited onto a flexible substrate, the binder should impart some flexibility to the paste composition or final product in addition to adherence. In some instances, the binder can melt or soften to permit deposition of the precursor composition. According to one embodiment, the binder is a solid at room temperature and when heated to greater than about 50° C., the binder melts and flows allowing for ease of transfer and good wetting of the substrate. Upon cooling to room temperature, the binder becomes solid again maintaining the shape of the electronic feature.

The binder may need to vaporize during final processing. The binder may also dissolve during deposition. The binder is preferably stable at room temperature and does not degrade substantially over time.

Preferred binders for use in the precursor compositions according to the present invention include waxes, styrenic polymers, polyalkylene carbonates, polyvinyl acetals, cellulose based materials, tetradecanol, trimethylolpropane and tetramethylbenzene. The preferred binders have good solubility in a solvent used to formulate the paste composition and should be processable in the melt form. For example, styrene allyl alcohol (SAA) is soluble in dimethyleacetimide, solid at room temperature and becomes fluid-like upon heating to 80° C.

In many cases, the binders should decompose cleanly leaving little or no residuals after processing. Decomposition of the binder can occur by vaporization, sublimation or combustion.

The present invention also provides compositions and methods to increase adhesion of the electronic feature to the substrate. Various substrates have different surface characteristics that result in varying degrees of adhesion. The surface can be modified by hydroxylating or functionalizing the surface to provide reaction sites from the precursor compositions. In one embodiment, the surface of a polyfluorinated material is modified by a sodium naphthalenide solution that provides reactive sites for bonding during reaction with the precursor. In another embodiment, a thin layer of metal is sputtered onto the surface to provide for better adhesion of precursor or converted precursor to the substrate. In another embodiment, polyamic acid and the like precursors are added to the composition that then bond with both the conductor and surface to provide adhesion. Preferred amounts of polyamic acid and related compounds are determined from the specific application. For example an application where high conductivity is required a low loading of polyamic acid would be preferred, less than about 5 weight percent of the high viscosity paste. Another example is an application where flexibility is paramount, then the preferred polyamic acid would be around 10 to 20 weight percent of the precursor composition.

The precursor composition of the present invention can also include surfactants or dispersants. Dispersants are added to improve particle dispersion in the vehicle or solvent and reduce inter-particulate attraction within that dispersion. Dispersants are typically two-component structures, namely a polymeric chain and an anchoring group. The anchoring group will lock itself to the particle surface while the polymeric chain prevents agglomeration. It is the particular combination of these, which leads to their effectiveness. The molecular weight of the dispersant is sufficient to provide polymer chains of optimum length to overcome Van der Waals forces of attraction between particles. If the chains are too short, then they will not provide a sufficiently thick barrier to prevent flocculation, which in turn leads to an increase in viscosity. There is generally an optimum chain length over and above which the effectiveness of the stabilizing material ceases to increase. Ideally, the chains should be free to move in the dispersing medium. To achieve this, chains with anchor groups at one end only have shown to be the most effective in providing steric stabilization. An example of a dispersant is SOLSPERSE 21000 (Avecia Limited). For the precursor compositions of the present invention, surfactants should be selected to be compatible with the other components of the composition, particularly the precursor compounds. In one embodiment of the present invention, surfactants can serve multiple functions such as a dispersant and a precursor to a conductive phase. Another example of a surfactant that is used with silver flake particles is a coupling agent such as Kennrich Titanate.

The precursor compositions of the present invention can in addition include rheology modifiers such as additives that have a thickening effect on the liquid vehicle. The advantageous effects of these additives include improved particle dispersion, reduced settling of particles, and reduction or elimination of filter pressing during syringe dispensing or screen-printing. Rheology modifiers can include SOLTHIX 250 (Avecia Limited), styrenic polymers, cellulose based materials, polyalkylene carbonates and the like.

In accordance with the foregoing, the conductor precursor compositions according to the present invention can include combinations of particles (nanoparticles and/or micro-size particles), molecular metal precursor compounds, solvents, vehicles, reducing agents, crystallization inhibitors, adhesion promoters, complexing agents and other minor additives to control properties such as surface tension.

For low viscosity precursor compositions, it is preferred that the total loading of particulates (nanoparticles and micron-size particles) is not greater than about 75 weight percent. Loading in excess of the preferred amount can lead to higher viscosities and undesirable flow properties. It is particularly preferred that the total loading of micron-size particles not exceed about 50 weight percent and that the total loading of nanoparticles not exceed about 75weight percent. In one preferred embodiment, the low viscosity precursor composition includes from about 5 to about 50 weight percent nanoparticles and substantially no micron-size particles.

A preferred conductor precursor composition comprises at least one molecular metal precursor where the precursor is highly soluble in the selected aqueous or organic solvent. Preferably, the precursor composition includes at least about 20 weight percent of molecular metal precursor, such as from about 30 weight percent to about 60 weight percent. It is particularly preferred that the molecular metal precursor be added to the precursor composition up to the solubility limit of the compound in the solvent.

The solvent can also serve as the vehicle. Alternatively, an additional liquid can be added as a vehicle.

According to certain embodiments of the present invention, the precursor composition can be selected to reduce the conversion temperature required to convert the metal precursor compound to the conductive metal. The precursor converts at a low temperature by itself or in combination with other precursors and provides for a high metal yield. As used herein, the conversion temperature is the temperature at which the metal species contained in the molecular metal precursor compound, is at least 95 percent converted to the pure metal. As used herein, the conversion temperature is measured using a thermogravimetric analysis (TGA) technique wherein a 50-milligram sample of the precursor composition is heated at a rate of 10° C./minute in air and the weight loss is measured.

A preferred approach for reducing the conversion temperature according to the present invention is to bring the molecular metal precursor compound into contact with a conversion reaction inducing agent. As used herein, a conversion reaction inducing agent is a chemical compound that effectively reduces the temperature at which the molecular metal precursor compound decomposes to the metal. The conversion reaction inducing agent can either be added into the original precursor composition or added in a separate step during conversion on the substrate. The former method is preferred. Preferably, the conversion temperature of the metal precursors can be preferably lowered by at least about 25° C., more preferably by at least about 50° C. even more preferably by at least about 100° C., as compared to the same composition without the inducing agent. Stated another way, the conversion temperature of the precursor compositions can be reduced by at least 10 percent, preferably by at least 20 percent and more preferably by at least 30 percent.

The reaction inducing agent can be the solvent or vehicle that is used for the precursor composition. For example, the addition of certain alcohols can reduce the conversion temperature of the precursor composition.

Preferred alcohols for use as conversion reaction inducing agents according to certain embodiments of the present invention include terpineol and diethyleneglycol butylether (DEGBE). It will be appreciated that the alcohol can also be the vehicle, such as in the case of terpineol.

More generally, organic alcohols such as primary and secondary alcohols that can be oxidized to aldehydes or ketones, respectively, can advantageously be used as the conversion reaction inducing agent. Examples are 1-butanol, diethyleneglycol, DEGBE, octanol, and the like. The choice of the alcohol is determined by its reducing capability as well as its boiling point, viscosity and precursor solubilizing capability. It has been discovered that some tertiary alcohols can also lower the conversion temperature of some precursors. For example, alpha-terpineol, which also serves as a vehicle, significantly lowers the conversion temperature of some molecular metal precursors. The boiling point of the conversion reaction inducing agents is preferably high enough to provide for the preferred ratio of metal ions to inducing agent during conversion to metal. It should also be low enough for the inducing agent to escape the deposit cleanly without unwanted side reactions that could lead to carbon residues in the final film. The preferred ratio of metal precursor to inducing agent is stoichiometric for complete reduction. However, in some cases catalytic amounts of the inducing agent are sufficient.

Some solvents, such as DMAc, can serve as both a vehicle and a conversion reaction inducing agent. It can also be regarded as a complexing agent for silver. This means that precursors such as Ag-nitrate that are otherwise not very soluble in organic solvents can be brought into solution by complexing the metal ion with a complexing agent such as DMAc. In this specific case, Ag-nitrate can form a 1:1 adduct with DMAc which is soluble in organic solvents such as N-methylpyrrolidinone (NMP) or DMAc.

Another approach for reducing the conversion temperature of certain metal precursors is utilizing a palladium compound as a conversion reaction inducing agent. According to this embodiment, a palladium precursor compound is added to the precursor composition, which includes another precursor such as a silver precursor. With addition of various Pd compounds, the conversion temperature of the silver precursor can be advantageously reduced by at least 25° C. and more preferably by at least 50° C. Preferred palladium precursors according to this embodiment of the present invention include Pd-acetate, Pd-trifluoroacetate, Pd-neodecanoate and tetramine palladium hydroxide. Pd-acetate and Pd-trifluoroacetate are particularly preferred as conversion reaction inducing agents to reduce the conversion temperature of a silver metal carboxylate compound. Small additions of Pd-acetate to a precursor composition that includes Ag-trifluoroacetate in DMAc can lower the decomposition temperature by up to 80° C. Preferred are additions of Pd-acetate or Pd-trifluoracetate in an amount of at least about 1 weight percent, more preferably at least about 2 weight percent. The upper range for this Pd conversion reaction inducing agent is limited by its solubility in the solvent and in one embodiment does not exceed about 10 weight percent. Most preferred is the use of Pd-trifluoroacetate because of its high solubility in organic solvents. For example, a preferred precursor composition for a silver/palladium alloy according to the present invention is Ag-trifluoroacetate and Pd-trifluoracetate dissolved in DMAc and lactic acid.

A complete range of Ag/Pd alloys can be formed with a Ag-trifluoroacetate/Pd-trifluoroacetate combination in a solvent such as DMAc. The molecular mixing of the metal precursors provides preferred conditions for the formation of virtually any Ag/Pd alloy at low temperature. The conversion temperature of the silver precursor when dissolved in DMAc is preferably reduced by at least 80° C. when combined with Pd-trifluoroacetate. Pure Pd-trifluoroacetate dissolved in DMAc can be converted to pure Pd at the same temperature. Similar conversion temperatures for the Ag and Pd precursor are advantageous since it provides optimal conditions for molecular mixing and the formation of Ag/Pd alloys with a homogeneous distribution of Ag and Pd.

Other conversion reaction inducing agents that can also lower the conversion temperature for nickel and copper metal precursors can be used such as amines (ammonia, ethylamine, propylamine), amides (DMAc, dimethylformamide, methylformamide, imidazole, pyridine), aminoalcohols (ethanol amine, diethanolamine and triethanolamine), aldehydes (formaldehyde, benzaldehyde, acetaldehyde); formic acid; thiols such as ethyl thioalcohol, phosphines such as trimethylphosphine or triethylphosphine and phosphides. Still other conversion reaction inducing agents can be selected from boranes and borohydrides such as borane-dimethylamine or borane-trimethylamine. Preferred conversion reaction inducing agents are alcohols and amides. Advantageously, DMAc can also serve as the solvent for the molecular precursor. Compared to precursor compositions that contain other solvents such as water, the precursor conversion temperature can be reduced by as much as 60° C. to 70° C. Also preferred is DEGBE, which can reduce the decomposition temperature of a silver precursor dissolved in a solvent such as water by as much as 125° C.

Another factor that has been found to influence the conversion temperature is the ratio of molecular metal precursor to conversion reaction inducing agent. It has been found that the addition of various amounts of DEGBE to a molecular silver precursor such as Ag-trifluoroacetate in DMAc reduces the precursor conversion temperature by up to about 70° C. Most preferred is the addition of stoichiometric amounts of the inducing agent such as DEGBE. Excess amounts of conversion temperature inducing agent are not preferred because it does not lower the temperature any further. In addition, higher amounts of solvent or inducing agents lower the overall concentration of precursor in solution and can negate other solution characteristics such as the composition being in the preferred viscosity and surface tension range. The ratio of inducing agent to metal ion that is reduced to metal during conversion can be expressed as a molar ratio of functional group (inducing part in the reducing agent) to metal ion. The ratio is preferably about 1, such as in the range from about 1.5 to about 0.5 and more preferably in the range of about 1.25 to about 0.75 for univalent metal ions such as Ag. For divalent metal ions the ratio is preferably about 2, such as in the range from about 3 to 1, and for trivalent metals the ratio is preferably about 3, such as in the range from about 4.5 to 1.5.

The molecular precursor preferably provides as high a yield of metal as possible. A preferred ratio of molecular precursor to solvent is that corresponding to greater than 10% mass fraction of metal relative to the total weight of the liquid (i.e., all precursor components excluding particles). As an example, at least 10 grams of conductor is preferably contained in 100 grams of the precursor composition. More preferably, greater than 20 wt. % of the precursor composition is metal, even more preferably greater than 30 wt. %, even more preferably greater than 40 wt. % and most preferably greater than 50 wt. %.

Yet another preferred approach for reducing the conversion temperature is to catalyze the reactions using particles, particularly nanoparticles. Preferred powders that catalyze the reaction include pure Pd, Ag/Pd alloy particles and other alloys of Pd. Another approach for reducing the conversion temperature is to use gaseous reducing agents such as hydrogen or forming gas.

Yet another preferred approach for reducing the conversion temperature is ester elimination, either solvent assisted or without solvent assist. Solvent assist refers to a process wherein the metal alkoxide is converted to an oxide by eliminating an ester. In one embodiment, a metal carboxylate and metal alkoxide are mixed into the formulation. At the processing temperature the two precursors react and eliminate an organic ester to form a metal oxide, which decomposes to the corresponding metal at lower temperature than the precursors themselves. This is also useful for Ag and Au, where for Au the metal oxide formation is skipped.

Another preferred approach for reducing the conversion temperature is by photochemical reduction. For example, photochemical reduction of Ag can be achieved by using precursors containing silver bonds that can be broken photochemically. Another method is to induce photochemical reduction of silver on prepared surfaces where the surface catalyzes the photochemical reaction.

Another preferred approach for reducing the conversion temperature is in-situ precursor generation by reaction of ligands with particles. For example, silver oxide can be a starting material and can be incorporated into conductor precursor compositions in the form of nanoparticles. It can react with deprotonateable organic compounds to form the corresponding silver salts. For example, silver oxide can be mixed with a carboxylic acid to form silver carboxylate. Preferred carboxylic acids include acetic acid, neodecanoic acid and trifluoroacetic acid. Other carboxylic acids work as well. For example, DARVAN C (Vanderbilt Chemical) can be included in the composition as a rheology modifier and can react its carboxylic function with the metal oxide. Small silver particles that are coated with a thin silver oxide layer can also be reacted with these compounds. Another potential benefit is simultaneously gained with regard to rheology in that such a surface modification can lead to improved particle loadings in conductor compositions. Another example is the reaction of CuO coated silver powder with carboxylic acids. This procedure can be applied more generally on other oxides such as copper oxide, palladium oxide and nickel oxide particles as well. Other deprotonateable compounds are halogeno-, hydroxy- and other alkyl and aryl derivatives of carboxylic acids, beta diketones, more acidic alcohols such as phenol, and hydrogentetrafluoroborates.

For dielectric materials, the formation of carbon during the conversion of a molecular precursor should be avoided because it can lead to a high degree of dielectric loss. Many high K dielectric compositions contain barium. When processed in air, barium precursors are susceptible to formation of barium carbonate. Once barium carbonate is formed, it cannot be converted to an oxide below 1000° C. Therefore, barium carbonate formation should be avoided. It is also known that hydroxyl groups are an important source of loss in dielectric metal oxides and the condensation reactions to convert metal hydroxides to metal oxides are not complete until about 800° C. (for isolated surface hydroxyl groups). The present invention includes precursor compositions that avoid hydrolytic-based chemistry such as sol-gel-based hydrolysis and condensation routes.

For layers with low dielectric loss and high dielectric constant, the incorporation of porosity is detrimental to the performance of these layers as a result of the high internal surface area and the contribution of the dielectric properties of the material trapped inside the pores, especially air. Therefore, porosity should be reduced to a minimum.

The metal oxide phases that lead to the desired dielectric properties also require that the material be highly crystalline. The desired metal oxides do not crystallize until a high temperature and so a method that relies on a low temperature precursor composition that only includes a molecular precursor to the final phase will have both a low material yield and poor crystallinity. Conversely, a composition and method relying on only particulate material will likely provide high porosity if processed below 300° C.

The present invention includes dielectric precursor compositions that address these issues and can be converted at low temperatures to form high performance dielectric features. The compositions can include a large volume and mass fraction of highly crystalline, high performance dielectric powder such as BaTiO₃ or BaNd₂Ti₅O₁₄ that has the desired dielectric constant, has a low temperature coefficient and has a low loss. The precursor composition can include a smaller fraction of precursor to another material for which precursors are available that have the following characteristics:
Avoid the intermediate formation of hydroxyl groups.
Have ligands that react preferentially to give a single-phase complex stoichiometry product rather than a mixture of a number of different crystalline phases.
Can be processed to form a crystalline phase at low temperatures.
Have high ceramic yield.
Which result in a good K, low loss and small temperature coefficient contribution.

An example of such a target phase is TiO₂ or Zr_{0.40}Sn_{0.66}Ti_{0.94}O₂.

One embodiment of the present invention utilizes novel combinations of molecular precursors that provide lower reaction temperatures than can be obtained through individual precursors. The precursors can include molecules that can be converted to metal oxides, glass-metal oxide, metal oxide-polymer, and other combinations. The dielectric precursor compositions of the present invention can include novel combinations of precursors that provide lower reaction temperatures to form dielectric features than can be obtained through the use of individual precursors. An example of one such combination is Sn-, Zr-, and Ti-oxide precursors.

Depending on their nature, the dielectric precursors can react in the following ways:

Hydrolysis/Condensation
M(OR)ₙ+H₂O [symbol] [MOₓ(OR)ₙ₋ₓ]+MOy

Anhydride Elimination
M(OAc)ₙ [symbol] [MO_{x/2}(OAc)ₙ₋ₓ]+x/2Ac₂O [symbol] MOy+n−xAc₂O

Ether Elimination
M(OR)ₙ [symbol] [MOₓ(OR)ₙ₋ₓ]+R₂O [symbol] MOy+n−xR₂O

Ketone Elimination
M(OOCR)(R′) [symbol] MOy+R′RCO

Ester Elimination
M(OR)ₙ+M′(OAc)ₙ [symbol] [MM′Oₓ(OAc)ₙ₋ₓ(OR)ₙ₋ₓ]+ROAc [MM′Oₓ(OAc)ₙ₋ₓ(OR)ₙ₋ₓ]->MM′Oy+n−xROAc

Alcohol-Induced Ester Elimination
M(OAc)ₙ+HOR [symbol] [MOₓ(OAc)ₙ₋ₓ] [symbol] MOy

Small Molecule-Induced Oxidation
M(OOCR)+Me₃NO [symbol] MOy+Me₃N+CO₂

Alcohol-Induced Ester Elimination
MO₂CR+HOR [symbol] MOH+RCO₂R (ester) MOH-->MO₂

Ester Elimination
MO₂CR+MOR [symbol] MOM+RCO₂R (ester)

Condensation Polymerization
MOR+H₂O [symbol] (MₐO_{b})OH+HOR (MₐO_{b})OH+(MₐO_{b})OH [symbol] [(MₐO_{b})O(MₐO_{b})O]

A particularly preferred approach is ester elimination, including a sol-gel process utilizing alcohol ester elimination. One preferred combination of precursors is Sn-ethylhexanoate, Zr-ethylhexanoate and dimethoxy titanium neodecanoate. These precursors can be advantageously used in an organic based precursor formulation. In this case, the presence of metal alkoxides precludes the use of water. The nature and the ratio of the ligands used in these precursors are critical to achieve a low conversion temperature. Generally, small ligands that can escape cleanly without leaving carbon residue during conversion are preferred. For example, this can be achieved by formation of ethers from alkoxide ligands or by formation of anhydrides from carboxylates. Another preferred combination is the use of a mixed ligand system such as a carboxylate and an alkoxide that can be bound to either the same or different metal centers. Upon conversion, the metal oxygen bonds are broken and small molecules are eliminated. A carboxylate to alkoxide ratio of 1:1 is preferred because of the formation of organic esters at lower temperatures.

In accordance with the foregoing, useful precursors (where metal=Sn, Zr, Ti, Ba, Ca, Nd, Sr, Pb, Mg) include:

1) Metal alkoxides, such as Sn-ethoxide, Zr-propoxide, Pb-butoxide, Pb-isopropoxide, Sn-neodecanoate;

2) Metal carboxylates, such as metal fluorocarboxylates, metal chlorocarboxylates, metal hydroxocarboxylates. Specific examples include Ba-acetate, Sn-ethylhexanoate, and Pb-carboxylates such as Pb-acetate, Pb-trifluoroacetate and Pb-ethylhexanoate;

3) Metal betadiketonates, including Pb-betadiketonates such as Pb-acetylacetonate and Pb-hexafluoroacetylacetonate; and

4) Mixed alkoxo metal carboxylates (where metal=Sn, Zr, Ti, Ba, Ca, Nd, Sr, Pb, Mg) such as dimethoxy titanium neodecanoate. Dialkoxo titanium dicarboxylate precursors in the dielectric precursor compositions can also serve as an adhesion promoter.

A dielectric precursor composition can include a dielectric powder and a precursor to an insulative phase. Alternatively, the dielectric precursor can include an insulative powder and a precursor to a dielectric phase. Preferred dielectric powders (nanoparticles or micron-size particles) include BaTiO₃, lead magnesium niobate (PMN), lead zirconium titanate (PZT), doped barium titanate (BTO), barium neodymium titanate (BNT), lead tantalate (Pb₂Ta₂O₇), and other pyrochlores. Preferred insulative powders include TiO₂, SiO₂, and insulating glasses. Preferred insulative phase precursors include organic titanates such as titanium bis(ammonium lactato) dihydroxide; mixed alkoxo titanium carboxylates such as dimethoxy titanium bis(neodecanoate) or dibutoxy titanium bis(neodecanoate); silicon alkoxides such as silicon methoxide and silicon ethoxide. Preferred dielectric phase precursors include metal alkoxides, carboxylates and beta-diketonates to form the mixed metal oxide as listed above.

Another consideration when using precursor compositions containing dielectric particles that are formulated to be converted at a low temperature is that the particles must possess properties close to the final desired physical properties of the fully processed devices. Optimization of the intrinsic properties of the particles is crucial because recrystallization and annealing of crystal defects during thermal processing is often not possible at processing temperatures of less than 500° C. Maximization of dielectric constant in the final material requires maximization of the dielectric constant of the powders because the composition is subjected to low temperatures for short times, which are insufficient to increase the crystallinity of the high k powder during processing.

In one embodiment, the precursor composition utilizes dielectric powders with dielectric constants (k) preferably greater than 500 and more preferably greater than 1000. The dielectric constant of the powder can be measured as follows: A pellet is pressed from the dry powder and calcined at 400° C. for one hour to drive off water. The pellet is then placed between metal electrodes and the capacitance is measured as a parallel plate capacitor, over the frequency range of 1 kHz to 1 MHz. Based on the geometry and packing density, the logarithmic rule of mixtures is applied, assuming the two phases present are the powder and air, and the dielectric constant of the powder alone is calculated.

In another embodiment, a precursor composition utilizes dielectric powders with dielectric constants greater than 2000. Such high dielectric constant can be obtained in a powder in various ways. One way is the use of spray pyrolysis, which allows for the addition of dopant in each individual particle. Another way is the use of annealing of particle beds at elevated temperatures such as 900° C. to 1000° C. to improve particle composition and particle crystallinity followed by milling to break up any soft agglomerations formed during firing. A rotary calcine can be used to anneal and limit particle agglomeration.

In another embodiment, a precursor composition includes low loss dielectric powders having a loss of less than 1%, more preferably less than 0.1%, and most preferably less than 0.01%, over the frequency range of 1 kHz to 1 MHz. The dielectric loss can be measured as follows: A pellet is pressed from the dry powder and calcined at 400° C. to drive off surface water. Once the pellet has been dried, it is kept in a dry environment. The pellet is then placed between electrodes and the loss measured as a parallel plate capacitor over the frequency range of 1 kHz to 1 MHz.

In another embodiment, a precursor composition utilizes high-k or low loss dielectric powders as described above, where the particles are exposed to a liquid surface modification agent, such as a silanating agent. The purpose of this treatment is the elimination of surface defects such as hydroxyl groups that induce dielectric loss and/or sensitivity to humidity in the final low-fired dielectric layer. The silanating agent can include an organosilane. For example, a surface-modifying agent is exposed as a gas in a confined enclosure to the powder bed and allowed to sit for about 15 minutes at 120° C. for 10 minutes, completing the surface modification.

Useful organosilanes include RₙSiX₍₄₋ₙ₎, where X is a hydrolysable leaving group such as an amine (e.g., hexamethyldisilazane), halide (e.g., dichlorodimethylsilane), alkoxide (e.g., trimethoxysilane, methacryloxypropyltrimethoxysilane, N-methyl-3-aminopropyltrimethoxysilane), or acyloxy (e.g., acryloxytrimethylsilane).

Hydrolysis and condensation can occur between organosilane and surface hydroxy groups on the dielectric particle surface. Hydrolysis occurs first with the formation of the corresponding silanol followed by condensation with hydroxo groups on the metal oxide surface. As an example:
R—(CH₂)₃Si(OMe)₃+H₂O [symbol] R—(CH₂)₃Si(OH)₂(OMe)₂+2MeOH
R—(CH₂)₃Si(OH)₂(OMe)₂+(particle_{surf}Si)OH [symbol] (particle_{surf}Si)—O—Si(OH)₂(CH₂)₃—R+H₂O
where
R═CH₂CCH₃COO

Particularly preferred compositions for high dielectric constant powders are those having the perovskite structure. Examples include metal titanates, metal zirconates, metal niobates, and other mixed metal oxides. Particularly useful is the barium titanate system which can reach a broad range of dielectric performance characteristics by adding small levels of dopant ions. Specific examples include BaTiO₃, PbTiO₃, PbZrO₃, PbZrₓTi₁₋ₓO₃ (where x is from 0.01 to about 0.52) and PbMg_{1/3}Nb_{2/3}O₃.

Particularly preferred compositions for low loss dielectric constant powders are Zr_{0.7}Sn_{0.3}TiO₄, Zr_{0.4}Sn_{0.}66Ti0_{.94}O₄, CaZr_{0.98}Ti_{0.02}O₃, SrZr_{0.94}Ti_{0.06}O₃, BaNd₂Ti₅O₁₄, Pb₂Ta₂O₇, and various other pyrochlores.

The dielectric precursor compositions of the present invention uniquely allow for the use of two or more different particles, such as by mixing Al₂O₃ and TiO₂ particles, or barium titanate and PZT particles. These compositions will not inter-diffuse significantly during firing below 600° C., preserving their unique dielectric properties. These compositions can be tailored to have a very low TCC value combined with very low loss.

Preferred glass compositions are low melting temperature glasses, such as borosilicate glasses doped with lead or bismuth. The preferred average particle size for the glass powder is no larger than the other particles present, and more preferably is less than about half the size of the other particles.

The preferred average particle size of the low melting glass particles is on the order of the size of the dielectric particles, and more preferably is about one-half the size of the dielectric particles, and most preferably is about one quarter the size of the dielectric particles.

A bimodal size distribution of particles, as is discussed above, enhances the packing density and is desired to increase the performance, preferably with the smaller particles being about 10 wt. % of the total mass of powder.

The dielectric precursor compositions of the present invention can be converted at a low temperature. The preferred conversion temperature is less than 900° C. for ceramic substrates. For glass substrates, the preferred conversion temperature is not greater than 600° C. Even more preferred for glass substrates is a conversion temperature of not greater than 500° C., such as not greater than 400° C. The preferred conversion temperature for organic substrates is not greater than 350° C., even more preferably not greater than 300° C., and even more preferably not greater than 200° C.

Spherical dielectric particles can be incorporated to improve solids loading while maintaining good flowability. In one embodiment, the precursor composition includes spherical dielectric particles and a vehicle. The spherical particles can be formed, in one embodiment, by spray pyrolysis.

In another embodiment, the dielectric precursor composition includes dielectric particles, a precursor, and a vehicle, wherein the precursor is preferably a metal organic.

In another embodiment, the dielectric precursor composition includes solid dielectric particles, nanoparticles and a vehicle.

In another embodiment, the dielectric precursor composition includes solid dielectric particles, a precursor, nanoparticles and a vehicle wherein the precursor is preferably a metallo-organic compound.

The dielectric precursor compositions can include dielectric particles, vehicle, and polymer precursor. In cases where adhesion to a polymeric substrate is desired, the precursor composition can include a polymer or precursor to a polymer. The precursor to a polymer can be poly (amic) acid. The polymer can be an epoxy, polyimide, phenolic resin, thermo set polyester, polyacrylate and the like. The flowable compositions can include a low curing polymer that cures at not greater than 200° C., more preferably not greater than 150° C.

The precursor composition can include a low loss polymer such as poly tetra fluoro ethylene, or a precursor to such a polymer.

The precursor compositions can include a particle surface modifier such as a liquid surface modification agent, for example, a silanating agent. The silanating agent can include hexamethyldisilazane.

The present invention provides dielectric precursor compositions capable of forming combinations of high k particles and matrix derived from a precursor or a low melting glass or both. Preferred particles for high k materials are lead magnesium niobate (PMN, PbMg_{1/3}Nb_{2/3}O₃), PbTiO₃ (PT), PMN-PT, PbZrₓTi₁₋ₓO(PZT), and doped BaTiO₃. Preferred particles for low loss applications are barium neodymium titanate (BNT, BaNd₂Ti₅O₁₄), zirconium tin titanate (ZST, Ti_{0.94}Zr_{0.4}Sn_{0.66}O₄), lead tantalate (Pb₂Ta₂O₇). Preferred glass compositions are low melting sealing glasses with a melting point below 500° C., more preferably below 400° C., even more preferably below 300° C. Preferred low melting glass particles for high k compositions have high dielectric constants, typically in the range from 10 to 40, more preferably higher than 40. Preferred low melting glass particles for high k compositions have low dielectric loss characteristics, preferably not greater than 2%, more preferably not greater than 1%, even more preferably not greater than 0.1%.

There are essentially two routes to formation of dielectric materials according to the present invention: a precursor plus powders approach, and a powders only approach. Ceramic products that are desirably formed using a precursor plus powder method include: BaTiO₃—PbZrₓTi₁₋ₓO, BaTiO₃—TiO₂, BaTiO₃—TiZrₓSn₁₋ₓO₄, BaNd₂Ti₅O₁₄—TiZrₓSn₁₋ₓO₄. These basic building blocks may be enhanced by the application of surface modification (silanation), or the addition of low melting temperature glass.

The precursor-based approach for dielectrics requires the combination of a dielectric powder with a precursor to a dielectric. The general approach is to first disperse the dielectric powder in a low boiling point solvent. The precursor is then added to the dispersion and most of the solvent is removed, leaving a thick precursor consisting of particles and precursor with a trace amount of solvent. This precursor can then be deposited on a substrate by a variety of methods and fired to yield a novel structure of dielectric particles connected by a dielectric formed from precursor decomposition.

An approach exploiting low melting glasses (LTG) is desirable for: BaTiO₃-LTG, BaNd₂Ti₅O₁₄-LTG and PbMg_{1/3}Nb2_{/3}O₃-LTG. The glass-based approach combines a low melting point glass with one or more dielectric powders. For this approach to be successful the particle size of the glass phase is critical. If the glass particles are larger than the dielectric powder, they will either pool when melted, forming inhomogeneities, or they will wick into the porous arrangement of dielectric particles leaving behind voids.

The general approach according to the present invention is to coat the powders with a dispersant while in a vehicle then remove the vehicle. The coated powders are then combined in the desired ratio and milled with a solvent and binder system. The desired ratio of glass to particles will vary by application and desired final properties, but will be governed by the following criteria. The dielectric phase is targeted to occupy the majority of the final composite depending on the particle size distribution of the powder. For example, a monomodal powder would be targeted to occupy 63% of the composite. The glass phase is then targeted to occupy the remaining volume, in the example here, 37%. This calculation provides the minimum glass loading and there may be some applications where more glass is used.

The dielectric precursor compositions of the present invention are based on optimizing the dielectric performance of a multiphase composite by combining the phases in the best possible way. The traditional route to high performance dielectrics is dominated by sintering of ceramics at high temperatures, which eliminates porosity and allows for high degrees of crystallization, which yield high performance. When processing at low temperatures, sintering will not occur and other methods must be employed to achieve the best performance. One route to accomplish this is to densely pack dielectric powders and fill the remaining voids with another component. This route has been used in polymer thick film by using a polymer to fill the voids. The dielectric constant of a composite follows a logarithmic mixing rule:

$$log K = {\sum }_{i} {V}_{i} log {K}_{i} ,$$

where the log of the dielectric constant of the composite is a sum of the dielectric constants of the phases (Kᵢ) multiplied by their volume fractions (Vᵢ). Filling the voids with a low dielectric constant material, for example a polymer, would dramatically reduce the dielectric constant of the composite. For example, if a dielectric powder with a dielectric constant of 5000 is packed 60% dense and the remaining volume is filled with a polymer having a dielectric constant of 4, the resulting dielectric constant of the composite is 289. This equation leads to two pursuable routes to maximizing the dielectric constant. One is to maximize the volume fraction of the high dielectric constant particles, and the other is to increase the dielectric constant of the matrix phase.

The packing of spherical particles has been studied thoroughly and the best packing of monomodal spheres results in 74% efficient space filling, with a random packing resulting in a density of about 63%, or the practical limit for monomodal packing. Pauling's rules for packing of spheres shows that perfect packing results in two different sized interstitial voids throughout the structure. To fill the larger voids with smaller spheres, one would target a radius ratio of small particle to big particle of 0.414. To fill the smaller voids would require a radius ratio of small particle to big particle of 0.225. Using a trimodal distribution of spherical particles in accordance with the present invention and assuming perfect packing of the system, 81% of the space. Naturally, this process could be continued filling the voids between the spheres with smaller and smaller spheres, but there is a diminishing return and physical limits that prohibit packing to 100% density by this approach. With particles in the micron range and traditional processing techniques, a density of 70% would be achievable and anything higher would be a significant advance in the art.

It is an object of the present invention to maximize the dielectric constant of the matrix. Most polymers have dielectric constants ranging from 2 to 10. Most glasses are not much higher, but glasses with high lead or bismuth contents can have dielectric constants upwards of 40. The best way to achieve the high dielectric constant matrix is to use a metal oxide such as barium titanate. To achieve this at low processing temperatures requires a dielectric precursor approach. Metal oxide precursors can form traditional high dielectric constant morphologies at low temperatures. The compositions and methods of the present invention can produce a high ceramic yield and a high degree of crystallinity.

The present invention is also particularly useful for making low loss materials. Some of the major classes of materials that can be utilized or formed by the present invention include: Ba-Ln-Ti—O(Ln=Nd, Sm), (Zn,Sn)ₓ(Ti,Sn)_{y}O₄, Ba₂Ti₉O₂₀Ba₃Ta₂MeO₉ (Me=Zn or Mg). Specific examples include: Ba—Pb—Nd—Ti—O, Ba(Mg_{1/3}Ta_{2/3})O₃—BaO—Nd₂O₃-5TiO₂Ba_{4.5}Nd₉Ti₁₈O₅₄, with small additions of Bi₂O or bismuth titanate, ReBa₃Ti₂O_{8.5} (Re=Y, Nd, and Sm), Ba_{3.75}Nd_{9.5}Ti₁₈O₅₄ with 1.0-4.0 wt. % Bi₂O₃BaO-Ln₂O₃-5TiO₂ (Ln=La, Pr, Nd, Sm), BaO—Nd₂O₃—TiO₂Ba₆₋ₓ(Sm_{1-y′}Ndy)₈_{⁺}_{2x/3}Ti₁₈O₅₄, (Ba,Pb)O—Nd₂O₃—TiO₂ (CaO doped) and Ti_{0.94}Zr_{0.4}Sn_{0.66}O₄.

Another class of materials that can be utilized are the pyrochlores, having the general formula A₂B₂O₇, for example Pb₂Ta₂O₇. The present invention is useful for making high dielectric constant materials. One family of materials that can be used are those having a perovskite structure. Examples include metal titanates, metal zirconates, metal niobates, and other mixed metal oxides. Of extensive use has been the barium titanate system, which can reach a broad range of dielectric performance characteristics by adding small levels of dopant ions. Specific examples include: BaTiO₃, PbTiO₃, PbZrO₃, PbZrₓTi₁₋ₓO, PbMg_{1/3}Nb_{2/3}O₃.

### Resistor Precursor Compositions

The present invention also relates to resistor precursor compositions for low-, mid-, and high-ohm resistors. The major classes of conductor component materials for mid to high ohm resistors include metal rutile, pyrochlore, and perovskite phases, many of which contain ruthenium. Examples include RuO₂, Pb₂Ru₂O₆₋₇, SrRuO₃. Other metallic oxides which behave similarly to these ruthenates may be used. Substitutions for Ru can include Ir, Rh, Os. La and Ta compounds can also be used. Other conductive phases include materials such as carbon, zinc oxide, indium oxide, indium tin oxide, and conductive glasses. Insulative components of the resistor may be formed from many types of glass materials including but not limited to lead borosilicate glass compositions.

The present invention is also directed to novel combinations of precursors that can be converted to a useful resistor at lower reaction temperatures than by using individual precursors. In one embodiment, a mixture of metal oxide precursors is dissolved in an aqueous solution to form an amorphous lead zinc aluminum borosilicate glass with a conductive ruthenate constituent at 300° C. This formulation included ruthenium nitrosyl nitrate precursor plus lead acetate precursor to form a lead ruthenate conductive phase with lead acetate, aluminum nitrate, boric acid, zinc acetate and fumed silica nanoparticles forming the glass phase. A preferred combination for an organic based precursor composition includes ruthenium ethylhexanoate with other metal ethylhexanoates for lead, aluminum, zinc, boron and some silica nanoparticles or silane precursor in a solvent such as DMAc or teterahydrofuran (THF). Precursors for insulative matrix materials include organosilanes and sol-gel type materials as precursors to silica. An insulative matrix can also be derived from polymer precursors such as polyamic acid. Other polymer matrix phases include a wide variety of polymer resins.

The resistor precursor compositions can include various precursors. The metal oxide-polymer, and other combinations. Low-ohm resistors typically include a conductive phase such as silver metal with controlled amounts of an insulative phase such as a glass or metal oxide. Typically, the low-ohm resistors include at least 50 volume percent of an insulative phase. High-ohm resistors typically include a conductive oxide phase (e.g., a ruthenate compound) with controlled amounts of an insulative phase. The resistor precursor compositions of the present invention can therefore include molecular precursors to conductive phases and molecular precursors to insultative phases.

Depending on their nature, the molecular precursors to the resistor phases can react in the following ways:

Hydrolysis/Condensation
M(OR)ₙ+H₂O [symbol] [MOₓ(OR)ₙ₋ₓ]+MOy

Anhydride Elimination
M(OAc)ₙ [symbol] [MO_{x/2}(OAc)ₙ₋ₓ]+x/2Ac₂O [symbol] MOy+n−xAc₂O

Ether Elimination
M(OR)ₙ [symbol] [MOₓ(OR)ₙ₋ₓ]+R₂O [symbol] MOy+n−xR₂O

Ketone Elimination
M(OOCR)(R′) [symbol] MOy+R′RCO

Ester Elimination
M(OR)ₙ+M′(OAc)ₙ [symbol] [MM′Oₓ(OAc)ₙ₋ₓ(OR)ₙ₋ₓ]+ROAc [MM′Oₓ(OAc)ₙ₋ₓ(OR)ₙ₋ₓ] [symbol] MM′Oy+n−xROAc

Alcohol-Induced Ester Elimination
M(OAc)ₙ+HOR [symbol] [MOₓ(OAc)ₙ₋ₓ] [symbol] MOy

Small Molecule-Induced Oxidation
M(OOCR)+Me₃NO [symbol] MOy+Me₃N+CO₂

Alcohol-Induced Ester Elimination
MO₂CR+HOR [symbol] MOH+RCO₂R (ester) MOH [symbol] MO₂

Ester Elimination
MO₂CR+MOR [symbol] MOM+RCO₂R (ester)

Condensation Polymerization
MOR+H₂O [symbol] (MₐO_{b})OH+HOR (MₐO_{b})OH+(MₐO_{b})OH [symbol] [(MₐO_{b})O(MₐO_{b})O]

A particularly preferred approach is ester elimination.

Preferred precursors to conductive phases in resistor precursor compositions are described above with respect to conductor precursor compositions and include metal alkoxides, carboxylates, acetylacetonates, and others. Ruthenates are typically used in resistors for their temperature stability over a useful range of temperatures. Particularly preferred ruthenate precursors are ruthenium compounds such as Ru-nitrosylnitrate, Ru-ethylhexanoate and other ruthenium resinate materials. Other preferred combinations are any of the ruthenium compounds with: lead precursors such as Pb-acetate, Pb-nitrate or Pb-ethylhexanoate; bismuth precursors such as Bi-nitrate, Bi-carboxylates or Bi-beta-diketonates; and strontium precursors such as Sr-nitrate or Sr-carboxylates.

Other precursors to conductive non-ruthenate materials can be used such as precursors to IrO₂, SnO₂, In₂O₃, LaB₆, TiSi₂ or TaN. Precursors to insulative phases include precursors to PbO, B₂O₃, SiO₂ and Al₂O₃. Such insulative phase precursors can include boric acid, Si-alkoxides, Al-nitrate, Al-ethylhexanoate or other Al-carboxylates. The ratio of the insulative phase to the conductive phase can be adjusted to obtain a resistor having the desired properties.

Other preferred conductive phases for low-ohm resistors include metals such as silver, metal ruthenates, and other conducting metal, metal oxide, nitride, carbide, boride and silicide compounds. Particularly preferred precursors are Ag-trifluoroacetate, Ag-neodecanoate, tetramine palladium hydroxide, Pd-neodecanoate and Pd-trifluoroacetate.

Although the resistors can be derived from only precursors, the resistor precursor compositions can also include powders of conductor precursor and powders of insulator or powders of insulator and molecular precursors to conductive phases. Preferred conductor powders include metals and metal ruthenates such as strontium, bismuth and lead ruthenate. Preferred insulator powders include lead borosilicate glasses and other borosilicate glasses. Preferred molecular precursors to insulative phases include metal alkoxides and carboxylates.

The resistor precursor compositions can include powders of conductors and powders of insulators. Preferred conductor powders include ruthenium-based metal oxides. Preferred insulator powders can include low melting glasses such as glasses having a melting point of not greater than about 500° C., more preferably not greater than about 400° C. It is preferred that the powders have a small particle size.

The conductor phase of the resistor can include a metal or a metal compound such as a metal oxide, metal nitride, metal carbide, metal boride, metal oxycarbide, metal oxynitride, metal sulfide, metal oxysulfide, metal silicide or metal germanide. The conductor phase can also include carbon such as graphitic carbon. Preferred conductor metals include silver, copper and nickel. Preferred metal oxides include RuO₂, SrRuO₃, BiₓRu_{y}O_{z}, and other Ru-based mixed metal oxides.

The insulator phase can include a glass. It can also include a ceramic or glass ceramic. The glass can be silica, a lead-based glass, lead borosilicate, lead aluminum borosilicate glass or a silver-based glass.

Preferred processing temperatures for resistor precursor compositions are not greater than about 900° C., more preferably not greater than about 500° C., more preferably not greater than about 400° C., even more preferably not greater than about 300° C. The preferred processing times are not greater than about 5 minutes, more preferably not greater than about one minute. The substrate can be transparent or reflective.

The resistor precursor compositions can also combine conductive nanoparticles with glass precursors. The resistor composition can also combine ruthenate precursor and/or particles with a sol-gel precursor to a silica or multi-component glass phase. The resistor precursor composition can also include precursors that are compatible with organic solvents, such as metal ethylhexanoate type precursors. The resistor precursor compositions can be a combination of powder and precursor in aqueous or organic carriers.

The resistor precursor composition can include a metal or metal alloy which exhibits good TCR characteristics with or without some insulating or semiconductive phase such as SiO₂, ZrO₂, Al₂O₃, TiO₂, ZnO or SnO₂ that limits the connectivity and current carrying area of the resistor. For example, Ag/Pd alloys can be produced having a temperature coefficient of resistance (TCR) of not greater than 100 ppm/° C. It is also possible to produce alloys such as Ni/Cr and other common resistor alloys under the correct processing conditions, such as by using a forming gas.

The present invention includes resistor precursor compositions that are a combination of precursor and particles with a carrier. The precursor composition can include one or more precursors and vehicle. The precursor composition can include precursor, vehicle, and particles. The precursor composition can include precursor, vehicle, and polymer precursor. The precursor composition can include polymer, precursor, and vehicle. The precursor composition can include glass and metal oxide-particles. The precursor composition can include glass and metal oxide particles, and a precursor. The precursor composition can include glass and metal particles. The precursor composition can include glass and metal oxide particles and a precursor. The glass particles can be a conductive glass, for example a AgI doped AgPO₃ glass. The precursor composition may use a precursor as a carrier material for particles to increase ceramic yield.

The present invention also provides combinations of conductive metal and metal oxide particles in a matrix derived from a low melting glass. The present invention also provides combinations of insulating particles in a matrix of conductive metal derived from particles and precursor. The present invention also provides combinations of composite particles, or composite and single phase particles, or composite particles and precursor, or composite particles and single-phase particles and precursor in a matrix derived from a polymeric precursor or resin.

Preferred conductor particles or phases include conductive metals, metal oxides, or conductive low melting point glasses such as AgI doped silver phosphate glass. Preferred insulator glass compositions include lead borosilicate and bismuth borosilicate. Preferred insulator particles include many metal oxides with insulative properties. The precursor composition can include precursor to conductor and insulator. The precursor composition can include a precursor to conductor with insulating particles, or precursor to insulator with conductive particles, or a combination of several precursors and particles. The precursor composition can include small additions of TCR modifiers.

Preferred average particle sizes for the low melting glass particles are not greater than 1 μm, such as not greater than 0.5 μm. A bimodal particle size distribution can advantageously be used to increase the packing density of the particles and increase the final density and uniformity of the structure. The preferred morphology for all particles is spherical in order to improve rheology and optimize particle loading in the precursor composition and the density of the processed resistor.

The precursor compositions of the present invention can include a variety of material combinations. The resistor composition can be a composite. The composite can be metal-metal, metal-metal oxide, metal-polymer, metal oxide-polymer, metal-glass and other combinations. By way of example, a silver precursor can be combined with a palladium precursor to form a silver-palladium alloy. These precursor compositions have applications in the fabrication of surge resistors. The metal-oxide composition can include ruthenium-based mixed metal oxides and various glasses. The metal-polymer resistors can include metal derived from powder and/or precursors, and polymer. The metal can include silver, nickel, copper, and other metals.

The metal-glass compositions can include metals and various glasses. The metals can include silver, copper, nickel, and others. The glasses can include lead-based glasses.

The resistor precursor compositions according to the present invention can also utilize particles that result in an advantageous microstructure and promote uniformity of the structure with minimal processing time and temperature. Conductor particles for mid- to high-ohm resistors are traditionally sub-micron in size with a fairly high surface area. Insulative matrix particles have traditionally been larger than the conductive phase, with a mean particle size from about 1 μm to 4 μm. This forms a microstructure where ruthenate particles are segregated at interfaces of glass particles and tend to form conductive chains of conductor particles separated by glass, which has flowed and wetted to the conductor particles. Sub-micron particles may help dispersion of the conductive phase and lower processing temperature and time. The present invention includes the use of sub-micron particles for glass and ruthenate to improve the overall uniformity of a precursor composition. Morphology of particles also plays an important role in the processing characteristics of the precursor. Spherical glass matrix particles with fairly low surface areas and mean particle size of about 1 μm allow higher loading and better rheological characteristics. In one embodiment of the present invention, glass particles of sub-micron size are used, resulting in better uniformity in the precursor. Spherical glass particles with a bimodal size distribution are more desirable than a unimodal size distribution in terms of packing efficiency. It is important that the matrix particles have a low melting temperature, wet the conductor particles, have good TCR characteristics and good stability. An optimal resistor particle can include a composite particle having a microstructure that is already evolved after powder processing.

In one embodiment of the present invention, a precursor composition includes a lead borosilicate glass or other low melting glass, or a higher melting temperature glass in a composite particle with a segregated ruthenate phase, for example a particle incorporating separate phases of ruthenate and matrix glass. This composition allows tailoring of bulk properties (i.e., ρ, TCR, tolerance, etc.) into a single powder component. Such composite particles will give properties that are less dependent on processing temperature parameters. Composite particles will have an intrinsic microstructure similar to that of the developed microstructure of a thick film resistor, with phase-separated ruthenate regions in a dielectric matrix of glass with ruthenium and other ions diffused into dielectric regions. This could be accomplished by firing the resistor material in bulk and fritting the resultant material into a “resistor” powder. This would allow resistivities indicative of volume loading of resistor and higher processing temperatures.

In another embodiment precursors are combined in a spray pyrolysis process to produce a powder. In this embodiment of the present invention, the composite resistor particles are substantially spherical. This allows a precursor composition consisting entirely of spherical particles. This could solve problems related to shrinking feature size in screen printing, micropening and other methods. Ruthenate resistors can also be made with higher conductor loading but without the resultant roughness and porosity usually associated with use of non-spherical particles. The precursor compositions will also produce a much better heterogeneous mixture than current pastes, resulting in better tolerance as deposited and improved trim characteristics.

Another advantage of using composite particles is that these particles have qualities more representative of the bulk properties. Processing will typically require less time at a lower temperature to realize the (diffusion induced) necessary properties while retaining a very robust, high performance resistor. Such a composition can be designed to be fired at 500° C. or less. In addition, a much more rapid thermal process could be employed such as an IR furnace or a laser.

In yet another embodiment of the present invention, composite particles are mixed with another resistor powder or with another glass powder to give desired properties at lower temperatures. In the case of using a higher temperature glass composition, a low melting glass or dopant material (PbO, BiO) can be used to bond the “resistor” particles at lower temperatures. Because the resistor particles should exhibit bulk properties by themselves, it is not necessary to achieve a totally dense structure to achieve certain resistance values. Therefore, resistor particles could be partially necked and infiltrated with a low melting glass, polymeric material, or a silanating agent to keep water and other environmental factors from changing the resistor. It is also possible to achieve improved characteristics with a high loading of composite resistor particles in a polymer matrix.

The resistor precursor compositions according to the present invention typically include particulates in the form of micron-size particles and/or nanoparticles, unless a precursor is dissolved in a high-viscosity vehicle.

In low ohm resistor compositions, preferred particle compositions include silver, palladium, copper, gold, platinum, nickel, alloys thereof, composites thereof (2 or more separate phases), core-shell structures thereof (coated particles). For low cost resistor solutions, particle compositions can be selected from the group of copper aluminum, tungsten, molybdenum, zinc, nickel, iron, tin, solder, and lead. Transparent conductive particles can also be used, for example particulates of ZnO, TiO₂, In₂O₃, indium-tin oxide (ITO), antimony-tin oxide (ATO). Other conductive particles such as titanium nitride, various forms of carbon such as graphite and amorphous carbon, and intrinsically conductive polymer particles can also be used.

Other particles that can be used in the present invention belong to the group of glass particles, preferably low melting point glass particles, and even more preferably conductive low melting point glass particles such as silver doped phosphate glasses.

A mixture of a high melting point metal powder such as Cu and a low-melting point metal powder can be formulated into a precursor so that the low melting point powder melts and fills up the voids between the high melting point metal particles.

Finally, particulates can also be in the form of solid precursors to a conductive phase, such as Ag₂O nanoparticles. An extensive list of precursors is disclosed below.

A preferred resistor precursor composition of precursor and powder includes a precursor to a metal ruthenate with a low melting glass powder in an organic carrier. Low melting glass powder is preferably spherical and is preferably bimodal in particle size distribution with a mean size of about 1 μm. Another preferred resistor precursor composition includes a precursor to a ruthenate phase and a precursor to an insulative phase or TCR modifier with glass matrix particles. Low melting glass powder is preferably spherical and bimodal in particle size distribution with a mean size of 1 μm.

Another preferred resistor precursor precursor/powder composition includes metal or metal alloy particles representative of a resistor alloy (AgPd, NiCr, others) with a precursor or precursors to the metal or alloy in an aqueous or organic vehicle. There could also be an insulating powder component consisting of an insulating metal oxide (SiO₂, Al₂O₃, TiO₂, low temperature glass) to limit the conductive area or modify the mechanical characteristics of the resistor.

Resistor precursor compositions can also be produced by combining RuO₂ nanoparticles with a low-melting lead sealing glass along with an organic carrier of terpineol and fish oil dispersant. In one embodiment, compositions can be produced ranging from 10 to 30 vol. % RuO₂ powder, which can be processed at 500° C. for 30 minutes. Resistivity values up to 100 ohm-cm can be produced and TCR values of not greater than 300 ppm/° C. have been measured for this type of material system. Other systems for powder/powder include a variety of metal oxides with lead borosilicate powders (SrRuO₃/glass, Pb₂Ru₂O_{6.5}/glass etc.) A preferred resistor precursor composition includes ruthenate nanoparticles with a low temperature glass of spherical morphology with a bimodal size distribution and mean particle size of 1 μm in an aqueous or organic vehicle.

Another preferred resistor precursor composition includes ruthenate nanoparticles with a low temperature glass of spherical morphology and a bimodal size distribution and mean particle size of not greater than 1 μm in an aqueous or organic vehicle.

A preferred resistor precursor composition includes a powder with a composite structure representative of a bulk resistor in an organic or aqueous vehicle.

Another preferred resistor precursor composition includes a powder with a composite structure representative of a bulk resistor without lead or bismuth in an organic or aqueous vehicle.

Another preferred composition includes a powder with composite structure representative of a bulk resistor with a low melting glass powder in an organic or aqueous vehicle.

Another preferred register precursor composition includes a powder with a composite structure representative of a bulk resistor, including a dopant to aid necking of the particles in an organic or aqueous vehicle.

Another preferred resistor precursor composition includes a powder with a composite structure representative of a bulk resistor with a precursor to a low melting glass or dopant to aid necking of the particles in an organic or aqueous vehicle.

Another preferred resistor precursor composition includes a powder with a composite structure representative of a bulk resistor in a vehicle containing a precursor to a polymer matrix, such as polyimide or another resin.

In a preferred embodiment, the resistor precursor composition includes a conversion reaction inducing agent, which can be either or both of a powder or molecular precursor or another inorganic or organic agent. In another embodiment, the combination of molecular precursor and solvent is chosen to provide a high solubility of the precursor in the solvent. The resistor precursor compositions of the present invention typically combine a precursor formulation and particles together with other additives. In one embodiment, the precursor includes metal particles, a molecular precursor and a vehicle. The molecular precursor is preferably a metal organic compound.

In another embodiment, the resistor precursor composition includes insulative low-melting-point micron-size particles, conductive nanoparticles and a vehicle.

In another embodiment, the resistor precursor composition includes insulative low-melting-point micron-size particles, nanoparticles and a vehicle. The nanoparticles can be an inorganic precursor to a conductive phase such as Ag₂O nanoparticles.

In another embodiment, the resistor precursor composition includes micron-size particles, a molecular precursor, nanoparticles and a vehicle. The precursor is preferably a metal organic compound.

In another embodiment, the resistor precursor composition includes micron-size particles, a molecular precursor, nanoparticles and a vehicle. The precursor is preferably a metal organic compound. The nanoparticles are an inorganic precursor to a conductive phase such as Ag₂O nanoparticles. The precursor can also include precursor, vehicle, and nanoparticles. The nanoparticles can be selected from silver, copper and other metals, or can be non-conductive nanoparticles such as silica, copper oxide and aluminum oxide.

The resistor precursor composition can also include a precursor, a vehicle, and a polymer or polymer precursor, such as in cases where adhesion to a polymeric substrate is desired. The precursor to a polymer can be poly (amic) acid; The polymer can be an epoxy, polyimide, phenolic resin; thermo set polyester, polyacrylate and the like. The precursor compositions can include a low curing polymer, such as one that cures at not greater than 200° C., more preferably not greater than 150° C.

The resistor precursor compositions can also include carbon, a molecular precursor and a vehicle. The compositions can include particulate carbon, such as conductive graphitic carbon. One preferred combination is conductive carbon with molecular precursors to silver metal.

The resistor precursor compositions can also include a conductive polymer, molecular precursor and a vehicle. The polymer can be conductive for both electrons and protons. Electrically conductive polymers can be selected from polyacetylene, polyaniline, polyphenylene, polypyrrole, polythiophene, polyethylenedioxythiophene and poly (paraphenylene vinylene). Protonic conductive polymers include those with sulfonates or phosphates, for example sulfonated polyaniline

The resistor precursor composition can also include conductive nanoparticles and vehicle. The flowable composition can include conductive nanoparticles, a vehicle and polymer precursor.

Most of the foregoing description relating to optimum packing of particles in dielectric precursor compositions applies directly to resistor precursor compositions as well. The traditional route to high performance resistors is dominated by sintering of ceramic/glass composites at high temperatures, which eliminates porosity and allows for high degrees of crystallization, which yield high performance. When processing at low temperatures sintering will not occur and other methods must be employed to achieve the best performance. The resistivity of a composite also follows a logarithmic mixing rule where the log of the resistivity of the composite is a sum of the resistivities of the phases (rᵢ) multiplied by their volume fractions (Vᵢ). Thus, air gaps or voids will dramatically reduce the conductivity of the composite. In addition, stress and moisture associated with these voids will reduce stability and reproducibility. This leads to two pursuable routes to obtain reproducible resistor values. One is to maximize the volume fraction of the resistive and insulative phases, and the other is to control the resistivity of the two phases and their morphology after firing. Both are determined by the material properties, the particle size distribution of the two phases, and the firing profile.

The resistor precursor compositions of the present invention enable the efficient packing of particles at low firing temperatures, as is discussed above for dielectric precursor compositions.

In resistor precursor compositions that include a molecular precursor and powders (nanoparticles and/or micron-size particles), the ratio of precursors to powders is ideally close to that corresponding to the amount needed to fill the spaces between particulates with material derived from the precursors. However, a significant improvement in tolerance can also be obtained for lower levels of molecular precursor. It is preferred that at least about 5 vol. %, more preferably at least about 10 vol. % and even more preferably at least about 15 vol. % of the final resistor is derived from the precursor.

Other resistor precursor compositions according to the present invention are preferred for different applications. Typically, the precursor composition will take into account the deposition mechanism, the desired performance of the features and the relative cost of the features. For example, simple circuitry on a polymer or other organic substrate designed for a disposable, high-volume application will require a low cost precursor composition but will not require electronic features having superior properties. On the other hand, higher end applications will require electronic features having very good electrical properties and relative cost of the precursor composition will typically not be a significant factor.

A precursor composition will typically include a solid phase made up of particulates, including particulates that are a precursor to a conductive phase such as silver oxide, silver nitrate particles, Ag trifluoroacetate crystallites, conductive micron-size particles and nanoparticles of the conductive phase, and a liquid phase made up of a vehicle and a molecular precursor. For high viscosity pastes, the particulate fraction typically lies between 0 and 55 volume percent of the total precursor volume. The precursor fraction of the precursor composition, both present in the form of precursor particles and molecular precursor dissolved in solvents and/or dissolved in the vehicle, is typically expressed as a weight percent of the total precursor weight and can be up to 80 weight percent of the total precursor. In precursor compositions that have a significant loadings of functional particles, the precursor fraction is typically between 0 and 40 weight percent.

In one embodiment, the resistor precursor composition includes up to about 40 volume percent carbon and from about 5 to about 15 weight percent of a molecular precursor, with the balance being vehicle and other additives. In another embodiment, the precursor composition includes up to about 30 volume percent carbon and up to about 10 volume percent metal nanoparticles, with the balance being vehicle and other additives.

According to another embodiment, the resistor precursor composition includes up to about 40 volume percent metal nanoparticles and from about 5 to about 15 weight percent of a molecular precursor, wherein the balance is vehicle and other additives.

According to another embodiment, the precursor composition includes up to about 50 volume percent micron-size metal particles and from about 5 to about 15 weight percent of a molecular precursor with the balance being vehicle and other additives.

In addition to the foregoing, the resistor precursor compositions according to the present invention can also include carbon particles, such as graphitic particles. Depending upon the other components in the precursor composition, carbon particle loading up to about 50 volume percent can be obtained in the compositions. The average particle size of the carbon particles is preferably not greater than about 1 μm and the carbon particles can advantageously have a bimodal or trimodal particle size distribution. Graphitic carbon has a bulk resistivity of about 1375 μ106 -cm and is particularly useful in resistor precursor compositions that require a relatively low cost.

One embodiment of the present invention is directed to a low cost resistor precursor including between 20 and 50 vol % micron-size particles selected from the group of amorphous carbon, carbon graphite, iron, nickel, tungsten, molybdenum, and between 0 and 15 vol. % nanoparticles selected from the group of Ag, carbon, intrinsically conductive polymer, Fe, Cu, Mo, W, and between 0 and 20 wt. % precursor to an metal such as Ag, with the balance being solvents, vehicle and other additives.

In another embodiment of a low cost resistor precursor, the precursor includes between 20 and 50 vol. % micron-size particles selected from the group of amorphous carbon, graphite, iron, nickel, tungsten, molybdenum, and between 20 and 50 wt. % precursor to an intrinsically conductive polymer, with the balance being solvents, vehicle and other additives.

### Substrates

During conversion of the precursor compositions to electronic components such as resistors or capacitive layers, the surface that the precursor is deposited onto significantly influences how the overall conversion to a final structure occurs. The precursor compositions of the present invention have a low decomposition temperature enabling the compositions to be deposited and heated on a low-temperature substrate.

The types of substrates that are particularly useful according to the present invention include polyfluorinated compounds, polyimides, epoxies (including glass-filled epoxy), polycarbonates and many other polymers. Particularly useful substrates include cellulose-based materials such as wood or paper, acetate, polyester, polyethylene, polypropylene, polyvinyl chloride, acrylonitrile, butadiene styrene (ABS), flexible fiber board, non-woven polymeric fabric, woven fabric, cloth, metallic foil and thin glass. Although the present invention can be used for such low-temperature substrates, it will be appreciated that traditional substrates such as anodized metal, glass substrates and ceramic substrates can also be used in accordance with the present invention.

According to a particularly preferred embodiment of the present invention, the substrate onto which the precursor composition is deposited and converted to a conductive feature has a softening point of not greater than about 225° C., preferably not greater than about 200° C., even more preferably not greater than about 185° C. even more preferably not greater than about 150° C. and even more preferably not greater than about 100° C.

The substrate can be pre-coated, for example a dielectric can be coated on a metallic foil. In the case of dielectric pastes, the substrate is often pre-patterned with a bottom electrode layer, and the dielectric precursor is deposited on top. For resistor pastes, contact electrodes are often first deposited on the substrate. Further, the substrate surface can be modified by hydroxylating or otherwise functionalizing the surface, providing reaction sites for the precursor in the precursor composition. For example, the surface of a polyfluorinated material can be modified with a sodium naphthalenide solution that provides reactive sites for bonding during reaction with the precursor. In another embodiment, a thin layer of metal is sputtered onto the surface to provide for better adhesion to the substrate. In another embodiment, polyamic acid can be added to the precursor composition to bond with both the conductor and surface to provide adhesion. Preferred amounts of polyamic acid and similar compounds are 2 wt. % to 8 wt. % of the precursor composition.

Another method to improve adhesion is by infiltrating a precursor solution after deposition of the precursor composition and thermal treatment of the electronic feature. The precursor solution can include a precursor to a metal or a metal oxide that can be the same material than the electronic feature or a different metal. The liquid precursor solution infiltrates the porous matrix of the electronic feature deposited in the previous step and accumulates at the substrate interface. Heating will convert the liquid precursor to solid material and will improve adhesion of the feature to the surface.

The precursor compositions of the present invention can be deposited onto a substrate using a variety of tools and converted into electronic features for electronic applications. A preferred technique for depositing and converting the precursor compositions is a by filling of a pattern of one or more recessed features formed in a substrate as described in U.S. Pat. Nos. 4,508,753 and 4,508,754, both by Stepan which are incorporated herein by reference in their entirety. Other U.S. Patents that disclose similar processes include U.S. Pat. No. 4,270,823 by Kuznetoff, U.S. Pat. No. 4,336,320 by Cummings et al., U.S. Pat. No. 4,756,929 by Sullivan, U.S. Pat. No. 5,153,023 by Orlowski et al., U.S. Pat. No. 5,366,760 by Fujii et al., U.S. Pat. No. 5,384,953 by Economikos et al., U.S. Pat. No. 6,251,471 by Granoff et al., U.S. Pat. No. 4,897,676 by Sedberry, U.S. Pat. No. 5,716,663 by Capote et al., U.S. Pat. No. 5,747,222 by Ryu, U.S. Pat. No. 4,912,844 by Parker and U.S. Pat. No. 6,200,405 by Nakazawa et al. Each of these U.S. patents is incorporated herein by reference in their entirety.

The recessed features can be formed using a variety of techniques. For example, the recessed features can be formed by laser ablation, chemical etching using a mask, selective melting, stamping, milling and the like. A preferred method using a fine laser beam or lithographic techniques to form high-resolution trenches and other patterns. These recessed features can have a minimum feature size (i.e., width) of not greater than 100 μm, more preferably not greater than 50 μm, and even more preferably not greater than 25 μm. These features can be formed on high temperature substrates such as ceramics, glass substrates, or low temperature substrates such as polyimide. According to one preferred embodiment, the precursor composition is deposited into the recessed features using a doctor blade and excess precursor composition is removed from the surface of the substrate.

The trenches in the substrate can be enhanced, if necessary, such as wetting enhancers, adhesion aids, barrier layers or sealant layers. Wetting enhancers can modify the wetting characteristics of the trench. One example is to facilitate the wetting of a polymer surface by an aqueous precursor composition. For example, if the substrate is KAPTON-FN (a polyimide sheet with a TEFLON surface, available from E.I. duPont deNemours, Wilmington, Del.) and the precursor composition is aqueous based, an the trench can be filled with an acid, such as an organic acid, to allow the acid to modify the surface of the trench before washing it out. In another example, the wetting of KAPTON-HN (polyimide sheet) with a non-aqueous precursor composition may be accomplished by making the trench hydrophobic. This can be accomplished by filling the trench with a silanating agent, allowing it to react with the substrate, and then washing it off.

An adhesion aid will assist in bonding the precursor composition and/or the electronic material to the trench surface, such as in the case of a polymer substrate. The adhesion aid can be applied in a separate step or can be added to the precursor composition. For example, fluorinated acids are known to be very reactive with polyimide compounds. One method to enhance the adhesion of a precursor composition such as a silver metal precursor composition is to first fill the trenches with a fluorinated aced, such as trifluoroacetic acid, and then with the silver precursor composition. Another method is to mix a trifluoroacetate compound into the silver precursor composition, which will also aid adhesion. Such a compound could be, for example, Pd-trifluoroacetate.

A barrier layer can be utilized to protect the precursor composition and substrate material from each other. For example, an epoxy substrate can have a tendency to take up water and this can be detrimental to the precursor composition. To prevent the water in the epoxy from migrating into the precursor composition, a rubber-like barrier layer can be coated into the trench prior to filling with the precursor composition.

A sealant layer can be utilized to protect the electrical feature from the external environment. Two distinct classes of sealant performance are chemical performance and electrical performance. For example, a conductive feature may require an electrically insulating sealant layer to prevent shorting. If the electrical feature is porous, the sealant layer may be employed to prevent fluids from infiltrating the electrical feature.

In another embodiment, the sealant layer is a passivation layer. The sealant can infiltrate a pore structure and provide passivation of the exposed surfaces, effectively acting as a sealant for the material without necessarily providing a seal at the surface of the layer.

In addition to a doctor blade process, the precursor compositions can be deposited into the recessed features using a variety of techniques. For example, the composition can be spin-coated, dip-coated or roll-coated. According to one embodiment, the precursor compositions is deposited into the recessed features by a direct-write process. For example, the precursor can be ejected through an orifice toward the surface without the tool being in direct contact with the surface. The tool can advantageously be controllable over an x-y grid or even an x-y-z grid such as when depositing the feature onto a non-planar surface. Examples include ink-jet devices, aerosol jets and syringe deposition. One preferred embodiment of the present invention is directed to the use of automated syringes, such as the MICROPEN tool, available from Ohmcraft, Inc., of Honeoye Falls, N.Y.

Other printing methods include lithographic, gravure and other intaglio printing. Another preferred method for depositing of the precursor composition is screen-printing. In the screen-printing process, a porous screen fabricated from stainless steel, polyester, nylon or similar inert material is stretched and attached to a rigid frame. A predetermined pattern is formed on the screen corresponding to the pattern to be printed. For example, a UV sensitive emulsion can be applied to the screen and exposed through a positive or negative image of the design pattern. The screen is then developed to remove portions of the emulsion in the pattern regions.

The screen is then affixed to a printing device and the precursor composition is deposited on top of the screen. The substrate to be printed is then positioned beneath the screen, the precursor is forced through the screen and onto the substrate by a squeegee that traverses the screen. Thus, a pattern of traces and/or pads of the precursor material is transferred to the substrate. The substrate with the precursor composition applied in a predetermined pattern is then subjected to a drying and heating treatment to adhere the functional phase to the substrate. For increased line definition, the applied precursor can be further treated, such as through a photolithographic process, to develop and remove unwanted material from the substrate.

Some applications of such precursor compositions require higher tolerances than can be achieved using standard thick-film technology, as is described above. As a result, some precursor compositions have photo-imaging capability to enable the formation of lines and traces with decreased width and pitch. In this type of process, a photoactive precursor composition is applied to a substrate substantially as is described above. The precursor can include, for example, a liquid vehicle such as polyvinyl alcohol that is not cross-linked. The precursor is then dried and exposed to ultraviolet light through a photomask to polymerize the exposed portions of precursor and the precursor is developed to remove unwanted portions of the precursor. This technology permits higher density lines to be formed.

The electronic features of the present invention can be deposited using a syringe-dispense device at linear rates of at least 1 cm/sec, such as greater than 10 cm/sec, greater than 100 cm/sec, and even greater than 1000 cm/sec. This is enabled by the high flowability and low particle agglomeration of the precursor compositions, the lack of clogging of the precursor compositions in syringes, and other attributes. The precursor compositions of the present invention can also be deposited using a wide variety of larger volume production tools such as screen-printing and reel-to-reel printing techniques.

An optional first step, prior to deposition of the precursor composition, is surface modification of the substrate. The surface modification can be applied to the entire substrate or can be applied in the form of a pattern, such as by using photolithography. The surface modification can include increasing or decreasing the hydrophilicity of the substrate surface by chemical treatment. For example, a silanating agent can be used on the surface of a glass substrate to increase the adhesion and/or to control spreading of the precursor composition through modification of the surface tension and/or wetting angle. The surface modification can also include the use of a laser to clean the substrate. The surface can also be subjected to mechanical modification by contacting with another type of surface. The substrate can also be modified by corona treatment.

For the deposition of organic-based precursor compositions, the activation energy of the substrate surface can be modified. For example, a line of polyimide can be printed on the substrate prior to deposition of a precursor composition, such as a silver metal precursor composition, to prevent infiltration of the precursor composition into a porous substrate, such as paper. In another example, a primer material may be printed onto a substrate to locally etch or chemically modify the substrate, thereby inhibiting the spreading of the precursor being deposited in the following deposition step.

Either before or after the foregoing surface modification, trenches or other features can be formed in the substrate, as is discussed above. Thereafter, the interior surfaces of the trenches can be modified, as is discussed above.

The next step is the deposition of the precursor composition. As is discussed above, the deposition can be carried out by syringe-dispense, screen printing or otherwise filling the preformed patterns in the substrate as described in U.S. Pat. No. 4,508,753 by Stepan. In one embodiment, a first deposition step provides the precursor composition including a molecular precursor while a second deposition step provides a reducing agent or other co-reactant that converts the precursor. Another method for depositing the precursor is using multi-pass deposition to build the thickness of the deposit in the trench.

A third optional step is the modification of the properties of the deposited precursor. This can include freezing, melting and otherwise modifying the precursor properties such as viscosity, with or without chemical reactions or removal of material from the precursor. For example, a precursor composition including a thermoset polymer can be deposited and immediately exposed to a light source such as an ultraviolet lamp to polymerize and thicken the precursor and reduce spreading of the precursor. Depending on the nature of the thermoset polymer, other modification means can be used such as heat lamps or lasers.

A fourth optional step is drying or subliming of the precursor composition by heating or irradiating. In this step, material is removed from the precursor or chemical reactions occur in the precursor. An example of a method for processing the deposited precursor is using a UV, IR, laser or a conventional light source. In one embodiment, the deposited precursor is dried before processing in the subsequent step. In another embodiment, a precursor is contacted with a conversion reaction inducing agent before the precursor is dried. In another embodiment, the precursor is contacted with a gaseous reducing agent such as hydrogen.

A fifth step is increasing the temperature of the deposited precursor composition. An example of one method is to process the deposited precursor with specific temperature/time profiles. Heating rates can preferably be greater than about 10° C./min, more preferably greater than 100° C./min and even more preferably greater than 1000° C./min. The temperature of the deposited precursor can be raised using hot gas or by contact with a heated substrate. This temperature increase may result in further evaporation of solvents and other species. A laser, such as an IR laser, can also be used for heating. IR lamps or a belt furnace can also be utilized. It may also be desirable to control the cooling rate of the deposited feature. The heating step can also coincide with the activation of a reducing agent present in the precursor. The action of such reducing agent could include removal of a surface oxide from particles such as copper particles or nickel particles.

A sixth step is reacting the molecular precursors, if such precursors are present in the precursor composition. In one embodiment, the precursors are reacted using various gases to assist in the chemical conversion of the precursor to the targeted electronic material or feature. For example, hydrogen, nitrogen, and reducing gases can be used to assist the reaction. Copper, nickel, and other metals that oxidize when exposed to oxygen may require the presence of reducing atmospheres. It has been found that the precursor compositions of the present invention can advantageously provide very short reaction times when processed with light (e.g., a laser) that heats the materials. This is a result of the high chemical reaction rates when sufficiently high temperatures are provided for a specific precursor and the ability of light to rapidly heat the materials over time scales of milliseconds or even less. In the case of precursor compositions including particles, phases having a low melting or softening point allow short processing times.

The precursor compositions of the present invention including only particles, particles and molecular precursors and precursors without particles can all be processed for very short times and still provide useful materials. Short heating times can advantageously prevent damage to the underlying substrate. Preferred thermal processing times for deposits having a thickness on the order of about 10 μm are not greater than about 100 milliseconds, more preferably not greater than about 10 milliseconds, and even more preferably not greater than about 1 millisecond. The short heating times can be provided using laser (pulsed or continuous wave), lamps, or other radiation. Particularly preferred are scanning lasers with controlled dwell times. When processing with belt and box furnaces or lamps, the hold time is preferably not greater than 60 seconds, more preferably not greater than 30 seconds, and even more preferably not greater than 10 seconds. The heating time can even be not greater than 1 second when processed with these heat sources, and even not greater than 0.1 second, while providing electronic materials that are useful in a variety of applications. It will be appreciated that short heating times may not be beneficial if the solvent or other constituents boil rapidly and form porosity or other defects in the feature.

Typically, the deposited precursor compositions can be substantially fully converted at temperatures of not greater than 400° C., more preferably not greater than 300° C., more preferably not greater than 250° C., and even more preferably not greater than 200° C.

An optional seventh step is sintering of the particles or the material derived from the precursor. The sintering can be carried out using furnaces, light sources such as heat lamps and/or lasers. In one embodiment, the use of a laser advantageously provides very short sintering times and in one embodiment the sintering time is not greater than 1 second, more preferably not greater than 0.1 seconds and even more preferably not greater than 0.01 seconds. Laser types include pulsed and continuous wave. In one embodiment, the laser pulse length is tailored to provide a depth of heating that is equal to the thickness of the material to be sintered. The components in the precursor can be fully or partially reacted before contact with laser light. The components can be reacted by exposure to the laser light and then sintered. In addition, other components in the precursor composition (e.g., glasses) can melt and flow under these conditions.

Selective laser sintering can also be used to selectively melt a low melting phase in the precursor composition. Selective laser sintering was developed as a method for solid freeform fabrication of three-dimensional parts. One process involves spreading a layer of powder evenly over an area. A laser is then used to selectively melt the powder in a pattern that is representative of one layer of the desired part. The melted region becomes a solid layer while the untreated powder provides support for subsequent layers. A second layer of powder is then spread over the entire area and the laser used to melt the second layer. The process continues, building the part layer by layer until the final shape is complete. While the process really involves selective laser melting, it has been dubbed selective laser sintering as ceramic parts can be built by this method. Although the selective laser sintering process is traditionally used with only one material, the various combinations of ceramic powder and a low melting glass as described in the present invention allow for new applications for laser melting. Once a direct-write tool has deposited a mixture of ceramic oxide powder and glass, a laser may be employed to densify the structure by melting the glass phase. The proper balance of oxide powder to glass must be achieved along with the proper size distribution of both particulate phases. For high k dielectric applications the glass content would ideally be minimized so that the high k performance of the dielectric powder is maximized. For high-ohm resistors the glass phase may be the majority of the composition so that the conduction between the conductive oxide particles is limited by the insulating glass phase. As the glass phase is melted it wets the oxide powder and assists in densification. The laser energy can be coupled into the glass directly and other times it is desired to couple the laser energy with the oxide powder and achieve melting of the glass indirectly.

In an optional eighth step, the feature can be post-treated. For example, the crystallinity of the material phases can be increased by laser processing. The post-treatment can also include cleaning and/or encapsulation of the electronic features, or other modification such as silanation of a dielectric material.

Surface modification can also be performed to remove hydroxyl groups. Surface modification of the porosity in dielectric layers can lead to dramatically reduced dielectric loss and decreased sensitivity to humidify. In one embodiment, a porous dielectric layer is formed according to the previous steps 1 through 8. The dielectric is then exposed to a liquid surface modification agent such as a silanating agent. The silanating agent can include hexamethyldisilazane. For example, a surface modifying agent can be poured onto the fired dielectric layer and allowed to sit for about 15 minutes. The dielectric layer is then dried in an oven at 120° C. for 10 minutes, completing the surface modification.

The exposure time for the surface modifying agent is preferably not greater than 20 minutes, more preferably not greater than 10 minutes, with the temperature preferably about room temperature. The drying profile to remove excess surface modifying agent is preferably about 120° C. for 15 minutes.

Useful organosilanes include: RₙSiX₍₄₋ₙ₎ where X is a hydrolysable leaving group, such as X=amine (e.g., hexamethyldisilazane), halide (e.g., dichlorodimethylsilane), alkoxide (e.g., trimethoxysilane, Methacryloxypropyltrimethoxysilane, N-methyl-3-aminopropyltrimethoxysilane), and acyloxy (e.g., acryloxytrimethylsilane).

Hydrolysis and condensation occur between organosilane and surface hydroxy groups on the dielectric layer surface. Hydrolysis occurs first with the formation of the corresponding silanol followed by condensation with hydroxo groups on the metal oxide surface. As an example:
R—(CH₂)₃Si(OMe)₃+H₂O [symbol] R—(CH₂)₃Si(OH)₂(OMe)₂+2MeOH
R—(CH₂)₃Si(OH)₂(OMe)₂+(Layer_{surf}Si)OH [symbol] (Layer_{surf}Si)O—Si(OH)₂(CH₂)₃—R+H₂O,
where R=CH₂CCH₃COO—

It will be appreciated from the foregoing discussion that two or more of the latter process steps (e.g., drying, heating, reacting and sintering) can be combined into a single process step.

The foregoing process steps can be combined in several preferred combinations.

According to one embodiment of the present invention, the recessed feature can be treated by filling with a surface modifier, such as a wetting aide and/or an adhesion promoter, and processed to remove excess surface modifier. Thereafter, the recessed feature can be filled with a precursor composition that is then converted to an electronic material.

According to another embodiment, the recessed feature can optionally be treated by filling with a surface modifier, such as a wetting aide and/or an adhesion promoter, and processed to remove excess surface modifier. Thereafter, the recessed feature can be partially filled with a precursor composition that is then dried. Additional precursor composition of the same or different chemical composition can then be added and dried. The latter steps can be repeated multiple times until the desired level of filling and/or the desired multi-layer structure is achieved. Thereafter, the filled feature can be converted to an electronic material. It will be appreciated that the drying step between depositions of the precursor composition can be omitted, or a precursor composition can be converted prior to deposition of additional precursor composition.

According to a further embodiment, one of the foregoing process flows can be applied and a sealant layer can then be deposited over the recessed feature, either before or after conversion to the electronic material. One preferred process flow includes the steps of forming a laser milled structure; identifying locations requiring the addition of material; adding a precursor composition; and processing to form the final product

In another embodiment, a substrate is laser patterned, a precursor composition is deposited, dried, reacted at less than about 300° C., more preferably at less than about 250° C., even more preferably at less than about 200° C., and is then optionally laser sintered.

In yet another embodiment, a substrate is laser patterned, a precursor composition is deposited, dried, and reacted with a total reaction time of less than about 100 seconds, more preferably less than about 10 seconds and even more preferably less than about 1 second.

In yet another embodiment, a substrate is laser patterned, a precursor composition is deposited, dried, and reacted, wherein the total time for the deposition, drying and reaction is preferably less than about 60 seconds, more preferably less than about 10 seconds and even more preferably less than about 1 second.

In yet another embodiment, a substrate is laser patterned, the surface is modified to promote adhesion of the high viscosity paste. A precursor composition is deposited, and then the paste is dried and converted at a temperature of less than 300° C., more preferably at less than about 250° C., even more preferably at less than 200° C.

In yet another embodiment, a substrate is laser patterned, a precursor composition is deposited, dried and reacted at less than 200° C., more preferably at less than 175° C., and is then is laser sintered.

In yet another embodiment, a substrate is laser patterned, a precursor composition is deposited, dried, and reacted at less than 300° C., more preferably at less than about 200° C., to provide a conductive feature having a resistivity that is not greater than 10 times the bulk resistivity of the metal, preferably not greater than 6 times the bulk resistivity, more preferably not greater than 4 times the bulk resistivity and most preferably not greater than 2 times the bulk resistivity of the metal. In one embodiment, the conductive feature includes silver and the resistivity of the feature is not more than 100 times the bulk resistivity of silver (1.59 μΩ-cm), more preferably not more than 50 times and even more preferably not more than 10 times the bulk resistivity of silver.

In accordance with the foregoing, the present invention enables the formation of features for devices and components having a small average feature size. For example, the method of the present invention can be used to fabricate features having an average width of not greater than about 100 μm, such as not greater than about 75 μm, not greater than 50 μm and even not greater than 25 μm. In one embodiment, the small features are obtained by using a precursor composition comprising spherical metal particles. The small feature sizes can advantageously be applied to various components and devices. Additionally, the aspect ratio of the features may be controlled. Preferred aspect ratios are from much less than 1:1 for relatively large features to up to 20:1.

In another embodiment small feature sizes may be incorporated with large feature sizes, with all regions having either a constant depth or similar aspect ratios. For example a pattern consisting of 15 μm wide lines which connect 500 μm diameter regions to allow for interconnection of electronic features, can be patterned and filled with a conductive precursor composition in one process.

The conductive features that can be formed by the present invention have combinations of various features that have not been attained using other precursor compositions filled into recessed features.

The present invention is particularly useful for fabrication of conductors with resistivities that are not greater than 20 times the resistivity of the substantially pure bulk conductor, more preferably not greater than 10 times the substantially pure bulk conductor, even more preferably not greater than 5 times and most preferably not greater than 3 times that of the substantially pure bulk conductor.

A precursor composition including up to about 50 volume percent micron-size metal particles and from about 5 to about 15 weight percent of a molecular precursor with the balance being vehicle and other additives will, after heating to not greater than 200° C., yield a bulk conductivity in the range from 2 to 5 times the bulk metal conductivity.

The silver-palladium precursor compositions of the present invention can also provide a conductive feature having resistance to solder leaching. In one embodiment, the compositions provide resistance to 3 dips in standard 60/40 lead-tin solder at its melting point.

The precursor compositions and methods of the present invention advantageously allow the fabrication of various unique structures.

In one embodiment, the average thickness of the deposited feature is greater than about 2 μm, more preferably is greater than about 5 μm, even more preferably is greater than about 10 μm, and even more preferably is greater than about 25 μm.

Vias can also be filled with the high viscosity precursor compositions of the present invention. The via can be filled, dried to remove the volume of the solvent, filled further and two or more cycles of this type can be used to fill the via. The via can then be processed to convert the material to its final composition. After conversion, it is also possible to add more paste, dry and then convert the material to product to replace the volume of material lost upon conversion to the final product.

The compositions and methods of the present invention can also produce features that have good adhesion to the substrates on which they are formed. For example, the conductive features will adhere to the substrate with a peel strength of at least 10 newtons/cm. Adhesion can be measured using the scotch-tape test, wherein scotch-tape is applied to the feature and is pulled perpendicular to the plane of the trace and the substrate. This applies a force of about 10 N/cm. A passing measure is when little or no residue from the feature remains on the tape.

The precursor compositions and methods of the present invention can advantageously be used in a variety of applications.

In one embodiment, an antenna includes a conductor with resistivity of not greater than about 10 times the resistivity of bulk silver. High conductivity traces are required for inductively coupled antennas whereas low cost conductors can be used for electrostatic (capacitively coupled) antennas.

In one embodiment, the substrate is not planar. Examples of surfaces that are non-planar include windshields, electronic components, electronic packaging and visors.

The precursor compositions and methods can also be used to form under bump metallization, redistribution patterns and basic circuit components.

The precursor compositions and processes of the present invention can also be used to fabricate microelectronic components such as multichip modules, particularly for prototype designs or low-volume production

Another technology where the deposition of conductive traces according to the present invention provides significant advantages is for flat panel displays, such as plasma display panels, and solar cells. The compositions and deposition methods according to the present invention can advantageously be used to form the electrodes and bus lines for a display panel. Typically, a metal paste is printed onto a glass substrate and is fired in air at from about 450° C. to 600° C. The compositions of the present invention can be processed at much lower firing temperatures. The deposited features can have high resolution and dimensional stability and can have a high density.

The present invention is also applicable to inductor-based devices including transformers, power converters and phase shifters. Examples of such devices are illustrated in: U.S. Pat. No. 5,312,674 by Haertling et al.; U.S. Pat. No. 5,604,673 by Washburn et al.; and U.S. Pat. No. 5,828,271 by Stitzer. Each of the foregoing U.S. Patents is incorporated herein by reference in their entirety. In such devices, the inductor is commonly formed as a spiral coil of an electrically conductive trace, typically using a thick-film paste method. To provide the most advantageous properties, the metallized layer, which is typically silver, must have as fine a pitch (line spacing) as possible. More specifically, the output current can be greatly increased by decreasing the line width and decreasing the distance between lines. The process of the present invention is particularly advantageous for forming such devices, particularly when used in a low-temperature co-fired ceramic package (LTCC).

The precursor compositions of the present invention can also be used to fabricate antennas such as antennas used for cellular telephones. The design of antennas typically involves many trial and error iterations to arrive at the optimum design. Examples of microstrip antennas are illustrated in: U.S. Pat. No. 5,121,127 by Toriyama; U.S. Pat. No. 5,444,453 by Lalezari; U.S. Pat. No. 5,767,810 by Hagiwara et al.; and U.S. Pat. No. 5,781,158 by Ko et al. Each of these U.S. Patents is incorporated herein by reference in their entirety.

The precursor compositions of the present invention can also be used to fabricate circuitry for solar cell technology, disposable cell phones, replacement for wire bonding in a smart cards or RF tags.

The compositions and methods of the present invention can also produce conductive patterns that can be used in flat panel displays. The conductive materials used for electrodes in display devices have traditionally been manufactured by commercial deposition processes such as etching, evaporation, and sputtering onto a substrate. In electronic displays it is often necessary to utilize a transparent electrode to ensure that the display images can be viewed. Indium tin oxide (ITO), deposited by means of vacuum-deposition or a sputtering process, has found widespread acceptance for this application. U.S. Pat. No. 5,421,926 by Yukinobu et al. discloses a process for printing ITO inks. For rear electrodes (i.e., the electrodes other than those through which the display is viewed) it is often not necessary to utilize transparent conductors. Rear electrodes can therefore be formed from conventional materials and by conventional processes. Again, the rear electrodes have traditionally been formed using costly sputtering or vacuum deposition methods. The compositions according to the present invention allow the direct deposition of metal electrodes onto low temperature substrates such as plastics. For example, a silver precursor composition can be ink-jet printed and heated at 150° C. to form 150 μm by 150 μm square electrodes with excellent adhesion and sheet resistivity values of less than 1 ohms per square.

Nonlinear elements, which facilitate matrix addressing, are an essential part of many display systems. For a display of M×N pixels, it is desirable to use a multiplexed addressing scheme whereby M column electrodes and N row electrodes are patterned orthogonally with respect to each other. Such a scheme requires only M+N address lines (as opposed to M×N lines for a direct-address system requiring a separate address line for each pixel). The use of matrix addressing results in significant savings in terms of power consumption and cost of manufacture. As a practical matter, the feasibility of using matrix addressing usually hinges upon the presence of a nonlinearity in an associated device. The nonlinearity eliminates crosstalk between electrodes and provides a thresholding function. A traditional way of introducing nonlinearity into displays has been to use a backplane having devices that exhibit a nonlinear current/voltage relationship. Examples of such devices include thin-film transistors (TFT) and metal-insulator-metal (MIM) diodes. While these devices achieve the desired result, they involve thin-film processes, which suffer from high production costs as well as relatively poor manufacturing yields.

The present invention allows the direct printing of the conductive components of nonlinear devices including the source the drain and the gate. These nonlinear devices may include directly printed organic materials such as organic field effect transistors (OFET) or organic thin film transistors (OTFT), directly printed inorganic materials and hybrid organic/inorganic devices such as a polymer based field effect transistor with an inorganic gate dielectric. Direct printing of these conductive materials will enable low cost manufacturing of large area flat displays.

The compositions and methods of the present invention produce conductive patterns that can be used in flat panel displays to form the address lines or data lines. The lines may be made from transparent conducting polymers, transparent conductors such as ITO, metals or other suitable conductors. The present invention provides ways to form address and data lines using deposition tools such as an ink-jet device. The precursor compositions of the present invention allow printing on large area flexible substrates such as plastic substrates and paper substrates, which are particularly useful for large area flexible displays. Address lines may additionally be insulated with an appropriate insulator such as a non-conducting polymer or other suitable insulator. Alternatively, an appropriate insulator may be formed so that there is electrical isolation between row conducting lines, between row and column address lines, between column address lines or for other purposes. These lines can be printed with a thickness of about one μm and a line width of 100 μm by ink-jet printing the precursor composition. These data lines can be printed continuously on large substrates with an uninterrupted length of several meters. Surface modification can be employed, as is discussed above, to confine the composition and to enable printing of lines as narrow as 10 μm. The deposited lines can be heated to 200° C. to form metal lines with a bulk conductivity that is not less than 10 percent of the conductivity of the equivalent pure metal.

Flat panel displays may incorporate emissive or reflective pixels. Some examples of emissive pixels include electroluminescent pixels, photoluminescent pixels such as plasma display pixels, field emission display (FED) pixels and organic light emitting device (OLED) pixels. Reflective pixels include contrast media that can be altered using an electric field. Contrast media may be electrochromic material, rotatable microencapsulated microspheres, polymer dispersed liquid crystals (PDLCs), polymer stabilized liquid crystals, surface stabilized liquid crystals, smectic liquid crystals, ferroelectric material, or other contrast media well known in art. Many of these contrast media utilize particle-based non-emissive systems. Examples of particle-based non-emissive systems include encapsulated electrophoretic displays (in which particles migrate within a dielectric fluid under the influence of an electric field); electrically or magnetically driven rotating-ball displays as disclosed in U.S. Pat. Nos. 5,604,027 and 4,419,383, which are incorporated herein by reference in their entirety; and encapsulated displays based on micromagnetic or electrostatic particles as disclosed in U.S. Pat. Nos. 4,211,668, 5,057,363 and 3,683,382, which are incorporated herein by reference in their entirety. A preferred particle non-emissive system is based on discrete, microencapsulated electrophoretic elements, examples of which are disclosed in U.S. Pat. No. 5,930,026 by Jacobson et al. which is incorporated herein by reference in its entirety.

In one embodiment, the present invention relates to directly printing conductive features, such as electrical interconnects and electrodes for addressable, reusable, paper-like visual displays. Examples of paper-like visual displays include “gyricon” (or twisting particle) displays and forms of electronic paper such as particulate electrophoretic displays (available from E-ink Corporation, Cambridge, Mass.). A gyricon display is an addressable display made up of optically anisotropic particles, with each particle being selectively rotatable to present a desired face to an observer. For example, a gyricon display can incorporate “balls” where each ball has two distinct hemispheres, one black and the other white. Each hemisphere has a distinct electrical characteristic (e.g., zeta potential with respect to a dielectric fluid) so that the ball is electrically as well as optically anisotropic. The balls are electrically dipolar in the presence of a dielectric fluid and are subject to rotation. A ball can be selectively rotated within its respective fluid-filled cavity by application of an electric field, so as to present either its black or white hemisphere to an observer viewing the surface of the sheet.

In another embodiment, the present invention relates to electrical interconnects and electrodes for organic light emitting displays (OLEDs). Organic light emitting displays are emissive displays consisting of a transparent substrate coated with a transparent conducting material (e.g., ITO), one or more organic layers and a cathode made by evaporating or sputtering a metal of low work function characteristics (e.g., calcium or magnesium). The organic layer materials are chosen so as to provide charge injection and transport from both electrodes into the electroluminescent organic layer (EL), where the charges recombine to emit light. There may be one or more organic hole transport layers (HTL) between the transparent conducting material and the EL, as well as one or more electron injection and transporting layers between the cathode and the EL. The precursor compositions according to the present invention allow the direct deposition of metal electrodes onto low temperature substrates such as flexible large area plastic substrates that are particularly preferred for OLEDs. For example, a metal precursor composition can be ink-jet printed and heated at 150° C. to form a 150 μm by 150 μm square electrode with excellent adhesion and a sheet resistivity value of less than 1 ohm per; square. The compositions and printing methods of the present invention also enable printing of row and column address lines for OLEDs. These lines can be printed with a thickness of about one μm and a line width of 100 μm using ink-jet printing. These data lines can be printed continuously on large substrates with an uninterrupted length of several meters. Surface modification can be employed, as is discussed above, to confine the precursor composition and to enable printing of such lines as narrow as 10 μm. The printed ink lines can be heated to 150° C. and form metal lines with a bulk conductivity that is no less than 5 percent of the conductivity of the equivalent pure metal.

In one embodiment, the present invention relates to electrical interconnects and electrodes for liquid crystal displays (LCDs), including passive-matrix and active-matrix. Particular examples of LCDs include twisted nematic (TN), supertwisted nematic (STN), double supertwisted nematic (DSTN), retardation film supertwisted nematic (RFSTN), ferroelectric (FLCD), guest-host (GHLCD), polymer-dispersed (PD), polymer network (PN).

Thin film transistors (TFTs) are well known in the art, and are of considerable commercial importance. Amorphous silicon-based thin film transistors are used in active matrix liquid crystal displays. One advantage of thin film transistors is that they are inexpensive to make, both in terms of the materials and the techniques used to make them. In addition to making the individual TFTs as inexpensively as possible, it is also desirable to inexpensively make the integrated circuit devices that utilize TFTs. Accordingly, inexpensive methods for fabricating integrated circuits with TFTs, such as those of the present invention, are an enabling technology for printed logic.

For many applications, inorganic interconnects are not adequately conductive to achieve the desired switching speeds of an integrated circuit due to high RC time constants. Printed pure metals, as enabled by the precursor compositions of the present invention, achieve the required performance. A metal interconnect printed by using a silver precursor composition as disclosed in the present invention will result in a reduction of the resistance (R) and an associated reduction in the time constant (RC) by a factor of 100,000, more preferably by 1,000,000, as compared to current conductive polymer interconnect material used to connect polymer transistors.

Field-effect transistors (FETs), with organic semiconductors as active materials, are the key switching components in contemplated organic control, memory, or logic circuits, also referred to as plastic-based circuits. An expected advantage of such plastic electronics is the ability to fabricate them more easily than traditional silicon-based devices. Plastic electronics thus provide a cost advantage in cases where it is not necessary to attain the performance level and device density provided by silicon-based devices. For example, organic semiconductors are expected to be much more readily printable than vapor-deposited inorganics, and are also expected to be less sensitive to air than recently proposed solution-deposited inorganic semiconductor materials. For these reasons, there have been significant efforts expended in the area of organic semiconductor materials and devices.

Organic thin film transistors (TFTs) are expected to become key components in the plastic circuitry used in display drivers of portable computers and pagers, and memory elements of transaction cards and identification tags. A typical organic TFT circuit contains a source electrode, a drain electrode, a gate electrode, a gate dielectric, an interlayer dielectric, electrical interconnects, a substrate, and semiconductor material. The precursor compositions of the present invention can be used to deposit all the components of this circuit, with the exception of the semiconductor material.

One of the most significant factors in bringing organic TFT circuits into commercial use is the ability to deposit all the components on a substrate quickly, easily and inexpensively as compared with silicon technology (i.e., by reel-to-reel printing). The precursor compositions of the present invention enable the use of low cost deposition techniques, such as ink-jet printing, for depositing these components.

The precursor compositions of the present invention are particularly useful for the direct printing of electrical connectors as well as antennae of smart tags, smart labels, and a wide range of identification devices such as radio frequency identification (RFID) tags. In a broad sense, the conductive precursor compositions can be utilized for electrical connection of semiconductor radio frequency transceiver devices to antenna structures and particularly to radio frequency identification device assemblies. A radio frequency identification device (“RFID”) by definition is an automatic identification and data capture system comprising readers and tags. Data is transferred using electric fields or modulated inductive or radiating electromagnetic carriers. RFID devices are becoming more prevalent in such configurations as, for example, smart cards, smart labels, security badges, and livestock tags.

The precursor compositions of the present invention also enable the low cost, high volume, highly customizable production of electronic labels. Such labels can be formed in various sizes and shapes for collecting, processing, displaying and/or transmitting information related to an item in human or machine readable form. The precursor compositions of the present invention can be used to print the conductive features required to form the logic circuits, electronic interconnections, antennae, and display features in electronic labels. The electronic labels can be an integral part of a larger printed item such as a lottery ticket structure with circuit elements disclosed in a pattern as disclosed in U.S. Pat. No. 5,599,046.

In another embodiment of the present invention, the conductive patterns made in accordance with the present invention can be used as electronic circuits for making photovoltaic panels. Currently, conventional screen-printing is used in mass scale production of solar cells. Typically, the top contact pattern of a solar cell consists of a set of parallel narrow finger lines and wide collector lines deposited essentially at a right angle to the finger lines on a semiconductor substrate or wafer. Such front contact formation of crystalline solar cells is performed with standard screen-printing techniques. Direct printing of these contacts with the precursor compositions of the present invention provides the advantages of production simplicity, automation, and low production cost.

Low series resistance and low metal coverage (low front surface shadowing) are basic requirements for the front surface metallization in solar cells. Minimum metallization widths of 100 to 150 μm are obtained using conventional screen-printing. This causes a relatively high shading of the front solar cell surface. In order to decrease the shading, a large distance between the contact lines, i.e., 2 to 3 mm is required. On the other hand, this implies the use of a highly doped, conductive emitter layer. However, the heavy emitter doping induces a poor response to short wavelength light. Narrower conductive lines can be printed using the precursor composition and printing methods of the present invention. The conductive precursor compositions of the present invention enable direct printing of finer features down to 20 μm. The precursor compositions of the present invention further enable the printing of pure metals with resistivity values of the printed features as low as 2 times bulk resistivity after processing at temperatures as low as 200° C.

The low processing and direct-write deposition capabilities according to the present invention are particularly enabling for large area solar cell manufacturing on organic and flexible substrates. This is particularly useful in manufacturing novel solar cell technologies based on organic photovoltaic materials such as organic semiconductors and dye sensitized solar cell technology as disclosed in U.S. Pat. No. 5,463,057 by Graetzel et al. The precursor compositions according to the present invention can be directly printed and heated to yield a bulk conductivity that is no less than 10 percent of the conductivity of the equivalent pure metal, and achieved by heating the printed features at temperatures below 200° C. on polymer substrates such as plexiglass (PMMA).

Another embodiment of the present invention enables the production of an electronic circuit for making printed wiring board (PWBs) and printed circuit boards (PCBs). In conventional subtractive processes used to make printed-wiring boards, wiring patterns are formed by preparing pattern films. The pattern films are prepared by means of a laser plotter in accordance with wiring pattern data outputted from a CAD (computer-aided design system), and are etched on copper foil by using a resist ink or a dry film resist.

In such conventional processes, it is necessary to first form a pattern film, and to prepare a printing plate in the case when a photo-resist ink is used, or to take the steps of lamination, exposure and development in the case when a dry film resist is used.

Such methods can be said to be methods in which the digitized wiring data are returned to an analog image forming step. Screen-printing has a limited work size because of the printing precision of the printing plate. The dry film process is a photographic process and, although it provides high precision, it requires many steps, resulting in a high cost especially for the manufacture of small lots.

The precursor composition and printing methods of the present invention offer solutions to overcome the limitations of the current PWB formation process. For example, they do not generate any waste. The printing methods of the present invention are a single step direct printing process and are compatible with small-batch and rapid turn around production runs. For example, a copper precursor composition can be directly printed onto FR4 (a polymer impregnated fiberglass) to form interconnection circuitry. These features are formed by heating the printed copper precursor in an N₂ ambient at 150° C. to form copper lines with a line width of not greater than 100 μm, a line thickness of not greater than 5 μm, and a bulk conductivity that is not less than 10 percent of the conductivity of the pure copper metal.

Patterned electrodes obtained by one embodiment of the present invention can also be used for screening electromagnetic radiation or earthing electric charges, in making touch screens, radio frequency identification tags, electrochromic windows and in imaging systems, e.g., silver halide photography or electrophotography. A device such as the electronic book described in U.S. Pat. No. 6,124,851 can be formed using the compositions of the present invention.

The dielectric precursor compositions of the present invention can provide dielectric features having novel combinations of high performance in terms of dielectric constant, while being formed at a low processing temperature.

In one embodiment for a high k dielectric, a dielectric constant of 700 and a loss of 6% is achieved for a material processed at 600° C. for 12 minutes. In another embodiment for a high k dielectric, a dielectric constant of 200 and a loss of 2% is achieved for a material processed at 550° C. for 15 minutes. In another embodiment for a high k dielectric, a dielectric constant of 100 and a loss of 12% is achieved for a material processed at 350° C. for 30 minutes.

In one embodiment for a low loss dielectric, a dielectric constant of 300 is achieved with a low loss of 0.9% for a material processed at 400° C. for 30 minutes.

In another embodiment illustrating the importance of surface modification to reduce loss, a dielectric constant of 17 is obtained with a loss of 0.2% for a material processed at 450° C. for 30 minutes. In another embodiment illustrating the importance of surface modification to reduce loss, a dielectric constant of 13 is obtained with a loss of 0.7% for a material processed at 350° C. for 30 minutes. Both of these examples were treated after firing with a surface modification.

By way of example, a porous layer of dielectric composite consisting of BaTiO₃ particles and a ZST matrix has a loss of 5%. The layer was exposed to a silanating agent for 15 minutes, then oven dried at 120° C. for 15 minutes. The measured loss was reduced to 0.7%.

In accordance with the foregoing direct-write processes, the present invention enables the formation of features for devices and components having small feature size. For example, the method of the present invention can be used to fabricate features having an average width of not greater than about 100 μm, more preferably not greater than about 75 μm, even more preferably not greater than 50 μm and even more preferably not greater than 25 μm. The precursor compositions described in the present invention also enable the deposition of thinner layers than what is state of the art for thick film pastes. Dielectric layers with thickness of not greater than 20 μm can be readily deposited, more preferably not greater than 15 μm, or even more preferably not greater than 10 μm, while maintaining resistance to dielectric breakdown in the range of several kV/cm. In general terms, the capacitance of a capacitor embedded in a multilayer package is related to the dielectric constant of a dielectric material and the thickness of the dielectric layer according to the following equation:
C=(eNAk)/t

where C is the capacitance of the multilayer capacitor; e is a constant; N is the number of active layers in the case of multilayered ceramic package; k is the dielectric constant of the dielectric material obtained after deposition and processing of the dielectric precursor. A is the area of the electrodes which is often small to save “real estate cost”, and t is the thickness or distance between the capacitor plates.

This equation illustrates that if the value of A is constant, the capacitance can be improved by increasing either the number of active layers N or the ratio of K/t. Hence, the importance of using high-k compositions, and applying this dielectric precursor in very thin layers, as enabled by the present invention.

The present invention is particularly useful for fabrication of capacitors or dielectric layers that can be fired below 500° C., more preferably below 400° C., more preferably below 350° C., and even more preferably below 250° C. The present invention enables the production of highly pure dielectric features with low porosity, or fully dense composite layers with a dielectric constant of up to 500, more preferably up to 750, even more preferably up to 1000. The present invention further enables the deposition of very thin dielectric layers, such as not greater than 20 μm, more preferably thinner than 15 μm, and even more preferably thinner than 10 μm while having a typical surface roughness not greater than 10% of the full layer thickness and a typical breakdown voltage of at least 500 kV/cm for a 5 mm² device.

The present invention also enables the production of highly pure dielectric features with low porosity, or fully dense composite layers with a dielectric loss of not greater than 1%, more preferably not greater than 0.1%, even more preferably not greater than 0.05%. The dielectric constants are up to 700 at 1 MHz when processed at 600° C. The porosity is not greater than 20% when processed at 600° C. The surface roughness is not greater than 5% of the thickness of the layer.

The layer thickness is not greater than 1 μm for dielectrics made from pure precursors. Screen printed dielectric layers are typically about 12 μm thick.

The loss can be as low as 0.2% for dielectrics processed at 450° C. and surface modified.

The layers of the present invention can combine the attributes of being flexible, being compatible with a wide variety of electrode materials, including polymer thick film materials.

The dielectric layer can be a composite layer. The composite can include metal oxide/glass, metal oxide/polymer, and metal oxide 1/metal oxide 2. For example, the low temperature processing allows the formulation of composite dielectric layer including Al₂O₃ and TiO₂ particles. This composition can be tailored to have a very low TCC value combined with very low loss for low fire microwave applications. In a preferred embodiment, the dielectric metal oxide is PMN and the preferred glass is a lead based borosilicate glass. In another preferred embodiment, the dielectric derived from particles is doped BaTiO₃, and the dielectric derived from precursors is ZST.

The glass-metal oxide compositions can include powders of each material or various combinations of powders and precursors. For example, the dielectric composite could be a combination of dielectric particles, dielectric precursor, and a low melting temperature glass.

The compositions and methods of the present invention provide final microstructures including phases of dielectric and glass that are not interdiffused. They also provide compositions where the two dielectric phases are not interdiffused. For example, the composite could include BaTiO₃ particles that are connected through a network of TiO₂ derived from precursor. This structure would be impossible to achieve through traditional sintering routes where the phases would interdiffuse.

The porosity of the composite dielectric structures derived from the compositions and methods of the present invention is preferably not greater than 25%, more preferably not greater than 10%, even more preferably not greater than 5%, and most preferably not greater than 2%.

The low temperature processing further allows the combination of dielectric and magnetic materials into one composite phase. For example, a mixed phase including Ni—Zn ferrite and BaTiO₃ can be prepared by using particles of both phases and a low melting point glass and firing at 600° C. This low firing temperature avoids the problems that are typically associated with sintering, such as thermal mismatch during cooling, and solid-state diffusion, which causes interdiffusion of the two very different functional phases. The composite materials can have tailored dielectric and magnetic properties and be deposited on low temperature substrates including semiconductor chip components, microwave components, organic substrates, polymer substrates and glass substrates.

The present invention also provides high performance dielectric layers containing no polymer that are in contact with either a polymeric substrate, or a thin metal layer that is directly in contact with a polymeric substrate. This is a result of the low processing temperatures coupled with the high performance.

The compositions and methods of the present invention advantageously allow the fabrication of a variety of dielectric structures. The dielectric can form a portion of a loaded antenna. The dielectric can be placed under the conductor in an antenna. The dielectric can be used in a capacitor or sensor. The dielectric layer can also be used in organic and inorganic EL displays.

The present invention provides a method for creating unique microstructures of dielectric materials.

The compositions and methods of the present invention can be used to fabricate dielectric and capacitive layers for RF tags and smart cards. The compositions and methods provide the ability to print disposable electronics such games in magazines.

The precursor compositions and processes of the present invention can be used to fabricate microelectronic components such as decoupling capacitors deposited directly onto the semiconductor chip.

Another technology where the direct-write deposition of electronic powders according to the present invention provides significant advantages is for flat panel displays, such as plasma display panels. High resolution dispensing of low fire dielectric layers is a particularly useful method for forming the capacitive layers for a plasma display panel. Typically, a dielectric precursor is printed onto a glass substrate and is fired in air at from about 450° C. to 600° C. The present invention offers much lower firing temperatures.

Direct-write deposition offers many advantages over the precursor techniques including faster production time and the flexibility to produce prototypes and low-volume production applications. The deposited features will have high resolution and dimensional stability, and will have a high density.

The present invention is also applicable to inductor-based devices including transformers, power converters and phase shifters. Examples of such devices are illustrated in: U.S. Pat. No. 5,312,674 by Haertling et al.; U.S. Pat. No. 5,604,673 by Washburn et al.; and U.S. Pat. No. 5,828,271 by Stitzer. Each of the foregoing U.S. Patents is incorporated herein by reference in their entirety.

Further, the use of hollow particles leads to layers with lower dielectric constants. A particularly useful material for this application is alumina, where the hollowness reduces the dielectric constant and increases the buoyancy thereby reducing stratification, and has low loss due to the intrinsic characteristics of alumina at high frequencies. Further, very high thermal conductivity is not required and therefore silica is often used in this application.

The present invention can be used in circuitry for a disposable calculator, sensors including conductor features of pure metal on an organic, semiconductor, or glass substrates for solar cell technology, disposable cell phone, game in a magazine, electronic paper, where the paper is in a magazine

The present invention can also be used to print dielectric materials onto substrates that are not flat. For example, these can include helmets, windshields, electronic components, electronic packaging, visors, etc.

The present invention allows printing of electronic materials on substrates that have multiple material surfaces exposed. These exposed materials can include Si, SiO₂, silicon nitride, polymers, polyimides, epoxies, etc.

According to another embodiment of the present invention, the circuit can contain various combinations of circuit elements, some or all of which can be formed by direct writing. The circuit can include only a conductor. The circuit can include conductor and resistor elements as in resistor networks. The circuit can include conductor, resistor and dielectric elements.

According to another embodiment of the present invention, the circuit can be printed on a substrate that is transparent or reflective.

The present invention can be used to direct write the dielectric substrate for directly written antennae. The antenna can be a fractal antenna. The antenna can be a loaded antenna comprising resistive, inductive, or capacitive elements.

3-D deposition techniques such as syringe dispensing described herein allow direct deposition of a wide variety of materials. The composition of the particle/precursor can be continuously modified during deposition, and micrometer-scale composition and positioning accuracy can be achieved. The complete synthesis process can be performed below 500° C. and local laser heating can be employed for in-situ material processing. These deposition capabilities can be fully utilized to deposit radially graded structures.

In addition to circulators in microwave devices, the composite and functionally graded composites that are described herein have numerous other applications in the area of miniaturization of hybrid microwave circuits. For example, graded dielectric constants in the plane can be used for impedance transformers by relying on the graded dielectric constant rather than tapered geometry to change intrinsic impedance along the length of the line. This will reduce size and has the potential to reduce losses associated with the geometrical aspects and related resonance effects.

In another embodiment of the present invention, conducting or ceramic structures of one composition in a medium of a different composition can be provided. By building some type of resonance into the structure, novel properties can be obtained.

In one particular implementation of these resonant structures, miniature microwave filters with very specific performance can be constructed by imbedding a conductive resonant structure into a high-k medium. For example, imbedding a conductive resonator structure into a dielectric with a relative dielectric constant of 10,000 will enable a size reduction by a factor of 100.

This technique will enable the fabrication of devices with highly customized filter characteristics, while the reduction in device footprint, especially in the 1 GHz range where current component sizes are of the order of several centimeters, will allow for direct integration versatility onto monolithic microwave integrated chips.

The present invention, when combined with high resolution 3-D deposition techniques such as syringe dispensing described herein allow direct deposition of multiple types of materials in a multilayer fashion with micron-scale spatial resolution within the layers. One implementation of this capability results in a photonic bandgap material consisting of stacked layers of dielectric rods. Each layer in the stack is rotated 90 degrees relative to adjacent layers, forming what is commonly known as a Lincoln log structure. While such structures can be obtained using photolithographic techniques, the present invention allows the structures to be made from new materials, with fewer steps, and at significantly lower costs

In one embodiment of the present invention for low ohm resistors, the feature includes silver derived from a precursor and an insulating phase. The insulating phase is preferably a glass or metal oxide. Preferred glasses are aluminum borosilicates, lead borosilicates and the like. Preferred metal oxides are silica, titania, alumina, and other simple and complex metal oxides. In one embodiment the insulating phase is derived from particles. In another embodiment, it is derived from precursors. In yet another embodiment, the insulative phase is derived from nanoparticles.

In one embodiment, the substrate is not planar and a non-contact printing approach is used. The non-contact printing approach can be syringe-dispense providing deposition of discrete units of precursor onto the surface. Examples of surfaces that are non-planar include windshields, electronic components, electronic packaging and visors.

The precursor compositions and methods provide the ability to print disposable electronics such as for games included in magazines. The precursor compositions can advantageously be deposited and reacted on cellulose-based materials such as paper or cardboard. The cellulose-based material can be coated if necessary to prevent bleeding of the precursor composition into the substrate. For example, the cellulose-based material can be coated with a UV curable polymer.

The low-ohm resistors formed in accordance with the present invention have combinations of various features that have not been attained using other high viscosity precursor compositions. After firing, precursor compositions of the present invention will yield solids that may or may not be porous with specific bulk resistivity values. As a background, bulk resistivity values of a number of fully dense solids are provided in Table 6 below:

Bulk resistivity values for various materials.

TABLE 6

| | Bulk Resistivity |
|---|---|
| Material | (micro-Ωcm) |
| silver (Ag-thick film material fired at 850° C.) | 1.59 |
| copper (Cu) | 1.68 |
| gold (Au) | 2.24 |
| aluminum (Al) | 2.65 |
| Ferro CN33-246 (Ag + low melting glass, fired | 2.7-3.2 |
| at 450° C.) | |
| SMP Ag flake + precursor formulation, 250° C. | 4.5 |
| molybdenum (Mo) | 5.2 |
| Tungsten (W) | 5.65 |
| zinc (Zn) | 5.92 |
| nickel (Ni) | 6.84 |
| iron (Fe) | 9.71 |
| palladim (Pd) | 10.54 |
| platinum (Pt) | 10.6 |
| tin (Sn) | 11 |
| solder (Pb—Sn; 50:50) | 15 |
| Lead | 20.64 |
| titanium nitrate (TiN transparent conductor) | 20 |
| polymer thick film (state of the art Ag filled polymer, | 18-50 |
| 150° C.) | |
| polymer thick film (Cu filled polymer) | 75-300 |
| ITO indium tin oxide (IN₂O₃) | 100 |
| zinc oxide (ZnO) doped-undoped) | 120-450 |
| carbon (C-graphite) | 1375 |
| doped silver phosphate glass, 330° C. | 3000 |
| ruthenium oxide (RuO₂) type conductive oxides) | 5000-10,000 |
| intrinsically conductive polymer | 1,000,000 |

A low cost resistor precursor including between 20 and 40 vol. % micron-size particles selected from the group of amorphous carbon, carbon graphite, iron, nickel, tungsten, molybdenum, and between 0 and 15 vol. % nanoparticles selected from the group of Ag, carbon, intrinsically conductive polymer, Fe, Cu, Mo, W, and between 0 and 15 wt. % precursor to a metal such as Ag, with the balance being solvents, vehicle and other additives, will, after firing at between 250° C. and 400° C., yield a bulk conductivity in the range from 50 to 4000 micro-ohm-centimeter.

A low cost resistor precursor including between 20 and 40 vol. % micron-size particles selected from the group of amorphous carbon, graphite, iron, nickel, tungsten, molybdenum, and between 10 wt. % and 30 wt. % precursor to a intrinsically conductive polymer, with the balance being solvents, vehicle and other additives, will, after firing at between 100° C. and 200° C., yield a bulk conductivity is in the range from 1,000 to 10,000 micro-ohm-centimeter.

### EXAMPLES

Pure Ag-trifluoroacetate has a decomposition temperature of about 325° C. as indicated by thermogravimetric analysis. Pure Ag-acetate decomposes at about 255° C.

Ratio of Precursor to Conversion Reaction Inducing Agent

The following examples demonstrate the importance of having a correct stoichiometric ratio between a silver salt (e.g., a metal carboxylate) and an inducing agent (e.g., an alcohol) in the paste composition.

### Example 1 (Comparative Example)

A mixture of 0.1 grams alpha terpineol and 0.9 grams Ag-trifluoroacetate was formed, which corresponds to 6.285 moles of the silver precursor to one mole of terpineol. The mixture was subjected to TGA analysis, which showed that the composition converted to substantially pure silver at about 290° C. This example illustrates that the decomposition temperature is not substantially reduced at a high molar ratio of precursor to inducing agent.

### Example 2 (Comparative Example)

A mixture of 0.9 grams alpha terpineol and 0.1 grams Ag-trifluoroacetate was formed, which corresponds to 0.069 moles of precursor to one mole of terpineol. The mixture was subjected to TGA analysis, which showed that the composition converted to substantially pure silver at about 210° C. This example illustrates the use of excess conversion reaction inducing agent.

### Example 3

A mixture of 1.7 grams terpineol and 1.7 grams silver trifluoroacetate was formed, corresponding to 0.69 moles of precursor to one mole of precursor. The mixture was subjected to TGA analysis, which showed that the mixture converted to substantially pure silver at 175° C. This mixture has a conversion temperature of 175° C. The molar ratio of salt to terpineol is 0.69 moles of salt to one mole of terpineol. This example illustrates a correct ratio of inducing agent to precursor.

### Example 4 (Comparative example)

A mixture containing 50 parts by weight (pbw) Ag-trifluoroacetate and 50 pbw H₂O was formulated. The calculated silver content was 24.4 wt. % and thermogravimetric analysis showed the mass loss reached 78 wt. % at 340° C. This data corresponds to the above-described decomposition temperature for pure Ag-trifluoroacetate, within a reasonable margin for error.

### Example 5 (Preferred Additive)

A mixture was formulated containing 44 pbw Ag-trifluoroacetate, 22 pbw H₂O, 33 pbw DEGBE and 1 part by weight lactic acid. The calculated silver content was 21.5 wt. % and thermogravimetric analysis showed the mass loss reached 79 wt. % at 215EC. The addition of DEGBE advantageously reduced the decomposition temperature by 125EC compared to the formulation as described in Example 4. The lactic acid functions as a crystallization inhibitor.

### Example 6 (Comparative Example)

A mixture was formulated containing 58 pbw Ag-trifluoroacetate and 42 pbw dimethylformamide. The calculated silver content was 21.5 wt. % and thermogravimetric analysis showed a mass loss of 78.5 wt. % at 335EC, a decomposition temperature similar to the formulation in Example 4.

### Example 7 (Preferred Solvent, Comparative Example)

A mixture was formulated containing 40 pbw Ag-trifluoroacetate, 21 pbw DMAc and 0.7 pbw of a styrene allyl alcohol (SAA) copolymer binder. Thermogravimetric analysis showed that precursor decomposition to silver was complete at 275° C. The use of DMAc reduced the decomposition temperature by about 65° C. as compared to Example 4.

### Example 8

A mixture was formulated containing 51 pbw Ag-trifluoroacetate, 16 pbw DMAc and 32 pbw alpha terpineol. The calculated silver content was 25 wt. %. Thermogravimetric analysis showed a mass loss of 77 wt. % at 205EC. This decomposition temperature is decreased by 70° C. compared to the formulation described in Example 7, which does not employ terpineol as an additive.

### Example 9

A mixture was formulated containing 33.5 pbw Ag-trifluoroacetate, 11 pbw DMAc, 2 pbw lactic acid and 53.5 pbw DEGBE. The calculated silver content was 16.3 wt. %. Thermogravimetric analysis showed a mass loss of 83 wt. % at 205° C. to 215° C. The decomposition temperature is decreased by 60° C. to 70° C. compared to the formulation described in Example 7, which does not employ DEGBE as an additive.

### Example 10

A mixture was formulated containing 49 pbw Ag-trifluoroacetate, 16 pbw DMAc, 32 pbw alpha-terpineol and 1.2 pbw Pd-acetate. Thermogravimetric analysis indicated complete decomposition of the metal organic precursors at 170° C. This decomposition temperature is decreased by 35EC compared to the formulation described in Example 8, which does not employ Pd-acetate as an additive.

### Example 11

A mixture was formulated containing 46 pbw Ag-trifluoroacetate, 49 pbw DMAc and 2.3 pbw Pd-acetate. Thermogravimetric analysis indicated complete decomposition of the metal organic precursors at 195° C. This decomposition temperature is 80° C. lower compared to the formulation described in Example 7, which does not employ Pd-acetate as an additive.

### Example 12

A mixture was formulated containing 4 pbw Ag-acetate and 50 pbw ethanolamine. Thermogravimetric analysis showed that precursor decomposition to silver was complete at 190° C. This conversion temperature is 65° C. lower than the decomposition temperature of pure Ag-acetate.

### Example 13a

A silver/palladium mixture was formulated containing 3.8 pbw Ag-trifluoroacetate, 8.6 pbw Pd-trifluoroacetate, 32.3 parts DMAc and 1.3 parts lactic acid. The targeted ratio of Ag/Pd was 40/60 by mass. The calculated Ag/Pd content was 10 wt. %. Thermogravimetric analysis showed a mass loss of 87 wt. % at 190° C. The presence of Pd-trifluoroacetate reduced the decomposition temperature by 80° C. compared to the composition described in Example 7.

### Example 13b

A silver/palladium mixture was formulated containing 2.4 pbw Ag-trifluoroacetate, 10.8 pbw Pd-trifluoroacetate, 31.3 pbw DMAc and 1.6 pbw lactic acid. The targeted ratio of Ag/Pd was 25/75 by mass and the calculated Ag/Pd content was 10 wt. %. Thermogravimetric analysis showed a mass loss of 88 wt. % at 190° C. The presence of Pd-trifluoroacetate reduced the decomposition temperature by 80EC compared to the composition described in Example 7.

### Example 14 (Comparative Example)

A mixture was formulated containing 2.5 pbw Ag-trifluoroacetate, 2.5 pbw DMAc and 0.2 pbw DEGBE. The mixture was deposited on a glass substrate and heated on a hotplate at 200° C. The resulting film showed large crystal growth and was not conductive.

### Example 15

A mixture was formulated containing 2.5 pbw Ag-trifluoroacetate, 2.5 pbw DMAc and 0.2 pbw lactic acid. The mixture was deposited on a glass substrate and fired on a hotplate at 200° C. The resulting film showed reduced crystal growth.

Examples of In-Situ Precursor Generation

### Example 16 (Comparative Example)

Silver oxide (AgO) powder was tested using TGA at a constant heating rate of 10° C./min. The TGA showed the conversion to pure silver was complete by about 460° C.

### Example 17

A mixture of 3.2 grams silver oxide and 3.0 grams neodecanoic acid was analyzed in a TGA. The analysis demonstrated that the conversion to pure silver was substantially complete by about 250° C.

### Example 18

A mixture of 5.2 grams alpha terpineol, 4.9 grams silver oxide and 1.1 grams neodecanoic acid was analyzed in a TGA. The TGA demonstrated that the conversion to pure silver was substantially complete by about 220° C.

### Example 19

The silver oxide/carboxylic acid chemistry was modified by the addition of metallic silver powder. The reaction products from the silver oxide and carboxylic acid weld the silver particles together providing highly conductive silver traces and features.

Specifically, a mixture of 24.4 grams of metallic silver flake, 0.6 grams neodecanoic acid, 3.7 grams alpha terpineol and 1.5 grams silver oxide was heated in a TGA. The conversion to pure silver was complete by 220° C. When fired on a surface, this produced a feature having a resistivity of about 5 times the resistivity of bulk silver.

Lowering the Conversion Temperature by Use of Palladium Precursors

### Example 20 (Comparative Example)

A mixture of 80 grams metallic silver powder, 10 grams silver trifluoroacetate, 3.51 grams DMAc, 6.99 grams alpha terpineol, 0.1 gram ethyl cellulose and 0.1 gram SOLSPERSE 21000 (SOURCE?) was analyzed using TGA. The mixture converted to substantially pure silver at about 220° C. The same mixture was deposited and heated to 250° C. The resulting conductive trace had a resistivity of 6.7 times the bulk resistivity of pure silver.

### Example 21

A mixture of 80 grams metallic silver powder, 9.0 grams silver trifluoroacetate, 1.0 gram palladium acetate, 3.17 grams DMAc, 6.35 grams alpha terpineol, 0.2 grams ethyl cellulose and 0.2 grams Solsperse 21000 was analyzed in a TGA. The TGA analysis showed the conversion to substantially pure silver was complete by about 160° C. The mixture was deposited and heated to 250° C. for 10 minutes. The resulting conductive trace had a resistivity of 16.8 times the bulk resistivity of pure silver.

### Example 22

A mixture of 3.17 grams DMAc; 6.35 grams alpha terpineol, 0.2 grams ethyl cellulose, 0.2 grams SOLSPERSE 21000, 9 grams silver trifluoroacetate, 80 grams metallic silver powder and 1.0 gram palladium trifluoroacetate was analyzed using TGA. This mixture showed a conversion to substantially pure silver at about 160° C. This mixture was then deposited and heated to 250° C. for 10 Minutes. The resulting conductive trace had a resistivity of 4.2 times the bulk resistivity of pure silver.

Examples of Silver Paste Formulations

### Example 23

A paste composition was formulated including 16.5 grams metallic silver powder, 3.5 grams alpha-terpineol and 5 grams silver carbonate. This composition was deposited and heated to 350° C. The resulting conductive trace had a resistivity of 29 times the bulk resistivity of pure silver.

### Example 24

A paste composition was formulated including 10 grams silver oxide, 0.9 grams silver nitrate, 20 grams metallic silver powder, 2.1 grams DMAc and 5.0 grams terpineol. The composition was deposited and heated to 350° C. The resulting conductive trace had a resistivity of about 11 times the bulk resistivity of silver.

### Example 25

A paste composition was formulated including 77.3 grams silver powder, 32.5 grams silver trifluoracetate, 1.2 grams SOLSPERSE 21000 and 16.2 grams alpha terpineol. The paste was deposited and heated to 250° C. The resulting conductive trace had a resistivity that was less than 6 times the bulk resistivity of pure silver. The material was very dense and non-porous. This is an example of a paste or ink where the silver precursor was not dissolved in a solvent. In this mixture, the silver precursor was in a crystalline state interspersed amongst the particles of silver. This mixture was also tested using TGA and showed a conversion to silver at about 177° C.

### Example 26

A paste composition was formulated that included 102.9 grams silver powder, 7.8 grams silver oxide, 15.2 grams silver nitrate, 10.1 grams terpineol and 1.5 grams SOLSPERSE 21000. The paste composition was deposited and was heated to 250° C. The resulting conductive features had a resistivity that was less than 6 times the bulk resistivity of pure silver. The material was very dense and had low porosity. This mixture was analyzed in a TGA and showed a conversion to silver at about 270° C.

### Example 27

A paste composition was formulated including 54.5 grams of a highly spherical silver/silica composite powder, 0.25 grams styrene allyl alcohol (SAA), 2.25 grams DMAc, 0.1 grams SOLSPERSE 21000, 0.05 grams ethyl cellulose, 4.35 grams alpha terpineol and 6 grams of silver trifluoroacetate. This paste composition was capable of being dispensed through a syringe orifice having a 75 μm outer diameter and a 50 μm inner diameter. When heated to 850° C., the paste produced conductive features having a resistivity of 1.1 times the bulk resistivity of pure silver.

Examples of Silver/Palladium formulations

### Example 31

A paste composition was formulated using 80 grams spherical silver powder, 9.0 grams silver trifluoroacetate, 3.17 grams DMAc, and 6.35 grams alpha terpineol. The paste was doctor bladed onto a glass slide to form a feature in the shape of a narrow line. The feature was then heated in air at 250° C. for 10 minutes. The metal feature was subsequently dipped in liquid solder at 250° C. for 15 seconds. The solder dipping treatment reduced the width of the line by about 15%.

### Example 32

A paste composition was formulated using 80 grams of spherical silver powder, 9.0 grams silver trifluoroacetate, 1.0 grams palladium trifluoroacetate, 3.17 grams DMAc, and 6.35 grams alpha terpineol. The paste was doctor bladed onto a glass slide to form a feature in the form of a narrow line. The feature was heated in air at 250° C. for 10 minutes. The metal line was subsequently dipped in liquid solder at 250° C. for 15 seconds. The solder dip did not have any significant effect on the width of the deposited line, indicating good solder leach resistance.

Examples 31 and 32 illustrate that the formulation with the small amount of Pd precursor exhibits a significant improvement in solder leach resistance as compared to the formulation without palladium precursor.

Examples of Precursor Compositions for 185° C.

### Example 33

### Baseline for Low Temperature Performance

A precursor composition was formulated by combining 0.26 grams palladium trifluoroacetate, 7.2 grams silver trifluoroacetate, 37.49 grams silver flake, 5.08 grams terpineol. This mixture was fired at 185° C. for 30 minutes to yield a resistivity of 11.4 times the bulk resistivity of pure silver.

### Example 34

### Improved Performance with Solvent Addition

A precursor composition was formulated by combining 1.5 grams dimethylacetimide, 5.08 grams terpineol, 37.52 grams silver flake, 7.22 grams silver trifluoroacetate, 0.25 grams palladium trifluoroacetate. This mixture was fired at 185° C. for 60 minutes to yield a resistivity of 2.9 times the bulk resistivity of pure silver.

### Example 35

### Improved Performance with Solvent Addition

A paste composition was formulated by combining 0.24 grams palladium trifluoroacetate, 7.3 grams silver trifluoroacetate, 37.5 grams silver flake, 5.13 grams terpineol, 1.55 grams N-methyl-pyrolidone. This mixture was fired at 185° C. for 60 minutes to yield a resistivity of 2.3 times the bulk resistivity of pure silver.

### Example 36

A paste composition was formulated by combining 5.74 grams Silver Neodecanoate, 1.66 grams Dimethylacetimide, 3.8 grams terpineol, 0.58 grams palladium trifluoroacetate, 37.37 grams silver flake. This mixture was fired at 185° C. for 60 minutes to yield a resistivity of 11.9 times the bulk resistivity of pure silver.

### Example 37

A paste composition was formulated by combining 35 grams silver flake, 7.55 grams silver (I) oxide and 5.35 grams terpineol. This mixture was fired at 185° C. for 60 minutes to yield a resistivity of 2.4 times the bulk resistivity of pure silver.

### Example 38

A paste composition was formulated by combining 35.03 grams silver flake, 6.26 grams silver nitrite, 6.51 grams terpineol. This mixture was fired at 185° C. for 60 minutes to yield a resistivity of 2.1 times the bulk resistivity of pure silver.

Examples of Precursor Compositions with Adhesion Promotion

Adhesion promotion to Kapton-HN by etching with KOH, Tetra etch, surface coat of polyamic acid and coating with various inks. Also modification of the inks by addition of acids. Using above paste examples based on AgTFA and Ag-nitrite as base formulations. The pastes were applied to milled kapton samples. After treatment all parts were placed into a preheated oven at 185° C. and fired for 60 minutes.

### Example 39

A KAPTON substrate including grooves was washed with 7.3N KOH solution for 1 minute, rinsed with deionized water and dried in oven at 60° C. The grooves were filled with the paste from Example 34 and fired. After firing a 90° scotch tape test was performed with greater than 90% of the material remaining in the grooves. On an identically treated substrate the grooves were filled with the paste from Example 38 and fired. After firing a 90° scotch tape test was performed with less than 15% of the material remaining in the grooves.

### Example 40

A KAPTON substrate including grooves was washed with TETRA-ETCH (W.L. Gore and Associates) for 1 minute, rinsed with deionized water and dried in oven at 60° C. The grooves were filled with the paste from Example 34 and fired. After firing a 90° scotch tape test was performed with nearly 100% of the material remaining in the grooves. On an identically treated substrate the grooves were filled with the paste from Example 38 and fired. After firing a 90° scotch tape test was performed with about 40% of the material remaining in the grooves.

### Example 41

A KAPTON substrate including grooves was washed with a dilute polyamic acid solution (1 g polyamic acid/48.2 gram DMAc), and allowed to dry. The grooves were filled with the paste from Example 34 and fired. After firing a 90° scotch tape test was performed with greater than about 95% of the material remaining in the grooves. On an identically treated substrate the grooves were filled with the paste from Example 38 and fired. After firing a 90° scotch tape test was performed with about 10% of the material remaining in the grooves.

### Example 42

A KAPTON substrate including grooves was washed with Ag/Pd precursor ink (Pd-TFA 0.5 g, Ag-TFA 1.52 g and DMAc 2.5 g) wiped dry with a kimwipe and oven dried at 60° C. The grooves were filled with the paste from Example 34 and fired. After firing a 90° scotch tape test was performed with 100% of the material remaining in the grooves. On an identically treated substrate the grooves were filled with the composition from Example 38 and fired. After firing a 90° scotch tape test was performed with about 20% of the material remaining in the grooves.

### Example 43

### Lead Zirconate Titanate (PZT)

The following precursors are mixed in the following ratios in toluene to form a solution: 23.8 wt. % Ti dimethoxy dineodecanoate; 21.4 wt. % Zr butoxide; and 54.8 wt. % Pb ethylhexanoate. The PZT precursor mixture decomposes at 450° C. as evidenced by TGA. Formation of crystalline PZT does not occur until processing at 500° C. for at least 30 minutes and preferably 90 minutes or more.

### Example 44

### Zirconium Tin Titanate (ZST)

Precursors are mixed in the following ratios: 49.8 wt. % Ti isopropoxide triethylamine; 18.2 wt. % Zr ethylhexanoate; 5.9 wt. % Zr propoxide; and 26.1 wt. % Sn ethylhexanoate. The mixture was heated and found to decompose by 550° C. as evidenced by TGA. The crystallinity of the ZST is improved by post processing at greater than 500° C. for 60 minutes.

### Example 45

### Zirconium Tin Titanate (ZST)

Precursors are mixed in the following ratios: 50.9 wt. % Ti dimethoxy dineodecanoate; 19.3 wt. % Zr propoxide; 27.2 wt. % Sn ethylhexanoate; and 2.6 wt. % Zr ethylhexanoate. The composition was found to decompose by 550° C. as evidenced by TGA. The crystallinity of the ZST is improved by post processing at greater than 500° C. for 60 minutes.

### Example 46

### Pb₂Ta₂O₇

Precursors are mixed in the following ratios: 45.1 wt. % Ta ethoxide; 54.9 wt. % Pb ethylhexanoate; and dodecane as needed for solubility. The lead tantalate precursor decomposes by 450° C. as evidenced by TGA. Formation of crystalline Pb₂Ta₂O₇ occurs by processing at 550° C. for one hour.

### Example 47

### Composite Layer of Barium Titanate and Zirconium Tin Titanate

A barium titanate powder is dispersed in hexane with Menhaden fish oil as a dispersant. To this is added a ZST precursor and the hexane is volatilized. The precursor is then doctor bladed onto a silver coated alumina substrate and fired at 300° C. for 30 minutes. The resulting 34 μm film has a dielectric constant of 35 and a loss of 4% when electroded and measured at 1 MHz. This is equivalent to a capacitance of 970 pF/cm².

### Example 48

### Lead Magnesium Niobate/Glass Composite

A lead magnesium niobate powder (PMN) is dispersed in hexane with Menhaden fish oil as a dispersant. The solvent is then removed leaving a coated PMN powder. This powder is then mixed with a lead-based glass powder, which can optionally be coated with a dispersant. The powder mixture is combined With terpineol as a solvent and ethyl cellulose as a binder and milled into a precursor. The precursor is then screen printed onto a gold-electroded alumina substrate and fired at 600° C. for 12 minutes. The resulting 13 μm film has a dielectric constant of 700 with a loss of 6% when electroded and measured at 1 kHz. This is equivalent to a capacitance of 48 nF/cm².

### Example 49

A resistor precursor composition including aqueous precursors to Pb₂Ru₂O_{6.5} and lead borosilicate glass along with lead borosilicate glass particles was formulated. The components were 25.7 wt. % lead glass precursor (contains water and butyl carbitol), 6.4 wt. % Ru precursor (aqueous) and 67.9 wt. % of a lead glass. This composition showed upwards of 50 ohm-cm resistivity.

### Example 50

A resistor precursor including 34.8 wt. % of composite Ag-10% RuO₂ particles, 47.7 wt. % lead borosilicate glass particles and 17.4 wt. % alpha-terpineol was formulated. This represented about 30% conductor by volume. The resistor was processed at 500° C. for 30 minutes.

### Example 51

A resistor precursor composition was prepared including 50.3 wt. % of composite Ag-10% RuO₂ particles, 19.7 wt. % calcium aluminum borosilicate glass, 14.3 wt. % tetraethoxysilane, 14.3 wt. % terpineol carrier, 0.5 wt. % ethyl cellulose and 1.4 wt. % fumed silica. The composition was processed at 300° C. and had a sheet resistance of 9.9 k□/square.

### Example 52

A resistor precursor Composition was prepared including 34.9 wt. % SrRuO₃, 25.7 wt. % calcium aluminum borosilicate glass, 18.8 wt. % tetraethoxysilane, 1.9 wt. % fumed silica, 18.0 wt. % terpineol and 0.7 wt. % ethyl cellulose. The composition was processed at 300° C. and had a sheet resistance of 22.4 k□/square.

### Example 53

A very low-ohm resistor composition was prepared consisting of 70 vol. % spherical silver powder produced by spray pyrolysis with 30 vol. % conductive low melting silver glass. The composition was processed at 450° C. for 20 minutes and yielded a resistivity of 5.5× bulk silver.

### Example 54

A resistor composition was prepared consisting of RuO2 particles dispersed with lead borosilicate glass with 15 vol. % conductor. The composition shows resistivity values of 300 kΩ/square with a TCR on the order of 200 ppm/° C. The composition is processable by a laser.

### Example 55

Ag—RuO₂ particles were produced and combined in a glass matrix to make a resistor. The line was shown to be conductive with a 30 volume percent loading of conductor material when processed at 550° C. for 15 minutes.

### Example 56

Ag—RuO₂ particles were combined with a precursor to a silica matrix and processed at low temperatures (300° C.), and showed conductivity. In contrast, identical compostions containing pure silver particles showed no conductivity. This is believed to be due to RuO₂ phase on the surface of the particles, which allows either more intimate contact of particles or some tunneling, or both.

While various embodiments of the present invention have been described in detail, it is apparent that modifications and adaptations of those embodiments will occur to those skilled in the art. However, it is to be expressly understood that such modifications and adaptations are within the spirit and scope of the present invention.

What is claimed is:

1. A process for forming a solar cell conductive feature, comprising:
(a) direct printing a precursor composition onto a substrate, the precursor composition comprising at least one of metallic particles comprising a metal or a metal precursor compound to the metal; and
(b) heating the composition to a temperature not greater than 900° C. to form the solar cell conductive feature on the substrate, wherein the conductivity of the solar cell conductive feature is no less than 10 percent the conductivity of the equivalent pure metal.

2. The process of claim 1, wherein the direct printing comprises syringe printing.

3. The process of claim 1, wherein the direct printing comprises aerosol jet deposition.

4. The process of claim 1, wherein the direct printing comprises ink jet printing.

5. The process of claim 1, wherein step (b) comprises heating the composition to a temperature not greater than about 600° C. to form the conductive feature on the substrate.

6. The process of claim 1, wherein step (b) comprises heating the composition to a temperature not greater than about 400° C. to form the conductive feature on the substrate.

7. The process of claim 1, wherein step (b) comprises heating the composition to a temperature not greater than about 350° C. to form the conductive feature on the substrate.

8. The process of claim 1, wherein the conductive feature has a resistivity that is not greater than 4 times the resistivity of the equivalent pure metal.

9. The process of claim 1, wherein the conductive feature has a resistivity that is not greater than 2 times the resistivity of the equivalent pure metal.

10. The process of claim 1, wherein the precursor composition comprises the metallic particles comprising the metal.

11. The process of claim 10, wherein the heating sinters adjacent particles to one another

12. The process of claim 10, wherein the metal is selected from the group consisting of silver, palladium, copper, gold, platinum and nickel.

13. The process of claim 10, wherein the metallic particles have a volume median particle size of not greater than 100 nanometers.

14. The process of claim 10, wherein the metallic particles have a volume median particle size of not greater than 0.3 μm.

15. The process of claim 14, wherein the metallic particles comprise a cap or coating thereon.

16. The process of claim 15, wherein the cap or coating comprises an inorganic cap or coating.

17. The process of claim 15, wherein the cap or coating comprises silica.

18. The process of claim 15, wherein the cap or coating comprises an organic cap or coating.

19. The process of claim 15, wherein the cap or coating comprises a polymer.

20. The process of claim 15, wherein the cap or coating comprises an intrinsically conductive polymer, a sulfonated perfluorohydrocarbon polymer, polystyrene, polystyrene/methacrylate, sodium bis(2-ethylhexyl) sulfosuccinate, tetra-n-octyl-ammonium bromide or an alkane thiolate.

21. The process of claim 15, wherein the cap or coating comprises PVP.

22. The process of claim 1, wherein the precursor composition comprises the metal precursor compound to the metal.

23. The process of claim 22, wherein the metal is selected from the group consisting of silver, palladium, copper, gold, platinum and nickel.

24. The process of claim 1, wherein the precursor composition further comprises metal oxide particles.

25. The process of claim 1, wherein the precursor composition further comprises glass particles.

26. The process of claim 1, wherein the conductive feature comprises a set of finger lines and collector lines deposited essentially at a right angle to the finger lines.

27. The process of claim 26, wherein either or both the parallel finger lines or the collector lines have width less than 200 μm.

28. The process of claim 26, wherein either or both the parallel finger lines or the collector lines have width less than 100 μm.

29. The process of claim 1, wherein the conductive feature has a thickness greater than 5 μm.

30. The process of claim 1, wherein the conductive feature comprises a transparent conductive feature.

31. The process of claim 1, wherein the conductive feature comprises indium-tin oxide or antimony-tin oxide.

32. The process of claim 1, wherein the substrate comprises a ceramic.

33. The process of claim 1, wherein the substrate comprises glass.

34. The process of claim 1, wherein the conductive feature comprises a metal-glass composition.

35. The process of claim 1, wherein the conductive feature is resistant to solder leaching.

36. The process of claim 1, wherein the process further comprises high shear mixing the precursor composition.

37. The process of claim 1, wherein the process further comprises surface modifying the substrate with a laser.

38. A process for forming a solar cell conductive feature disposed on a substrate, the process comprising heating an ink jet printed precursor composition comprising a metal to a temperature not greater than 900° C. to form the solar cell conductive feature on the substrate, wherein the conductivity of the solar cell conductive feature is no less than 10 percent the conductivity of the equivalent pure metal.

39. The process of claim 38, wherein the heating comprises heating the composition to a temperature not greater than about 600° C. to form the conductive feature on the substrate.

40. The process of claim 38, wherein the heating comprises heating the composition to a temperature not greater than about 400° C. to form the conductive feature on the substrate.

41. The process of claim 38, wherein the heating comprises heating the composition to a temperature not greater than about 350° C. to form the conductive feature on the substrate.

42. The process of claim 38, wherein the conductive feature has a resistivity that is not greater than 4 times the resistivity of the equivalent pure metal.

43. The process of claim 38, wherein the conductive feature has a resistivity that is not greater than 2 times the resistivity of the equivalent pure metal.

44. The process of claim 38, wherein the precursor composition comprises metallic particles comprising the metal.

45. The process of claim 44, wherein the heating sinters adjacent particles to one another

46. The process of claim 44, wherein the metal is selected from the group consisting of silver, palladium, copper, gold, platinum and nickel.

47. The process of claim 44, wherein the metallic particles have a volume median particle size of not greater than 100 nanometers.

48. The process of claim 44, wherein the metallic particles have a volume median particle size of not greater than 0.3 μm.

49. The process of claim 48, wherein the metallic particles comprise a cap or coating thereon.

50. The process of claim 48, wherein the cap or coating comprises an inorganic cap or coating.

51. The process of claim 48, wherein the cap or coating comprises silica.

52. The process of claim 48, wherein the cap or coating comprises an organic cap or coating.

53. The process of claim 48, wherein the cap or coating comprises a polymer.

54. The process of claim 48, wherein the cap or coating comprises an intrinsically conductive polymer, a sulfonated perfluorohydrocarbon polymer, polystyrene, polystyrene/methacrylate, sodium bis(2-ethylhexyl) sulfosuccinate, tetra-n-octyl-ammonium bromide or an alkane thiolate.

55. The process of claim 48, wherein the cap or coating comprises PVP.

56. The process of claim 38, wherein the precursor composition comprises a metal precursor compound to the metal.

57. The process of claim 56, wherein the metal is selected from the group consisting of silver, palladium, copper, gold, platinum and nickel.

58. The process of claim 38, wherein the precursor composition further comprises metal oxide particles.

59. The process of claim 38, wherein the precursor composition further comprises glass particles.

60. The process of claim 38, wherein the conductive feature comprises a set of finger lines and collector lines deposited essentially at a right angle to the finger lines.

61. The process of claim 60, wherein either or both the parallel finger lines or the collector lines have width less than 200 μm.

62. The process of claim 60, wherein either or both the parallel finger lines or the collector lines have width less than 100 μm.

63. The process of claim 38, wherein the conductive feature has a thickness greater than 5 μm.

64. The process of claim 38, wherein the conductive feature comprises a transparent conductive feature.

65. The process of claim 38, wherein the conductive feature comprises indium-tin oxide or antimony-tin oxide.

66. The process of claim 38, wherein the substrate comprises a ceramic.

67. The process of claim 38, wherein the substrate comprises glass.

68. The process of claim 38, wherein the conductive feature comprises a metal-glass composition.

69. The process of claim 38, wherein the conductive feature is resistant to solder leaching.
